(19) United States
(12) Patent Application Publication
(10) Pub. No.: US 2025/0155803 A1
(43) Pub. Date: May 15, 2025

(54) CURABLE COMPOSITION, CURED FILM, AND DISPLAY DEVICE

(71) Applicant: SUMITOMO CHEMICAL COMPANY, LIMITED, Chuo-ku, Tokyo (JP)

(72) Inventors: Masayoshi TOKUDA, Osaka-shi (JP); Hiroshi IWAWAKI, Osaka-shi (JP); Mitsuo TSUCHIYA, Osaka-shi (JP); Megumi HAYASAKA, Osaka-shi (JP); Yukako NISHIKAWA, Osaka-shi (JP)

(73) Assignee: SUMITOMO CHEMICAL COMPANY, LIMITED, Chuo-ku, Tokyo (JP)

(21) Appl. No.: 18/838,590

(22) PCT Filed: Jan. 20, 2023
(86) PCT No.: PCT/JP2023/001667

§ 371 Date: Aug. 14, 2024

(30) Foreign Application Priority Data
Feb. 21, 2022 (JP) 2022-024732
Oct. 20, 2022 (JP) 2022-168518

(51) Int. Cl. G03F 7/021; G03F 7/004; G03F 7/105

(52) U.S. Cl. CPC G03F 7/0212; G03F 7/0045; G03F 7/105

(57) ABSTRACT

To provide a curable composition that includes a light-emissive semiconductor particle and is unlikely to cause generation of outgas.

A curable composition comprising: a semiconductor particle (A); a polymerizable compound (B); a polymerization initiator (C); and an antioxidant (D);
wherein a formula (i) is satisfied:

$$11.5 \leq {M}_{B} / {M}_{C} \leq 150 \qquad ( i )$$

wherein M_{B} represents a content ratio (% by mass) of the polymerizable compound (B) and Me represents a content ratio (% by mass) of the polymerization initiator (C), all based on a total amount of the curable composition.

### TECHNICAL FIELD

The present invention relates to a curable composition and a cured film formed therefrom, and a display device including the cured film.

### BACKGROUND ART

As a curable resin composition for forming a cured film, such as a wavelength conversion film included in a display device, there is known those including a light-emitting semiconductor particle, such as quantum dots (Patent Literature 1). Use of an ink composition including quantum dots has been studied for a method for producing a wavelength conversion film or the like by inkjet method (Patent Literatures 2 and 3).

### CITATION LIST

### Patent Literature

Patent Literature 1: Japanese Patent Laid-Open No. 2016-71362
Patent Literature 2: International Publication No. 2018/123821
Patent Literature 3: International Publication No. 2018/123103

### SUMMARY OF INVENTION

### Technical Problem

When heat is applied to a cured film, such as a wavelength conversion film, formed from a cured composition including a semiconductor particle, outgas may be generated from the cured film. The generation of the outgas may be problematic in a process after forming the cured film, and it is thus desirable to reduce the outgas. In addition, it is desirable that a cured film formed form a curable composition including a semiconductor particle should have favorable light-emitting characteristics even when it has undergone application of heat.

An object of the present invention is to provide a curable composition that includes a light-emissive semiconductor particle and is unlikely to cause generation of the above-described outgas. Another object of the present invention is to provide a curable composition that is unlikely to cause generation of outgas and is also capable of forming a cured film having a favorable emission intensity even when the cured film is produced by a method involving application of heat. Still another object of the present invention is to provide a cured film formed from the curable composition and a display device including the cured film.

### Means to Solve the Problems

The present invention provides a curable composition, a cured film, and a display device shown below.

[1]A curable composition comprising: a semiconductor particle (A); a polymerizable compound (B); a polymerization initiator (C); and an antioxidant (D);
wherein a formula (i) is satisfied:

$$11.5 \leq {M}_{B} / {M}_{C} \leq 150 \qquad ( i )$$

wherein M_{B} represents a content ratio (% by mass) of the polymerizable compound (B) and M_{c} represents a content ratio (% by mass) of the polymerization initiator (C), all based on a total amount of the curable composition.

[2] The curable composition according to [1], wherein a formula (ii) is further satisfied:

$$0.01 \leq {M}_{D} / {M}_{A} \leq 0.6 \qquad ( ii )$$

wherein M_{A} represents a content ratio (% by mass) of the semiconductor particle (A) and M_{D} represents a content ratio (% by mass) of the antioxidant (D), all based on the total amount of the curable composition.

[3] The curable composition according to [1] or [2], wherein a formula (iii) is further satisfied:

$$0.5 \leq ( {M}_{B} \times {M}_{D} ) / ( {M}_{C} \times {M}_{A} ) \leq 7.5 . \qquad ( iii )$$

[4]A curable composition comprising: a semiconductor particle (A); a polymerizable compound (B); a polymerization initiator (C); and an antioxidant (D);
wherein a formula (iii) is satisfied:

$$0.5 \leq ( {M}_{B} \times {M}_{D} ) / ( {M}_{C} \times {M}_{A} ) \leq 7.5 \qquad ( iii )$$

wherein M_{A} represents a content ratio (% by mass) of the semiconductor particle (A), M_{B} represents a content ratio (% by mass) of the polymerizable compound (B), M_{c} represents a content ratio (% by mass) of the polymerization initiator (C), and M_{D} represents a content ratio (% by mass) of the antioxidant (D), all based on a total amount of the curable composition.

[5] The curable composition according to any one of [1] to [4], further comprising a light scattering agent (E).

[6] The curable composition according to any one of [1] to [5], wherein the polymerizable compound (B) includes a polymerizable compound that has a volatile content of 7% by mass or less when heated at 80° C. for 1 hour.

[7] The curable composition according to any one of [1] to [6], wherein the polymerizable compound (B) includes a polymerizable compound of which homopolymer has a glass transition temperature of −50° C. or more.

[8] The curable composition according to any one of [1] to [7], wherein the polymerizable compound (B) includes a polymerizable compound that has a dipole moment of 3D or more, in an amount of 40% by mass or more based on a total amount of the polymerizable compound (B).

[9] The curable composition according to [8], wherein the polymerizable compound (B) includes a difunctional polymerizable compound that has a dipole moment of 3D or more, in an amount of 40% by mass or more based on the total amount of the polymerizable compound (B).

[10] The curable composition according to [8] or [9], wherein the polymerizable compound (B) includes a trifunctional polymerizable compound that has a dipole moment of 3D or more and 4D or less.

[11] The curable composition according to any one of [1] to [7], wherein the polymerizable compound (B) includes a polymerizable compound that has a dipole moment of 3D or more, in an amount of 20% by mass or more based on the total amount of the curable composition.

[12] The curable composition according to [11], wherein the polymerizable compound (B) includes a difunctional polymerizable compound that has a dipole moment of 3D or more, in an amount of 20% by mass or more based on the total amount of the curable composition.

[13] The curable composition according to [11] or [12], wherein the polymerizable compound (B) includes a trifunctional polymerizable compound that has a dipole moment of 3D or more and 4D or less.

[14] The curable composition according to any one of [1] to [13], wherein a content ratio of a solvent (F) is 1% by mass or less based on the total amount of the curable composition.

[15] The curable composition according to any one of [1] to [14], wherein a content ratio of a resin (I) is 1% by mass or less based on the total amount of the curable composition.

[16] The curable composition according to any one of [1] to [15], wherein the curable composition has a viscosity of 20 cP or less at 40° C.

[17]A cured film formed from the curable composition according to any one of [1] to [16].

[18]A display device comprising the cured film according to [17].

### Effects of Invention

According to the present invention, it is possible to provide a curable composition that includes a light-emissive semiconductor particle and is unlikely to cause generation of the above-described outgas. It is also possible to provide a curable composition that is unlikely to cause generation of the outgas and is also capable of forming a cured film having a favorable emission intensity even when the cured film is produced by a method involving application of heat. It is also possible to provide a cured film formed from the curable composition and a display device including the cured film.

### BRIEF DESCRIPTION OF DRAWINGS

FIG. 1 is a schematic cross-sectional view showing an example of a display member.

### DESCRIPTION OF EMBODIMENTS

### <Curable Composition>

The curable composition according to the present invention (hereinafter, also simply referred to as “curable composition”) comprises: a semiconductor particle (A); a polymerizable compound (B); a polymerization initiator (C); and an antioxidant (D). Components that are included or may be included in the curable composition will be described below.

Herein, compounds listed as a component that is included or may be included in the curable composition can be used singly or in combinations of two or more, unless otherwise noticed.

### [1] Semiconductor Particle (A)

The semiconductor particle (A) emits light having a wavelength different from that of primary light, and preferably converts a wavelength of blue light as primary light to a wavelength of light different therefrom. The semiconductor particle (A) preferably emits green light or red right, and it more preferably absorbs blue light and emits green light or red right.

As used herein, “blue” generally refers to light visually recognized as blue color (generally, light having an intensity within the wavelength range of blue color, for example, the range from 380 nm to 495 nm), and not limited to light having a single wavelength. “Green” generally refers to light visually recognized as green color (generally, light having an intensity within the wavelength range of green color, for example, the range from 495 nm to 585 nm), and not limited to light having a single wavelength. “Red” generally refers to light visually recognized as red color (generally, light having an intensity within the wavelength range of red color, for example, the range from 585 nm to 780 nm), and not limited to light having a single wavelength. “Yellow” generally refers to light visually recognized as yellow color (generally, light having an intensity within the wavelength range of yellow color, for example, the range from 560 nm to 610 nm), and not limited to light having a single wavelength.

The light emission spectrum of the semiconductor particle (A) that emits green light preferably exhibits a peak having the maximum value within a wavelength range of 500 nm or more and 560 nm or less, more preferably a peak having the maximum value within a wavelength range of 520 nm or more and 545 nm or less, even more preferably a peak having the maximum value within a wavelength range of 525 nm or more and 535 nm or less. This enables expansion of the color gamut that can be displayed by green light in a display device. The peak preferably has a full width at half maximum of 15 nm or more and 80 nm or less, more preferably 15 nm or more and 60 nm or less, even more preferably 15 nm or more and 50 nm or less, particularly preferably 15 nm or more and 45 nm or less. This enables expansion of the color gamut that can be displayed by green light in a display device.

The light emission spectrum of the semiconductor particle (A) emitting red light preferably exhibits a peak having the maximum value within a wavelength range of 610 nm or more and 750 nm or less, more preferably a peak having the maximum value within a wavelength range of 620 nm or more and 650 nm or less, even more preferably a peak having the maximum value within a wavelength range of 625 nm or more and 645 nm or less. This enables expansion of the color gamut that can be displayed by red light in a display device. The peak preferably has a full width at half maximum of 15 nm or more and 80 nm or less, more preferably 15 nm or more and 60 nm or less, even more preferably 15 nm or more and 50 nm or less, particularly preferably 15 nm or more and 45 nm or less. This enables expansion of the color gamut that can be displayed by red light in a display device.

The light emission spectrum of the semiconductor particle (A) is determined according to the method described in the section of Examples later.

Examples of the semiconductor particle (A) include quantum dots, and a particle of a compound having a perovskite crystal structure (hereinafter also referred to as “perovskite compound”), and the semiconductor particle (A) is preferably quantum dots. The quantum dots are light emissive semiconductor fine particles having a particle size of 1 nm or more and 100 nm or less, and are fine particles that utilize the bandgap of the semiconductor to absorb ultraviolet or visible light (e.g., blue light) and emit light.

Examples of the quantum dots include a compound between a group 12 element and a group 16 element, such as CdS, CdSe, CdTe, ZnS, ZnSe, ZnTe, HgS, HgSe, HgTe, CdHgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe; a compound between a group 13 element and a group 15 element, such as GaN, GaP, GaAs, AlN, AlP, AlAs, InN, InP, InAs, GaNP, GaNAs, GaPAs, AlNP, AlNAs, AlPAs, InNP, InNAs, InPAs, GaAlNP, GaAlNAs, GaAlPAs, GaInNP, GaInNAs, GaInPAs, InAlNP, InAlNAs, and InAlPAs; a compound between a group 14 element and a group 16 element, such as PdS and PbSe.

In a case where quantum dots including S or Se is used, the quantum dots optionally have a surface modified with a metal oxide or an organic matter. When quantum dots having a modified surface are used, S or Se abstraction by a reactive component that is contained or may be contained in the composition can be prevented.

The above-described compounds may be combined to form quantum dots having a core-shell structure. Examples of such a combination include a fine particle including CdSe as the core and ZnS as the shell, and a fine particle including InP as the core and ZnSeS as the shell.

Since the energy state of the quantum dots depends on its size, the emission wavelength can be freely selected by changing the particle size. The light emitted from the quantum dots has a spectrum having a narrow range, which is advantageous for expansion of the color gamut of a display device. Furthermore, the quantum dots have high responsibility, which is advantageous for efficiency of utilization of primary light.

The perovskite compound is a compound having a perovskite crystal structure and containing components A, B, and X.

In the perovskite crystal structure, A is the component located at each vertex of the hexahedron having B as the center, and is a monovalent cation.

In the perovskite crystal structure, X is the component located at each vertex of the octahedron having B as the center, and is at least one ion selected from the group consisting of halide ions and a thiocyanate ion.

In the perovskite crystal structure, B is the component located at the centers of the hexahedron having A at the vertices and the octahedron having X at the vertices, and is a metal ion.

The perovskite compound having component A, B, and X is not particularly limited, and may be a compound having any of a three-dimensional structure, a two-dimensional structure, and a pseudo two-dimensional structure.

In the case of the three-dimensional structure, the perovskite compound is represented by A₂BX_{(3+δ)}.

In the case of the two-dimensional structure, the perovskite compound is represented by A₂BX_{(4+δ)}.

δ is an appropriate variable number according to the charge balance of B, and is −0.7 or more and 0.7 or less.

Specific preferable examples of the perovskite compound having a three-dimensional structure of the perovskite crystal structure represented by ABX_{(3+δ)} include
CH₃NH₃PbBr₃, CH₃NH—PbCl₃, CH₃NH₃PbI₃, CH₃NH₃PbBr_{(3-y)}I_{y} (0<y<3), CH₃NH₃PbBr_{(3-y)}Cl_{y} (0<y<3), (H₂N═CH—NH₂)PbBr₃, (H₂N═CH−NH₂)PbCl₃, (H₂N═CH—NH₂)PbI₃,
CH₃NH₃Pb₍₁₋ₐ₎Ca₃Br₃ (0<a≤0.7), CH₃NH₃Pb₍₁₋ₐ₎SrₐBr₃ (0<a≤0.7), CH₃NH₃Pb₍₁₋ₐ₎LaₐBr_{(3+δ)} (0<a≤0.7, 0<δ≤0.7), CH₃NH₃Pb₍₁₋ₐ₎Ba₃Br₃ (0<a≤0.7), CH₃NH₃Pb₍₁₋ₐ₎DyₐBr_{(3+δ)} (0<a≤0.7, 0<δ≤0.7),
CH₃NH₃Pb₍₁₋ₐ₎NaₐBr_{(3+δ)} (0<a≤0.7, −0.7 δ<0), CH₃NH₃Pb₍₁₋ₐ₎LiₐBr_{(3+δ)} (0<a≤0.7, −0.7≤δ<0),
CsPb₍₁₋ₐ₎NaₐBr_{(3+δ)} (0<a 0.7, −0.7≤δ<0), CsPb₍₁₋ₐ₎LiₐBr_{(3+δ)} (0<a≤0.7, −0.7≤δ<0),
CH₃NH₃Pb₍₁₋ₐ₎NaₐBr_{(3+δ-y)}I_{y} (0<a≤0.7, −0.7≤δ<0, 0<y<3), CH₃NH₃Pb₍₁₋ₐ₎ LiₐBr_{(3+δ-y)}I_{y} (0<a≤0.7, −0.7≤δ<0, 0<y<3), CH₃NH₃Pb₍₁₋ₐ₎NaₐBr_{(3+δ-y)}Cl_{y} (0<a≤0.7, −0.7≤δ<0, 0<y<3), CH₃NH₃Pb₍₁₋ₐ₎LiₐBr_{(3+δ-y)}Cl_{y} (0<a≤0.7, −0.7≤δ<0, 0<y<3),
(H₂N═CH—NH₂) Pb₍₁₋ₐ₎NaₐBr_{(3+δ)} (0<a≤0.7, −0.7≤δ<0), (H₂N═CH—NH₂)Pb₍₁₋ₐ₎LiₐBr_{(3+δ)} (0<a≤0.7, −0.7≤δ<0), (H₂N═CH—NH₂)Pb₍₁₋ₐ₎NaₐBr_{(3+δ-y)}I_{y} (0<a≤0.7, −0.7≤δ<0, 0<y<3), (H₂N═CH—NH₂)Pb₍₁₋ₐ₎NaₐBr_{(3+δ-y)}Cl_{y} (0<a≤0.7, −0.7≤δ<0, 0<y<3),
CsPbBr₃, CsPbCl₃, CsPbI₃, CsPbBr_{(3-y)}I_{y} (0<y<3), CsPbBr_{(3-y)}Cl_{y} (0<y<3), CH₃NH₃PbBr_{(3-y)}Cl_{y} (0<y<3),
CH₃NH₃Pb₍₁₋ₐ₎MnₐBr₃ (0<a≤0.7), CH₃NH₃Pb₍₁₋ₐ₎AlₐBr_{(3+δ)} (0<a≤0.7, 0≤δ≤0.7), CH₃NH₃Pb₍₁₋ₐ₎Co₃Br₃ (0<a≤0.7), CH₃NH₃Pb₍₁₋ₐ₎MnₐBr₃ (0<a≤0.7), CH₃NH₃Pb₍₁₋ₐ₎MgₐBr₃ (0<a≤0.7),
CsPb₍₁₋ₐ₎ZnₐBr₃ (0<a≤0.7), CsPb₍₁₋ₐ₎AlₐBr_{(3+δ)} (0<a≤0.7, 0<δ≤0.7), CsPb₍₁₋ₐ₎CoₐBr₃ (0<a≤0.7), CsPb₍₁₋ₐ₎MnₐBr₃ (0<a≤0.7), CsPb₍₁₋ₐ₎MgₐBr₃ (0<a≤0.7),
CH₃NH₃Pb₍₁₋ₐ₎ZnₐBr_{(3-y)} (0<a≤0.7, 0<y<3), CH₃NH₃Pb₍₁₋ₐ₎AlₐBr_{(3+δ-y)}I_{y} (0<a≤0.7, 0<δ≤0.7, 0<y<3), CH₃NH₃Pb₍₁₋ₐ₎CoₐBr_{(3-y)}I_{y} (0<a≤0.7, 0<y<3), CH₃NH₃Pb₍₁₋ₐ₎MnₐBr_{(3-y)}I_{y} (0<a≤0.7, 0<y<3), CH₃NH₃Pb₍₁₋ₐ₎MgₐBr_{(3-y)}I_{y} (0<a≤0.7, 0<y<3), CH₃NH₃Pb₍₁₋ₐ₎ZnₐBr_{(3-y)}Cl_{y} (0<a≤0.7, 0<y<3), CH₃NH₃Pb₍₁₋ₐ₎AlₐBr_{(3+δ-y)}Cl_{y} (0<a≤0.7, 0<δ≤0.7, 0<y<3), CH₃NH₃Pb₍₁₋ₐ₎CoₐBr_{(3+δ-y)}Cl_{y} (0<a≤0.7, 0<y<3), CH₃NH₃Pb₍₁₋ₐ₎MnₐBr_{(3-y)}Cl_{y} (0<a≤0.7, 0<y<3), CH₃NH₃Pb₍₁₋ₐ₎Mg₃Br_{(3-y)}Cl_{y} (0<a≤0.7, 0<y<3),
(H₂N═CH—NH₂)ZnₐBr₃ (0<a≤0.7), (H₂N═CH—NH₂)MgₐBr₃ (0<a≤0.7), (H₂N═CH—NH₂) Pb₍₁₋ₐ₎ZnₐBr_{(3-y)}I_{y} (0<a≤0.7, 0<y<3), and (H₂N═CH—NH₂)Pb₍₁₋ₐ₎ZnₐBr_{(3-y)}Cl_{y} (0<a≤0.7, 0<y<3).

Specific preferable examples of the perovskite compound having a two-dimensional structure of the perovskite crystal structure represented by A₂BX_{(4+δ)} include
(C₄H₉NH₃)₂PbBr₄, (C₄H₉NH₃)₂PbCl₄, (C₄H₉NH₃)₂PbI₄, (C₇H₁₅NH₃)₂PbBr₄, (C₇H₁₅NH₃)₂PbCl₄, (C₇H₁₅NH₃)₂PbI₄, (C₄H₉NH₃)₂Pb₍₁₋ₐ₎Li₂Br_{(4+δ)} (0<a≤0.7, −0.7≤δ<0), (C₄H₉NH₃)₂Pb₍₁₋ₐ₎NaₐBr_{(4+δ)} (0<a≤0.7, −0.7≤δ<0), (C₄H₉NH₃)₂Pb₍₁₋ₐ₎RbₐBr_{(4+δ)} (0<a≤0.7, −0.7≤δ<0),
(C₇H₁₅NH₃)₂Pb₍₁₋ₐ₎NaₐBr_{(4+δ)} (0<a≤0.7, −0.7≤δ<0), (C₇H₁₅NH₃)₂Pb₍₁₋ₐ₎Li₃Br_{(4+δ)} (0<a≤0.7, −0.7≤δ<0), (C₇H₁₅NH₃)₂Pb₍₁₋ₐ₎RbaBr_{(4+δ)} (0<a≤0.7, −0.7≤δ<0),
(C₄H₉NH₃)₂Pb₍₁₋ₐ₎NaₐBr_{(4+δ-y)}I_{y} (0<a≤0.7, −0.7≤δ<0, 0<y<4), (C₄H₉NH₃)₂Pb₍₁₋ₐ₎LiₐBr_{(4+δ-y)}I_{y} (0<a≤0.7, −0.7 δ<0, 0<y<4), (C₄H₉NH₃)₂Pb₍₁₋ₐ₎RbₐBr_{(4+δ-y)}I_{y} (0<a≤0.7, −0.7≤δ<0, 0<y<4),
(C₄H₉NH₃)₂Pb₍₁₋ₐ₎NaₐBr_{(4+δ-y)}Cl_{y} (0<a≤0.7, −0.7≤δ<0, 0<y<4), (C₄H₉NH₃)₂Pb₍₁₋ₐ₎LiₐBr_{(4+δ-y)}Cl_{y} (0<a≤0.7, −0.7≤δ<0, 0<y<4), (C₄H₉NH₃)₂Pb₍₁₋ₐ₎RbₐBr_{(4+δ-y)}Cl_{y} (0<a≤0.7, −0.7≤δ<0, 0<y<4),
(C₄H₉NH₃)₂PbBr₄, (C₇H₁₅NH₃)₂PbBr₄,
(C₄H₉NH₃)₂PbBr_{(4-y)}Cl_{y} (0<y<4), (C₄H₉NH₃)₂PbBr_{(4-y)}I_{y} (0<y<4),
(C₄H₉NH₃)₂Pb₍₁₋ₐ₎ZnₐBr₄ (0<a≤0.7), (C₄H₉NH₃)₂Pb₍₁₋ₐ₎ MgₐBr₄ (0<a≤0.7), (C₄H₉NH₃)₂Pb₍₁₋ₐ₎CoₐBr₄ (0<a≤0.7), (C₄H₉NH₃)₂Pb₍₁₋ₐ₎MnₐBr₄ (0<a≤0.7),
(C₇H₁₅NH₃)₂Pb₍₁₋ₐ₎ZnₐBr₄ (0<a≤0.7), (C₇H₁₅NH₃)₂Pb₍₁₋ₐ₎ MgₐBr₄ (0<a≤0.7), (C₇H₁₅NH₃)₂Pb₍₁₋ₐ₎CoₐBr₄ (0<a≤0.7), (C₇H₁₅NH₃)₂Pb₍₁₋ₐ₎MnₐBr₄ (0<a≤0.7),
(C₄H₉NH₃)₂Pb₍₁₋ₐ₎ZnₐBr_{(4-y)}I_{y} (0<a≤0.7, 0<y<4), (C₄H₉NH₃)₂Pb₍₁₋ₐ₎MgₐBr_{(4-y)}I_{y} (0<a≤0.7, 0<y<4), (C₄H₉NH₃)₂Pb₍₁₋ₐ₎Co₃Br_{(4-y)}I_{y} (0<a≤0.7, 0<y<4), (C₄H₉NH₃)₂Pb₍₁₋ₐ₎MnₐBr_{(4-y)}I_{y} (0<a≤0.7, 0<y<4),
(C₄H₉NH₃)₂Pb₍₁₋ₐ₎ZnₐBr_{(4-y)}Cl_{y} (0<a≤0.7, 0<y<4), (C₄H₉NH₃)₂Pb₍₁₋ₐ₎Mg₃Br_{(4-y)}Cl_{y} (0<a≤0.7, 0<y<4), (C₄H₉NH₃)₂Pb₍₁₋ₐ₎CoₐBr_{(4-y)}Cl_{y} (0<a≤0.7, 0<y<4), (C₄H₉NH₃)₂Pb₍₁₋ₐ₎MnₐBr_{(4-y)}Cl_{y} (0<a≤0.7, 0<y<4).

The curable composition may contain two or more kinds of the semiconductor particles (A). For example, the curable composition may contain only a single kind of semiconductor particle (A) that absorbs primary light to emit green light, or may contain two or more kinds thereof in combination. The curable composition may contain only a single kind of the semiconductor particle (A) that absorbs primary light to emit red light, or may contain two or more kinds thereof in combination.

The semiconductor particle (A) may a ligand-containing semiconductor particle that contains an organic ligand (G) coordinates with the semiconductor particle. The organic ligand (G) may be, for example, an organic compound having a polar group having capability to coordinate with the semiconductor particle (A). The organic ligand (G) may coordinate to the surface of the semiconductor particle (A), for example. When the organic ligand (G) is an organic compound having a polar group, the organic ligand (G) generally coordinates with the semiconductor particle via the polar group. The semiconductor particle (A) may contain one or more kinds of the organic ligands (G). The semiconductor particle (A) containing the organic ligand (G) may bring about advantages in view of the stability and dispersibility of the semiconductor particle (A) and improvement in the emission intensity of the curable composition and the cured film. If the semiconductor particle is uniformly dispersed in a medium suitable for an organic ligand, it is determined that the organic ligand (G) coordinates with the semiconductor particle.

The polar group of the organic ligand (G) is at least one group selected from the group consisting of a thiol group (—SH), a carboxy group (—COOH), and an amino group (—NH). The polar group selected from the group can be advantageous in increasing the coordination property to the semiconductor particles. The larger coordination property can contribute to the improvement in stability and dispersibility of the semiconductor particle (A) in the curable composition and the improvement in the emission intensity of a curable composition and a cured film. In particular, the polar group is more preferably at least one group selected from the group consisting of a thiol group and a carboxy group. The organic ligand (G) may have one or more polar groups.

The organic ligand (G) may be, for example, an organic compound represented by the following formula (X):

X^{h}—R^{X} (X)

In the formula, X^{A} is the above-mentioned polar group, and R^{X} is a monovalent hydrocarbon group which may contain a heteroatom (N, O, S, halogen atom, or the like). The hydrocarbon group may have one or two or more unsaturated bonds such as carbon-carbon double bonds. The hydrocarbon group may have a linear, branched, or cyclic structure. The number of carbon atoms of the hydrocarbon group is, for example, 1 or more and 40 or less, and may be 1 or more and 30 or less. The methylene group contained in the hydrocarbon group is optionally replaced by —O—, —S—, —C(═O)—, —C(═O)—O—, —O—C(═O)—, —C(═O)—NH—, —NH—, or the like.

The group R^{X} may contain a polar group. With respect to specific examples of the polar group, the above description relating to the polar group X^{A} is referred to.

Specific examples of the organic ligand having a carboxy group as the polar group X^{A} include formic acid, acetic acid, propionic acid, and saturated or unsaturated fatty acids. Specific examples of saturated or unsaturated fatty acids include saturated fatty acids such as butyric acid, pentanoic acid, caproic acid, caprylic acid, capric acid, lauric acid, myristic acid, pentadecylic acid, palmitic acid, margaric acid, stearic acid, arachidic acid, behenic acid, and lignoceric acid; monounsaturated fatty acids such as myristoleic acid, palmitoleic acid, oleic acid, icosenoic acid, erucic acid, and nervonic acid; and polyunsaturated fatty acids such as linoleic acid, α-linolenic acid, γ-linolenic acid, stearic acid, dihomo-γ-linolenic acid, arachidonic acid, eicosatetraenoic acid, docosadienoic acid, and adrenic acid (docosatetraenoic acid).

Specific examples of the organic ligand having a thiol group or an amino group as the polar group X^{A} include organic ligands in which the carboxy group of the organic ligands having a carboxy group as the polar group X^{A} exemplified above is replaced by a thiol group or an amino group.

In addition to the above, examples of the organic ligand represented by the formula (X) include a compound (G-1) and a compound (G-2).

### [Compound (G-1)]

The compound (G-1) is a compound having the first functional group and the second functional group. The first functional group is a carboxy group (—COOH), and the second functional group is a carboxy group or thiol group (—SH). Since the compound (G-1) has a carboxy group and/or a thiol group, it may serve as a ligand to coordinate with the semiconductor particle. The semiconductor particle (A) may contain only a single kind of the compound (G-1) or two or more thereof.

An example of the compound (G-1) is a compound represented by the formula (G-1a) below. The compound (G-1) may be an acid anhydride of the compound represented by the formula (G-1a).

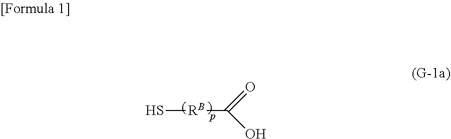

[In the formula, R^{B} represents a divalent hydrocarbon group. A plurality of R^{B}, when present, are optionally the same or different. The hydrocarbon group may have one or more substituents. When there are a plurality of substituents, they may be the same or different, and they may be bonded to each other to form a ring together with the atoms to which they are bonded. —CH₂— contained in the hydrocarbon group is optionally replaced by at least one of —O—, —S—, —SO₂—, —CO—, and —NH—.

p represents an integer of 1 to 10.]

Examples of the divalent hydrocarbon group represented by R^{B} include a chain hydrocarbon group, an alicyclic hydrocarbon group, and an aromatic hydrocarbon group.

Examples of the chain hydrocarbon group include a linear or branched alkanediyl group, and the number of carbon atoms thereof is generally 1 to 50, preferably 1 to 20, and more preferably 1 to 10. Examples of the alicyclic hydrocarbon group include a monocyclic or polycyclic cycloalkanediyl group, and the number of carbon atoms thereof is usually 3 to 50, preferably 3 to 20, and more preferably 3 to 10. Examples of the aromatic hydrocarbon group include a monocyclic or polycyclic arenediyl group, and the number of carbon atoms thereof is generally 6 to 20.

Examples of the substituent that the hydrocarbon group may have include an alkyl group having 1 to 50 carbon atoms, a cycloalkyl group having 3 to 50 carbon atoms, an aryl group having 6 to 20 carbon atoms, a carboxy group, an amino group, and a halogen atom. The substituent that the hydrocarbon group may have is preferably a carboxy group, an amino group, or a halogen atom.

When —CH₂— contained in the hydrocarbon group is replaced by at least one of —O—, —CO—, and —NH—, —CH₂— is preferably replaced by at least one of —CO— and —NH—, and more preferably —NH—. p is preferably 1 or 2.

Examples of the compound represented by the formula (G-1a) include compounds represented by the following formulas (1-1) to (1-9).

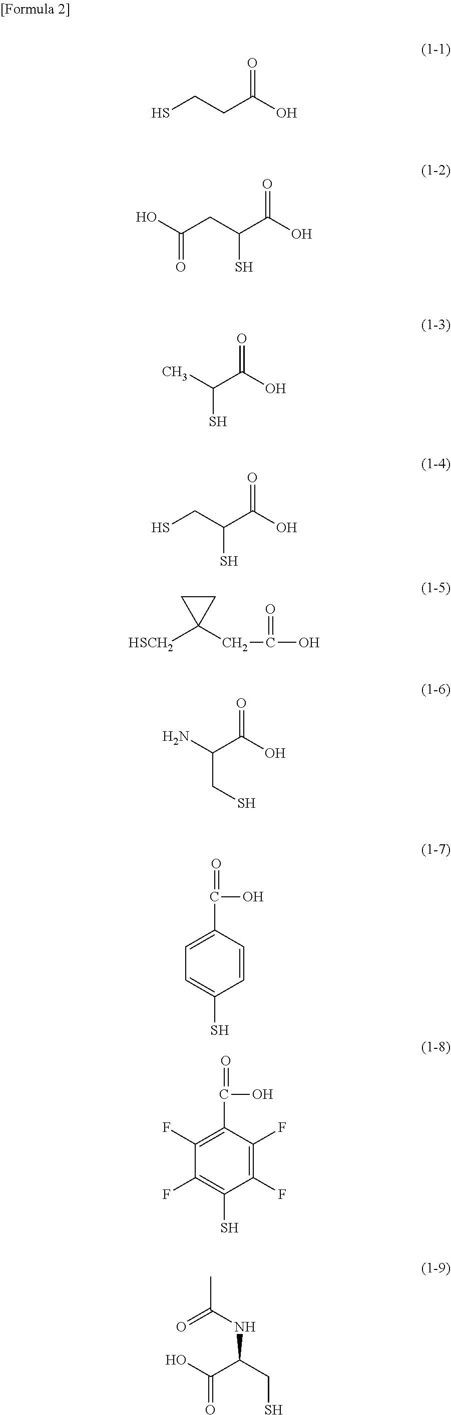

Specific examples of the compound represented by the formula (G-1a) include mercaptoacetic acid, 2-mercaptopropionic acid, 3-mercaptopropionic acid, 3-mercaptobutanoic acid, 4-mercaptobutanoic acid, mercaptosuccinic acid, mercaptostearic acid, mercaptooctanoic acid, 4-mercaptobenzoic acid, 2,3,5,6-tetrafluoro-4-mercaptobenzoic acid, L-cysteine, N-acetyl-L-cysteine, 3-methoxybutyl 3-mercaptopropionate, and 3-mercapto-2-methylpropionic acid. Of these, 3-mercaptopropionic acid and mercaptosuccinic acid are preferable.

Another example of the compound (G-1) is a polycarboxylic acid compound, preferably a compound (G-1b) in which —SH in the formula (G-1a) is replaced by a carboxy group (—COOH) in the compound represented by the formula (G-1a).

Examples of the compound (G-1b) include the following compounds:
Succinic acid, glutaric acid, adipic acid, octafluoroadipic acid, azelaic acid, dodecanedioic acid, tetradecanedioic acid, hexadecanedioic acid, heptadecanedioic acid, octadecanedioic acid, nonadecandioic acid, dodecafluorosuberic acid, 3-ethyl-3-methylglutaric acid, hexafluoroglutaric acid, trans-3-hexenedioic acid, sebacic acid, hexadecafluorosebacic acid, acetylenedicarboxylic acid, trans-aconitic acid, 1,3-adamantandicarboxylic acid, bicyclo[2.2.2]octane-1,4-dicarboxylic acid, cis-4-cyclohexene-1,2-dicarboxylic acid, 1,1-cyclopropanedicarboxylic acid, 1,1-cyclobutanedicarboxylic acid, cis- or trans-1,3-cyclohexanedicarboxylic acid, cis- or trans-1,4-cyclohexanedicarboxylic acid, 1,1-cyclopentanediacetic acid, 1,2,3,4-cyclopentanetetracarboxylic acid, decahydro-1,4-naphthalenedicarboxylic acid, 2,3-norbornanedicarboxylic acid, 5-norbornene-2,3-dicarboxylic acid, phthalic acid, 3-fluorophthalic acid, isophthalic acid, tetrafluoroisophthalic acid, terephthalic acid, tetrafluoroterephthalic acid, 2,5-dimethylterephthalic acid, 2,6-naphthalenedicarboxylic acid, 2,3-naphthalenedicarboxylic acid, 1,4-naphthalenedicarboxylic acid, 1,1′-ferrocenedicarboxylic acid, 2,2′-biphenyldicarboxylic acid, 4,4′-biphenyldicarboxylic acid, 2,5-furandicarboxylic acid, benzophenone-2,4′-dicarboxylic acid monohydrate, benzophenone-4,4′-dicarboxylic acid, 2,3-pyrazinedicarboxylic acid, 2,3-pyridinedicarboxylic acid, 2,4-pyridinedicarboxylic acid, 3,5-pyridinedicarboxylic acid, 2,5-pyridinedicarboxylic acid, 2,6-pyridinedicarboxylic acid, 3,4-pyridinedicarboxylic acid, pyrazole-3,5-dicarboxylic acid monohydrate, 4,4′-stilbenedicarboxylic acid, anthraquinone-2,3-dicarboxylic acid, 4-(carboxymethyl)benzoic acid, chelidonic acid monohydrate, azobenzene-4,4′-dicarboxylic acid, azobenzene-3,3′-dicarboxylic acid, chlorendic acid, 1H-imidazole-4,5-dicarboxylic acid, 2,2-bis(4-carboxyphenyl)hexafluoropropane, 1,10-bis(4-carboxyphenoxy) decane, dipropylmalonic acid, dithiodiglycolic acid, 3,3′-dithiodipropionic acid, 4,4′-dithiodibutanoic acid, 4,4′-dicarboxydiphenyl ether, 4,4′-dicarboxydiphenyl sulfone, ethylene glycol bis(4-carboxyphenyl)ether, 3,4-ethylenedioxythiophene-2,5-dicarboxylic acid, 4,4′-isopropylidenediphenoxyacetic acid, 1,3-acetonedicarboxylic acid, methylenedisalicylic acid, 5,5′-thiodisalicylic acid, tris(2-carboxyethyl)isocyanurate, tetrafluorosuccinic acid, α,α,α′,α′-tetramethyl-1,3-benzenedipropionic acid, and 1,3,5-benzenetricarboxylic acid.

From the viewpoint of improving stability and dispersibility of the semiconductor particle (A) and the emission intensity of a curable composition and a cured film, the molecular weight of the compound (G-1) is preferably 3000 or less, more preferably 2500 or less, even more preferably 2000 or less, still more preferably 1000 or less, particularly preferably 800 or less, and most preferably 500 or less. The molecular weight of the compound (G-1) is generally 100 or more.

The molecular weight may be a number-average molecular weight or a weight-average molecular weight. In this case, the number-average molecular weight and the weight-average molecular weight are a number-average molecular weight and a weight-average molecular weight in terms of standard polystyrene measured by gel permeation chromatography (GPC), respectively.

In the case where the ligand-containing semiconductor particles contain the compound (G-1), the ratio of the content of the compound (G-1) to that of the semiconductor particle is preferably 0.001 or more and 1 or less, more preferably 0.01 or more and 0.5 or less, and even more preferably 0.02 or more and 0.45 or less, in terms of mass ratio. The ratio between these contents within this range can be advantageous for improving stability and dispersibility of the semiconductor particle (A) and the emission intensity of a curable composition and a cured film.

In the case where the ligand-containing semiconductor particles contain the compound (G-1), the content ratio of the compound (G-1) in the curable composition is preferably 0.1% by mass or more and 20% by mass or less, more preferably 0.2, by mass or more and 20% by mass or less, even more preferably 0.2% by mass or more and 10% by mass or less, still more preferably 0.5% by mass or more and 10% by mass or less, and particularly preferably 0.5% by mass or more and 8% by mass or less, based on the total amount of the solid content of the curable composition, from the viewpoint of improving stability and dispersibility of the semiconductor particle (A) and the emission intensity of a curable composition and a cured film.

### [Compound (G-2)]

The compound (G-2) is a compound (G-2) different from the compound (G-1), and is a compound having a polyalkylene glycol structure and having a polar group at the molecular end. The molecular end is preferably the end of the longest carbon chain in the compound (G-2) (the carbon atom in the carbon chain is optionally replaced by another atom such as an oxygen atom).

The semiconductor particle (A) may contain only one compound (G-2) or two or more thereof. The semiconductor particle (A) may contain the compound (G-1) or the compound (G-2), or may be the compound (G-1) and the compound (G-2).

Compounds having a polyalkylene glycol structure and having the first functional group and the second functional group are considered to belong to the compound (G-1).

The polyalkylene glycol structure refers to a structure represented by the following formula:

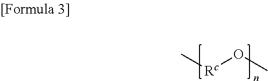

wherein n is an integer of 2 or more. In the formula, R^{C} is an alkylene group, and examples thereof include an ethylene group and a propylene group.

Specific examples of the compound (G-2) include a polyalkylene glycol compound represented by the formula (G-2a) below.

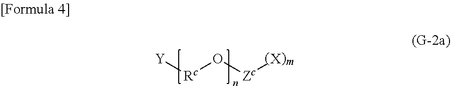

In the formula (G-2a), X is a polar group, Y is a monovalent group, and Z^{C} is a divalent or trivalent group. n is an integer of 2 or more. m is 1 or 2. R^{C} is an alkylene group.

The polar group X is preferably at least one group selected from the group consisting of a thiol group (—SH), a carboxy group (—COOH), and an amino group (—NH₂). The polar group selected from the above-described group may be advantageous in terms of enhancing capability to coordinate with the semiconductor particle. Among these, the polar group X is more preferably at least one group selected from the group consisting of a thiol group and a carboxy group in view of enhancing the stability and dispersibility of the semiconductor particle (A) and the emission intensity of the curable composition and the cured film.

The group Y is a monovalent group. The group Y is not particularly limited, and examples thereof include a monovalent hydrocarbon group optionally having a substituent (N, O, S, a halogen atom, etc.). —CH₂-contained in the hydrocarbon group is optionally replaced by —O—, —S—, —C(═O)—, —C(═O)—O—, —O—C(═O)—, —C(═O)—NH—, —NH—, or the like. The number of carbon atoms of the hydrocarbon group is, for example, 1 or more and 12 or less. The hydrocarbon group may have an unsaturated bond.

Examples of the group Y include an alkyl group having a linear, branched, or cyclic structure having 1 or more and 12 or less carbon atoms; and an alkoxy group having a linear, branched, or cyclic structure having 1 or more and 12 or less carbon atoms. The number of carbon atoms of the alkyl group and the alkoxy group is preferably 1 or more and 8 or less, more preferably 1 or more and 6 or less, and still more preferably 1 or more and 4 or less. —CH₂— contained in the alkyl group and the alkoxy group is optionally replaced by —O—, —S—, —C(═O)—, —C(═O)—O—, —O—C(═O)—, —C(═O)—NH—, —NH—, or the like. In particular, the group Y is preferably a linear or branched alkoxy group having 1 or more and 4 or less carbon atoms, and more preferably a linear alkoxy group having 1 or more and 4 or less carbon atoms.

The group Y may contain a polar group. Examples of the polar group include at least one group selected from the group consisting of a thiol group (—SH), a carboxy group (—COOH), and an amino group (—NH₂). However, as described above, compounds having a polyalkylene glycol structure and having the first functional group and the second functional group are considered to belong to the compound (G-1). The polar group is preferably located at the end of the group Y.

The group Z^{C} is a divalent or trivalent group. The group Z^{C} is not particularly limited, and examples thereof include a divalent or trivalent hydrocarbon group which may contain a heteroatom (N, O, S, halogen atom, or the like). The number of carbon atoms of the hydrocarbon group is, for example, 1 or more and 24 or less. The hydrocarbon group may have an unsaturated bond.

Examples of the group Z^{C} which is a divalent group include an alkylene group having a linear, branched, or cyclic structure having 1 or more and 24 or less carbon atoms; and an alkenylene group having a linear, branched, or cyclic structure having 1 or more and 24 or less carbon atoms. The number of carbon atoms of the alkyl group and the alkenylene group is preferably 1 or more and 12 or less, more preferably 1 or more and 8 or less, and still more preferably 1 or more and 4 or less. —CH₂-contained in the alkyl group and the alkenylene group is optionally replaced by —O—, —S—, —C(═O)—, —C(═O)—O—, —O—C(═O)—, —C(═O)—NH—, —NH—, or the like. Examples of the group Z^{C} which is a trivalent group include a group obtained by removing one hydrogen atom from the group Z which is a divalent group described above.

The group Z^{C} may have a branched structure. The group Z^{C} having a branched structure may have a polyalkylene glycol structure different from the polyalkylene glycol structure represented by the formula (G-2a) in a branched chain different from the branched chain including the polyalkylene glycol structure represented by the formula (G-2a).

In particular, the group Z^{C} is preferably a linear or branched alkylene group having 1 or more and 6 or less carbon atoms, and more preferably a linear alkylene group having 1 or more and 4 or less carbon atoms.

R^{C} is an alkylene group, and is preferably a linear or branched alkylene group having 1 or more and 6 or less carbon atoms, and more preferably a linear alkylene group having 1 or more and 4 or less carbon atoms.

n in the formula (G-2a) is an integer of 2 or more, preferably 2 or more and 540 or less, more preferably 2 or more and 120 or less, and still more preferably 2 or more and 60 or less.

The molecular weight of the compound (G-2) can be, for example, about 150 or more and about 10000 or less, and is preferably 150 or more and 5000 or less, and more preferably 150 or more and 4000 or less, from the viewpoint of improving stability and dispersibility of the semiconductor particle (A) and the emission intensity of a curable composition and a cured film. The molecular weight may be a number average molecular weight or a weight-average molecular weight. In this case, the number-average molecular weight and the weight-average molecular weight are a number-average molecular weight and a weight-average molecular weight in terms of standard polystyrene measured by GPC, respectively.

In the case where the ligand-containing semiconductor particles contain the compound (G-2), the ratio of the content of the compound (G-2) to that of the semiconductor particle is preferably 0.001 or more and 2 or less, more preferably 0.01 or more and 1.5 or less, and even more preferably 0.1 or more and 1 or less, in terms of mass ratio. The ratio between these contents within this range can be advantageous for improving stability and dispersibility of the semiconductor particle (A) and the emission intensity of a curable composition and a cured film.

In the case where the ligand-containing semiconductor particles contain the compound (G-2), the content ratio of the compound (G-2) in the curable composition is preferably 0.1% by mass or more and 40% by mass or less, more preferably 0.1% by mass or more and 20% by mass or less, even more preferably 1% by mass or more and 15% by mass or less, and still more preferably 2% by mass or more and 12% by mass or less, based on the total amount of the solid content of the curable composition, from the viewpoint of improving stability and dispersibility of the semiconductor particle (A) and the emission intensity of a curable composition and a cured film.

When the semiconductor particle (A) is a ligand-containing semiconductor particle that contains the organic ligand (G), the ratio of the content of the organic ligand (G) to that of the semiconductor particle in the curable composition, in terms of mass, is preferably 0.001 or more and 1 or less, more preferably 0.01 or more and 0.8 or less, even more preferably 0.02 or more and 0.5 or less. The ratio between these contents within this range can be advantageous for improving stability and dispersibility of the semiconductor particle (A) and the emission intensity of a curable composition and a cured film. The content of the organic ligand (G) here means the total content of all the organic ligand(s) contained in the curable composition.

The content ratio of the semiconductor particle (A), M_{A}, is preferably 10% by mass or more, more preferably 16% by mass or more, even more preferably 17% by mass or more, still more preferably 18% by mass or more, particularly preferably 20% by mass or more, most preferably 25% by mass or more, and preferably 45% by mass or less, more preferably 40% by mass or less, even more preferably 35% by mass or less, based on the total amount of the curable composition. A content ratio of the semiconductor particle (A), M_{A}, within the above-described range may be advantageous in terms of enhancing the emission intensity of the curable composition and the cured film. In a case where the semiconductor particle (A) is a ligand-containing semiconductor particle that contains the organic ligand (G), the content ratio of the semiconductor particle (A), M_{A}, herein is the content ratio of the ligand-containing semiconductor particle.

Also, the content ratio of the semiconductor particle (A) based on the total amount of the solids content of the curable composition is preferably within the same range as described above, in view of enhancing the emission intensity of the curable composition and the cured film.

Herein, the total amount of the solids content of the curable composition means the total of the components excluding the solvent (F) among the components contained in the curable composition. The content ratio in the solids content of the curable composition can be determined by known analytical means such as liquid chromatography or gas chromatography. The content ratio of each component in the solids content of the curable composition may also be calculated from the formulation when the curable composition is prepared.

As stated above, the curable composition may contain two or more kinds of the semiconductor particles (A). In this case, the above-described content ratio of the semiconductor particle (A) means the total content ratio of the two or more kinds of the semiconductor particles (A). The same also applies to components other than the semiconductor particle (A) that are contained or may be contained in the curable composition, which will be later. In a case where two or more kinds are contained as a component, the amount contained or the content ratio of the component means the total amount or the total content ratio of the two or more kinds.

### [2] Polymerizable Compound (B)

The curable composition contains a polymerizable compound (B). The polymerizable compound (B) is a compound that is polymerizable due to, for example, an active radial or an acid generated from the polymerization initiator (C), which will be described later. The curable composition may contain two or more kinds of the polymerizable compounds (B).

Examples of the polymerizable compound (B) include a photopolymerizable compound, which is cured by irradiation with light, and a thermally polymerizable compound, which is cured by heat. Examples of the photopolymerizable compound include a radically photopolymerizable compound, which is cured through a radical polymerization reaction by irradiation with light, and a cationically photopolymerizable compound, which is cured through a cation polymerization reaction by irradiation with light. The photopolymerizable compound is preferably the radically photopolymerizable compound.

The photopolymerizable compound has a weight-average molecular weight of, for example, 150 or more and 3000 or less, preferably 150 or more and 2900 or less, more preferably 250 or more and 1500 or less.

Examples of the radically photopolymerizable compound include a compound having a polymerizable, ethylenically unsaturated bond, and among others, a (meth)acrylate compound is preferable. Examples of the (meth)acrylate compound include a monofunctional (meth)acrylate monomer having a single (meth)acryloyloxy group per molecule (hereinafter, also referred to as “compound (B-1)”), a bifunctional (meth)acrylate monomer having two (meth)acryloyloxy groups per molecule (hereinafter, also referred to as “compound (B-2)”), and a polyfunctional (meth)acrylate monomer having three or more (meth)acryloyloxy groups per molecule (hereinafter, also referred to as “compound (B-3)”)

Herein, “(meth)acrylate” means acrylate and/or methacrylate. The same also applies to “(meth)acryloyl”, “(meth)acrylic acid”, etc.

Examples of the compound (B-1) include methyl (meth)acrylate, ethyl (meth)acrylate, propyl (meth)acrylate, butyl (meth)acrylate, amyl (meth)acrylate, hexyl (meth)acrylate, 2-ethylhexyl (meth)acrylate, octyl (meth)acrylate, nonyl (meth)acrylate, dodecyl (meth)acrylate (lauryl (meth)acrylate), hexadecyl (meth)acrylate, octadecyl (meth)acrylate, cyclohexyl (meth)acrylate, methoxyethyl (meth)acrylate, butoxyethyl (meth)acrylate, phenoxyethyl (meth)acrylate, nonylphenoxyethyl (meth)acrylate, glycidyl (meth)acrylate, dimethylaminoethyl (meth)acrylate, diethylaminoethyl (meth)acrylate, isobornyl (meth)acrylate, dicyclopentanyl (meth)acrylate, dicyclopentenyl (meth)acrylate, dicyclopentenyloxyethyl (meth)acrylate, 2-hydroxy-3-phenoxypropyl (meth)acrylate, tetrahydrofurfuryl (meth)acrylate, 2-hydroxyethyl (meth)acrylate, benzyl (meth)acrylate, phenyl(meth)acrylate, mono(2-acryloyloxyethyl) succinate, N-[2-(acryloyloxy)ethyl]phthalimide, N-[2-(acryloyloxy)ethyl]tetrahydrophthalimide, 2-(2-vinyloxyethoxy)ethyl (meth)acrylate, ω-carboxy-polycaprolactone monoacrylate, ethylcarbitol (meth)acrylate (ethoxyethoxyethyl (meth)acrylate), and 3,3,5-trimethylcyclohexyl (meth)acrylate.

Examples of the compound (B-2) include diethylene glycol di(meth)acrylate, triethylene glycol di(meth)acrylate, polyethylene glycol di(meth)acrylate, 1,3-butylene glycol di(meth)acrylate, 1,4-butanediol di(meth)acrylate, 1,5-pentanediol di(meth)acrylate, 3-methyl-1,5-pentanediol di(meth)acrylate, 1,6-hexanediol di(meth)acrylate, neopentyl glycol di(meth)acrylate, 1,8-octanediol di(meth)acrylate, 1,9-nonanediol di(meth)acrylate, tricyclodecanedimethanol di(meth)acrylate, ethylene glycol di(meth)acrylate, polyethylene glycol di(meth)acrylate, propylene glycol di(meth)acrylate, dipropylene glycol di(meth)acrylate, tripropylene glycol di(meth)acrylate, polypropylene glycol di(meth)acrylate, neopentyl glycol hydroxypivalate ester di(meth)acrylate, di(meth)acrylate obtained by replacing two hydroxy groups of tris(2-hydroxyethyl)isocyanurate by (meth)acryloyloxy groups, di(meth)acrylate obtained by adding four or more moles of ethylene oxide or propylene oxide to one mole of neopentyl glycol to obtain a diol and replacing two hydroxy groups of the diol by (meth)acryloyloxy groups, di(meth)acrylate obtained by adding two moles of ethylene oxide or propylene oxide to one mole of bisphenol A to obtain a diol and replacing two hydroxy groups of the diol by (meth)acryloyloxy groups, di(meth)acrylate obtained by adding three or more moles of ethylene oxide or propylene oxide to one mole of trimethylolpropane to obtain a triol and replacing two hydroxy groups of the triol by (meth)acryloyloxy groups, and di(meth)acrylate obtained by adding four or more moles of ethylene oxide or propylene oxide to one mole of bisphenol A to obtain a diol and replacing two hydroxy groups of the diol by (meth)acryloyloxy groups.

Examples of the compound (B-3) include glycerol tri(meth)acrylate, trimethylolpropane tri(meth)acrylate, pentaerythritol tri(meth)acrylate, pentaerythritol tetra(meth)acrylate, dipentaerythritol penta(meth)acrylate, dipentaerythritol hexa(meth)acrylate, tripentaerythritol octa(meth)acrylate, tripentaerythritol hepta(meth)acrylate, tetrapentaerythritol deca(meth)acrylate, tetrapentaerythritol nona(meth)acrylate, tris(2-(meth)acryloyloxyethyl)isocyanurate, ethylene glycol-modified pentaerythritol tetra(meth)acrylate, ethylene glycol-modified trimethylolpropane tri(meth)acrylate, ethoxylated trimethylolpropane tri(meth)acrylate, ethylene glycol-modified dipentaerythritol hexa(meth)acrylate, ethoxylated dipentaerythritol hexa(meth)acrylate, propylene glycol-modified pentaerythritol tetra(meth)acrylate, propylene glycol-modified dipentaerythritol hexa(meth)acrylate, caprolactone modified pentaerythritol tetra(meth)acrylate, caprolactone modified dipentaerythritol hexa(meth)acrylate, monosuccinate of pentaerythritol triacrylate, mono succinate of dipentaerythritol pentaacrylate, monomaleate of pentaerythritol triacrylate, and monomaleate of dipentaerythritol pentaacrylate.

Examples of the cationically photopolymerizable compound include a compound having at least one oxetane ring (4-membered ring ether) per molecule (hereinafter simply referred to as “oxetane compound”), a compound having at least one oxirane ring (3-membered ring ether) per molecule (hereinafter simply referred to as “epoxy compound”), and a vinyl ether compound.

Examples of the oxetane compound include 3-ethyl-3-hydroxymethyloxetane, 1,4-bis[(3-ethyl-3-oxetanyl) methoxymethyl]benzene, 3-ethyl-3-(phenoxymethyl)oxetane, di[(3-ethyl-3-oxetanyl)methyl]ether, 3-ethyl-3-(2-ethylhexyloxymethyl)oxetane, and phenolic novolac oxetane. These oxetane compounds can be easily obtained as commercially available products, and examples of the commercially available products include “ARON OXETANE (registered trademark) OXT-101”, “ARON OXETANE (registered trademark) OXT-121”, “ARON OXETANE (registered trademark) OXT-211”, “ARON OXETANE (registered trademark) OXT-221”, and “ARON OXETANE (registered trademark) OXT-212”, which are all product names and manufactured by TOAGOSEI CO., LTD.

Examples of the epoxy compound include an aromatic epoxy compound, a glycidyl ether of a polyol having an alicyclic ring, an aliphatic epoxy compound, and an alicyclic epoxy compound.

Examples of the aromatic epoxy compound include a bisphenol epoxy resin, such as diglycidyl ether of bisphenol A, diglycidyl ether of bisphenol F, and diglycidyl ether of bisphenol S; a novolac epoxy resin, such as a phenolic novolac epoxy resin, a cresol novolac epoxy resin, and a hydroxybenzaldehyde phenolic novolac epoxy resin; and a multifunctional epoxy resin, such as glycidyl ether of tetrahydroxyphenylmethane, glycidyl ether of tetrahydroxybenzophenone, and epoxidized polyvinylphenol.

Examples of the glycidyl ether of a polyol having an alicyclic ring include that obtained by selectively hydrogenating the aromatic ring of an aromatic polyol under pressure in the presence of a catalyst to thereby obtain a nuclear-hydrogenated polyhydroxy compound, and subjecting the compound to glycidyl etherification. Examples of the aromatic polyol include a bisphenol compound, such as Bisphenol A, Bisphenol F, and Bisphenol S; a novolac resin, such as a phenolic novolac resin, a cresol novolac resin, and a hydroxybenzaldehyde phenolic novolac resin; and a polyfunctional compound, such as tetrahydroxydiphenylmethane, tetrahydroxybenzophenone, and polyvinylphenol. An alicyclic polyol obtained by hydrogenating the aromatic ring of any of these aromatic polyols can be reacted with epichlorohydrin to thereby obtain a glycidyl ether. Among these glycidyl ether of a polyol having an alicyclic ring, diglycidyl ether of hydrogenated bisphenol A is preferable.

Examples of the aliphatic epoxy compound include a polyglycidyl ether of an aliphatic polyhydric alcohol or an alkylene oxide adduct thereof. Specific examples include diglycidyl ether of 1,4-butanediol; diglycidyl ether of 1,6-hexanediol; triglycidyl ether of glycerin; triglycidyl ether of trimethylolpropane; diglycidyl ether of polyethylene glycol; diglycidyl ether of propylene glycol; diglycidyl ether of neopentyl glycol; and a polyglycidyl ether of polyether polyol obtained by adding one or more alkylene oxides (such as ethylene oxide and propylene oxide) to an aliphatic polyhydric alcohol such as ethylene glycol, propylene glycol or glycerin.

The alicyclic epoxy compound is a compound having at least one structure in which carbon atoms of an alicyclic ring also forms an oxirane ring, per molecule. “CELLOXIDE” series and “CYCLOMER” (all manufactured by DAICEL CORPORATION) and “CYRACURE UVR” series (manufactured by The Dow Chemical Company) can be used.

Examples of the vinyl ether compound include 2-hydroxyethyl vinyl ether, triethylene glycol vinyl monoether, tetraethylene glycol divinyl ether, and trimethylolpropane trivinyl ether.

The photopolymerizable compound preferably includes the polyfunctional (meth)acrylate monomer having three or more (meth)acryloyloxy groups per molecule (the compound (B-3)). When the curable composition includes the compound (B-3), the heat resistance and mechanical strength of the curable composition and the cured film can be larger, and furthermore, the compound (B-3) may be advantageous in terms of view of improvement in the emission intensity of the curable composition and the cured film. In addition, when the curable composition include the compound (B-3), the curable composition may has improved curability.

Examples of the compound (B-3) include a compound having three or more (meth)acryloyloxy groups per molecule and having an acid functional group, (B-3a); and a compound having three or more (meth)acryloyloxy groups per molecule and having no acid functional group, (B-3b). The photopolymerizable compound preferably includes at least one of the compound (B-3a) and the compound (B-3b), and may include two or more compounds (B-3a), two or more compounds (B-3b), or at least one compound (B-3a) and at least one compound (B-3b).

The curable composition preferably includes the compound (B-3a) as the photopolymerizable compound. When the curable composition includes the compound (B-3a), aggregation of the semiconductor particle (A) can be suppressed to improve the dispersibility of the semiconductor particle (A), and as a result, the curable composition and the cured film may have improved emission intensity. In addition, when the curable composition includes the compound (B-3a), the curable composition may have improved curability. Furthermore, when the curable composition includes the compound (B-3a), the curable composition and the cured film may have improved heat resistance.

Examples of the acid functional group include a carboxy group, a sulfonic acid group, and a phosphoric acid group. The acid functional group is preferably a carboxy group among these.

The number of the (meth)acryloyloxy groups per molecule of the compound (B-3) is, for example, 3 or more and 6 or less, preferably 3 or more and 5 or less, more preferably 3. The number of the acid functional groups per molecule of the compound (B-3a) is, for example, 1 or more, preferably 1. In a case where the compound (B-3a) has two or more acid functional groups, the acid functional groups may be different or the same, and the compound (B-3a) preferably has at least one carboxy group.

Examples of the compound (B-3a) include a compound obtained by esterifying a dicarboxylic acid and a compound having three or more (meth)acryloyloxy groups and a hydroxy group, such as pentaerythritol tri(meth)acrylate or dipentaerythritol penta(meth)acrylate. Examples thereof include a monoester compound between pentaerythritol tri(meth)acrylate and succinic acid, a monoester compound between dipentaerythritol penta(meth)acrylate and succinic acid, a monoester compound between pentaerythritol tri(meth)acrylate and maleic acid, and a monoester compound between dipentaerythritol penta(meth)acrylate and maleic acid. Among these, preferred is the monoester compound between pentaerythritol tri(meth)acrylate and succinic acid.

Examples of commercially available products of the compound (B-3a) include “ARONIX M-510”, which includes as the main component dibasic acid anhydride adduct of a pentaerythritol tri(meth)acrylate and is manufactured by TOAGOSEI CO., LTD., and “ARONIX M-520D”, which include as the main component a dibasic acid anhydride adduct of dipentaerythritol penta(meth)acrylate and is manufactured by TOAGOSEI CO., LTD. These commercially available products have a carboxy group as the acid functional group.

When the photopolymerizable compound includes the compound (B-3) (preferably the compound (B-3a)), the content ratio of the compound (B-3) is preferably 5, by mass or more, more preferably 10% by mass or more, even more preferably 15% by mass or more, and preferably 70% by mass or less, more preferably 60% by mass or less, even more preferably 50% by mass or less, still more preferably 40% by mass or less, particularly preferably 30% by mass or less, based on the total amount of the photopolymerizable compound, in view enhancing curability of the curable composition, and heat resistance, the emission intensity, etc. of the curable composition and the cured film.

When the photopolymerizable compound includes the compound (B-3) (preferably the compound (B-3a)), the content ratio of the compound (B-3) is preferably 0.1% by mass or more and 50% by mass or less, more preferably 1% by mass or more and 40% by mass or less, even more preferably 2% by mass or more and 30% by mass or less, still more preferably 5% by mass or more and 20% by mass or less, particularly preferably 5% by mass or more and 15% by mass or less, based on the total amount of the curable composition or the total amount of the solids content of the curable composition, in view enhancing curability of the curable composition, and heat resistance, the emission intensity, etc. of the curable composition and the cured film.

When the photopolymerizable compound includes the compound (B-3) (preferably the compound (B-3a)), the content of the compound (B-3) is preferably 15 parts by mass or more, more preferably 25 parts by mass or more, even more preferably 30 parts by mass or more, still more preferably 35 parts by mass or more, and preferably 110 parts by mass or less, more preferably 100 parts by mass or less, even more preferably 85 parts by mass or less, still more preferably 70 parts by less or more, based on 100 parts by mass of the semiconductor particle (A).

The photopolymerizable compound preferably includes a (meth)acrylate monomer having a vinylether group and a (meth)acryloyl group (preferably (meth)acryloyloxy group) in the same molecule (hereinafter, also referred to as “compound (B-4)”). When the curable composition includes the compound (B-4), aggregation of the semiconductor particle (A) can be suppressed to improve the dispersibility of the semiconductor particle (A), and as a result, the emission intensity of the curable composition and the cured film may be improved. In addition, when the curable composition includes the compound (B-4), the curable composition can have a reduced viscosity and therefore improved applicability. The compound (B-4) may be a compound that belongs any of the compound (B-1) to compound (B-3).

The number of the vinylether groups of the compound (B-4) is preferably 1 or more and 4 or less, more preferably 1 or more and 2 or less, particularly preferably 1. The number of the (meth)acryloyl groups of the compound (B-4) is preferably 1 or more and 4 or less, more preferably 1 or more and 2 or less, particularly preferably 1.

Examples of the compound (b-4) include 2-vinyloxyethyl (meth)acrylate, 3-vinyloxypropyl (meth)acrylate, 2-vinyloxypropyl (meth)acrylate, 1-vinyloxypropyl (meth)acrylate, 1-methyl-2-vinyloxyethyl (meth)acrylate, 4-vinyloxybutyl (meth)acrylate, 3-vinyloxybutyl (meth)acrylate, 2-vinyloxybutyl (meth)acrylate, 1-methyl-3-vinyloxypropyl (meth)acrylate, 2-methyl-3-vinyloxypropyl (meth)acrylate, 1-methyl-2-vinyloxypropyl (meth)acrylate, 1,1-dimethyl-2-vinyloxyethyl (meth)acrylate, 6-vinyloxyhexyl (meth)acrylate, 4-vinyloxycyclohexyl (meth)acrylate, (4-vinyloxymethylcyclohexyl)methyl (meth)acrylate, (3-vinyloxymethylcyclohexyl)methyl (meth)acrylate, (2-vinyloxymethylcyclohexyl)methyl(meth)acrylate, (4-vinyloxymethylphenyl)methyl (meth)acrylate, (3-vinyloxymethylphenyl)methyl (meth)acrylate, 2-vinyloxymethylphenylmethyl (meth)acrylate, 2-(2-vinyloxyisopropoxy)ethyl (meth)acrylate, 2-(2-vinyloxyethoxy)ethyl (meth)acrylate, 2-(2-vinyloxyethoxy)propyl (meth)acrylate, 2-(2-vinyloxyisopropoxy)propyl (meth)acrylate, 2-(2-vinyloxyethoxy)isopropyl (meth)acrylate, 2-(2-vinyloxyisopropoxy)isopropyl (meth)acrylate, 2-{2-(2-vinyloxyethoxy)ethoxy}ethyl (meth)acrylate, 2-{2-(2-vinyloxyisopropoxy)ethoxy}ethyl (meth)acrylate, 2-{2-(2-vinyloxyisopropoxy)isopropoxy}ethyl (meth)acrylate, 2-{2-(2-vinyloxyethoxy)ethoxy}propyl (meth)acrylate, 2-{2-(2-vinyloxyethoxy)isopropoxy}propyl (meth)acrylate, 2-{2-(2-vinyloxyisopropoxy)ethoxy}propyl (meth)acrylate, 2-{2-(2-vinyloxyisopropoxy)isopropoxy}propyl (meth)acrylate, 2-{2-(2-vinyloxyethoxy)ethoxy}isopropyl (meth)acrylate, 2-{2-(2-vinyloxyethoxy)isopropoxy}isopropyl (meth)acrylate, 2-{2-(2-vinyloxyisopropoxy)ethoxy}isopropyl (meth)acrylate, 2-{2-(2-vinyloxyisopropoxy)isopropoxy}isopropyl (meth)acrylate, 2-[2-{2-(2-vinyloxyethoxy)ethoxy}ethoxy]ethyl (meth)acrylate, 2-[2-{2-(2-vinyloxyisopropoxy)ethoxy}ethoxy]ethyl (meth)acrylate, 2-(2-[2-{2-(2-vinyloxyethoxy)ethoxy}ethoxy]ethoxy)ethyl (meth)acrylate.

The compound (B-4) is preferably vinyloxy C₁₋₆alkyl(meth)acrylate or (vinyloxy C₁₋₆alkoxy)C₁₋₄ alkyl(meth)acrylate, more preferably (vinyloxy C₁₋₄alkoxy)C₁₋₄alkyl(meth)acrylate, particularly preferably 2-(2-vinyloxyethoxy)ethyl (meth)acrylate.

In a case where the photopolymerizable compound includes the compound (B-4), the content ratio of the compound (B-4) is preferably 5% by mass or more, more preferably 10% by mass or more, even more preferably 20% by mass or more, still more preferably 25% by mass or more, and preferably 85% by mass or less, more preferably 75% by mass or less, even more preferably 65% by mass or less, still more preferably 60% by mass or less, particularly preferably 55% by mass or less, based on the total amount of the photopolymerizable compound, in view of, for example, reducing the viscosity of the curable composition and enhancing the emission intensity of the cured film.

In a case where the photopolymerizable compound includes the compound (B-4), the content ratio of the compound (B-4) is preferably 3% by mass or more and 50% by mass or less, more preferably 5% by mass or more and 45% by mass or less, even more preferably 10% by mass or more and 40% by mass or less, still more preferably 15% by mass or more and 35% by mass or less, based on the total amount of the photopolymerizable compound or the total amount of the solids content of the curable composition, in view of, for example, reducing the viscosity of the curable composition and enhancing the emission intensity of the curable composition and the cured film.

In a case where the photopolymerizable compound includes the compound (B-4), the content of the compound (B-4) is preferably 30 parts by mass or more, more preferably 40 parts by mass or more, even more preferably 50 parts by mass or more, still more preferably 60 parts by mass or more, and preferably 200 parts by mass or less, more preferably 180 parts by mass or less, even more preferably 150 parts by mass or less, still more preferably 130 parts by mass or less, based on 100 parts by mass of the semiconductor particle (A).

The photopolymerizable compound preferably includes the monofunctional (meth)acrylate monomer having a single (meth)acryloyloxy group per molecule (the compound (B-1)). When the curable composition includes the compound (B-1), the curable composition can have a reduced viscosity and therefore the improved discharge characteristics.

In view of suppressing the generation of outgas as described above, the curable composition preferably includes a polymerizable compound that has a volatile content of 7, by mass or less when heated at 80° C. for 1 hour. In the same viewpoint, the photopolymerizable compound more preferably includes a compound that is a compound (B-1) and has a volatile content of 7% by mass or less when heated at 80° C. for 1 hour. The volatile content is preferably 5% by mass or less, more preferably 3% by mass or less, even more preferably 2% by mass or less, still more preferably 1% by mass or less, and may be 0.01% by mass or more or 0.1% by mass or more. The volatile content when heated at 80° C. for 1 hour can be determined by the method described in the section of Examples later.

In view of obtaining the curable composition and the cured film having favorable emission intensity, the curable composition preferably includes a polymerizable compound of which homopolymer has a glass transition temperature of −50° C. or more. In the same viewpoint, the photopolymerizable compound more preferably includes a compound that is a compound (B-1) of which homopolymer has a glass transition temperature of −50° C. or more. The glass transition temperature is preferably −30° C. or more, more preferably −20° C. or more, and may be 0° C. or more, and be 200° C. or less. As the glass transition temperature, a numerical value described in a catalog or a general table of physical properties may be used, or the glass transition temperature may be determined by, for example, a commercially available differential scanning calorimeter.

The curable composition preferably includes a polymerizable compound having a molecular weight of 120 or more and 280 or less in view of suppressing the generation of the outgas as described above. In the same viewpoint, the photopolymerizable compound more preferably includes a compound that is a compound (B-1) and has a molecular weight of 120 or more and 280 or less.

In view of obtaining the curable composition and the cured film having favorable emission intensity, it is preferable that the curable composition should include a compound (B-1), and that in the compound (B-1), the group bonded to the (meth)acryloyloxy group is a hydrocarbon group free of hetero atoms such as an oxygen atom or nitrogen atom. The hydrocarbon group is more preferably a linear hydrocarbon group or an alicyclic hydrocarbon group.

In a case where the photopolymerizable compound includes the compound (B-1), the content ratio of the compound (B-1) is preferably 5, by mass or more, more preferably 10% by mass or more, even more preferably 15% by mass or more, still more preferably 20% by mass or more, particularly preferably 25% by mass or more, and preferably 75% by mass or less, more preferably 65% by mass or less, even more preferably 60% by mass or less, still more preferably 55% by mass or less, particularly preferably 50, by mass or less, based on the total amount of the photopolymerizable compound, in view of a reduced viscosity of the curable composition, for example.

In a case where the photopolymerizable compound includes the compound (B-1), the content ratio of the compound (B-1) is preferably 5% by mass or more and 50% by mass or less, more preferably 8% by mass or more and 45% by mass or less, even more preferably 10% by mass or more and 40% by mass or less, still more preferably 15% by mass or more and 35% by mass or less, based on the total amount of the curable composition or the total amount of the solids content of the curable composition, in view of a reduced viscosity of the curable composition, for example.

The content ratio of the polymerizable compound (B), M_{B}, is preferably 10% by mass or more and 90% by mass or less, more preferably 20, by mass or more and 80% by mass or less, even more preferably 30% by mass or more and 75%, by mass or less, still more preferably 40% by mass or more and 70% by mass or less, particularly preferably 50% by mass or more and 70% by mass or less, based on the total amount of the curable composition.

The content ratio of the polymerizable compound (B) is preferably 10% by mass or more and 90% by mass or less, more preferably 20% by mass or more and 80% by mass or less, even more preferably 30% by mass or more and 75% by mass or less, still more preferably 40% by mass or more and 70% by mass or less, particularly preferably 50% by mass or more and 70% by mass or less, based on the total amount of the solids content of the curable composition.

The polymerizable compound (B) preferably includes at least one compound selected from the group consisting of the compound (B-1), the compound (B-3), and the compound (B-4), more preferably includes at least one compound selected from the group consisting of the compound (B-1), the compound (B-3a), and the compound (B-4), even more preferably includes the compound (B-3a) and the compound (B-4), and particularly preferably includes all of the compound (B-1), the compound (B-3a), and the compound (B-4).

The polymerizable compound (B) preferably includes all of the compound (B-1), the compound (B-3a), and the compound (B-4), wherein the compound (B-1) satisfies at least one of the following:
the compound (B-1) is a compound having a volatile content of 7, by mass or less when heated at 80° C. for 1 hour;
the compound (B-1) is a compound of which homopolymer has a glass transition temperature of −50° C. or more;
the compound (B-1) has a molecular weight of 120 or more and 280 or less; and
the compound (B-1) is a compound in which the group bonded to the (meth)acryloyloxy group is a hydrocarbon group free of hetero atoms.

### [3] Polymerization Initiator (C)

The curable composition contains a polymerization initiator (C). The polymerization initiator (C) is a compound that may generate, for example, an active radical or an acids by action of light or heat to initiate polymerization of the polymerizable compound (B). The curable composition can contain one or more types of the polymerization initiators (C).

Examples of the polymerization initiator (C) include a photopolymerization initiator, such as an oxime compound, an alkylphenone compound, a bimidazole compound, a triazine compound, and an acylphosphine compound, and a thermal polymerization initiator, such as an azo compound and an organic peroxide.

An example of the oxime compound is an oxime compound having the first molecular structure represented by the formula (1) below. This oxime compound will be hereinafter also referred to as “oxime compound (1)”.

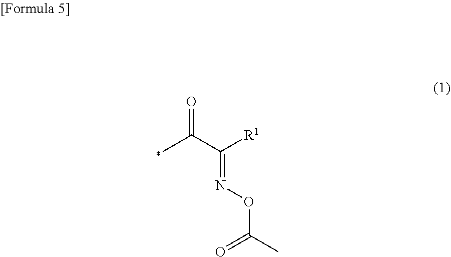

Including the oxime compound (1) as the polymerization initiator (C) is advantageous in terms of view of enhancing the emission intensity of the curable composition and the cured film. One reason for exhibiting such an effect is inferred as follows: due to the characteristic molecular structure of the oxime compound (1), the absorption wavelength of the oxime compound (1) significantly changes before and after cleavage (decomposition), which is necessary to initiate photopolymerization by the oxime compound (1), and the oxime compound (1) thus has the large capability of initiating radical photopolymerization.

In the formula (1), R¹ represents R¹¹, OR¹¹, COR¹¹, SR¹¹, CONR¹²R¹³, or CN.

R¹¹, R¹², and R³ each independently represent a hydrogen atom, an alkyl group having 1 to 20 carbon atoms, an aryl group having 6 to 30 carbon atoms, an aralkyl group having 7 to 30 carbon atoms, or a heterocyclic group having 2 to 20 carbon atoms.

A hydrogen atom of the group represented by R¹¹, R¹², or R¹³ is optionally replaced by OR²¹, COR²¹, SR²¹, NR²²Ra²³, CONR²²R²³, —NR²², —OR²³, —N(COR²²)—OCOR²³, —C(═N—OR²¹)—R²², —C(═N—OCOR²¹)—R²², CN, a halogen atom, or COOR²¹.

R²¹, R²², and R²³ each independently represent a hydrogen atom, an alkyl group having 1 to 20 carbon atoms, an aryl group having 6 to 30 carbon atoms, an aralkyl group having 7 to 30 carbon atoms, or a heterocyclic group having 2 to 20 carbon atoms.

A hydrogen atom of the group represented by R²¹, R²², or R²³ is optionally replaced by CN, a halogen atom, a hydroxy group, or a carboxy group.

In a case where the group represented by R¹¹, R¹², R¹³, R²¹, R²², or R²³ has an alkylene moiety, the alkylene moiety may be interrupted 1 to 5 times by —O—, —S—, —COO—, —OCO—, —NR²⁴—, —NR²⁴CO—, —NR²⁴COO—, —OCONR²⁴—, —SCO—, —COS—, —OCS—, or —CSO—.

R²⁴ represents a hydrogen atom, an alkyl group having 1 to 20 carbon atoms, an aryl group having 6 to 30 carbon atoms, an aralkyl group having 7 to 30 carbon atoms, or a heterocyclic group having 2 to 20 carbon atoms.

In a case where the group represented by R¹¹, R¹², R¹³, R²¹, R²², or R²³ has an alkyl moiety, the alkyl moiety may be branched or cyclic, and R¹² and R¹³, or R²² and R²³ may together form a ring.
* represent a bond to the second molecular structure, which is another molecular structure different from the first molecular structure of the oxime compound (1).

Examples of the alkyl group having 1 to 20 carbon atoms represented by R¹¹, R¹², R¹³, R²¹, R²², R²³, and R²⁴ in the formula (1) include a methyl group, an ethyl group, a propyl group, an isopropyl group, a butyl group, an isobutyl group, a sec-butyl group, a tert-butyl group, a pentyl group, an isopentyl group, a tert-pentyl group, a hexyl group, a heptyl group, an octyl group, an isooctyl group, a 2-ethylhexyl group, a tert-octyl group, a nonyl group, an isononyl group, a decyl group, an isodecyl group, an undecyl group, a dodecyl group, a tetradecyl group, a hexadecyl group, an octadecyl group, an icosyl group, a cyclopentyl group, a cyclohexyl group, a cyclohexylmethyl group, and a cyclohexylethyl group.

Examples of the aryl group having 6 to 30 carbon atoms represented by R¹¹, R¹², R¹³, R²¹, R²², R²³, and R²⁴ in the formula (1) include a phenyl group, a tolyl group, a xylyl group, an ethylphenyl group, a naphthyl group, an anthryl group, a phenanthryl group, and a phenyl group, a biphenyl group, a naphthyl group, and an anthryl group substituted with one or more aforementioned alkyl groups.

Examples of the aralkyl group having 7 to 30 carbon atoms represented by R¹¹, R¹², R¹³, R²¹, R²², R²³, and R²⁴ in the formula (1) include a benzyl group, an α-methylbenzyl group, an α,α-dimethylbenzyl group, and a phenylethyl group.

Examples of the heterocyclic group having 2 to 20 carbon atoms represented by R¹¹, R¹², R¹³, R²¹, R²², R²³, and R²⁴ in the formula (1) include a pyridyl group, a pyrimidyl group, a furyl group, a thienyl group, a tetrahydrofuryl group, a dioxolanyl group, a benzoxazol-2-yl group, a tetrahydropyranyl group, a pyrrolidyl group, an imidazolidyl group, a pyrazolidyl group, a thiazolidyl group, an isothiazolidyl group, an oxazolidyl group, an isoxazolidyl group, a piperidyl group, a piperazyl group, and a morpholinyl group, and the heterocyclic group is preferably a 5- to 7-membered heterocyclic ring.

For the formula (1), the phrase “R¹² and R¹³, or R²² and R²³ may together form a ring” means that R¹² and R¹³, or R²² and R²³, together with the nitrogen atom, carbon atom, or oxygen atom bonded thereto, may form a ring.

Examples of the ring that may be formed by R¹² and Ra¹³, or Ra²² and Ra²³, together in the formula (1) include a cyclopentane ring, a cyclohexane ring, a cyclopentene ring, a benzene ring, a piperidine ring, a morpholine ring, a lactone ring, and a lactam ring, and the ring is preferably a 5- to 7-membered ring.

Example of the halogen atom R¹¹, R¹², R¹³, R²¹, R²², and R²³ in the formula (1) optionally has as a substituent include a fluorine atom, a chlorine atom, a bromine atom, and an iodine atom.

R¹ in the formula (1) is preferably R¹¹, more preferably an alkyl group having 1 to 20 carbon atoms, even more preferably an alkyl group having 1 to 10 carbon atoms, still more preferably an alkyl group having 1 to 6 carbon atoms.

One example of the second molecular structure bonded to the first molecular structure represented by the formula (1) is the structure represented by the formula (2). The second molecular structure is the molecular structure moiety other than the first molecular structure in the oxime compound (1).

The bond represented by “*” in the formula (2) is directly bonded to the bond represented by “*” in the formula (1). In other words, when the second molecular structure is the structure represented by the formula (2), the benzene ring having “-*” in the formula (2) is directly bonded to the carbonyl group having “-*” in the formula (1).

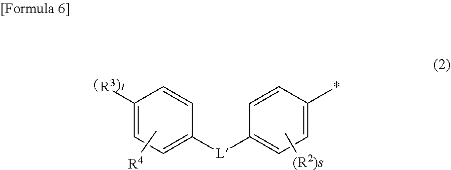

In the formula (2), R² and R³ each independently represent R¹¹, OR¹¹, SR¹¹, COR¹¹, CONR¹²R¹³, NR¹²COR¹¹, OCOR¹¹, COOR¹¹, SCOR¹¹, OCSR¹¹, COSR¹¹, CSOR¹¹, CN, or a halogen atom.

When a plurality of R² are present, they may be the same or different.

When a plurality of R³ are present, they may be the same or different.

R¹¹, R¹², and R¹³ each have the same meaning as above described.

s and t each independently represent an integer of 0 to 4.

L represents a sulfur atom, CR³¹R³², CO, or NR³³.

R³¹, R³², and R³³ each independently represent a hydrogen atom, an alkyl group having 1 to 20 carbon atoms, an aryl group having 6 to 30 carbon atoms, or an aralkyl group having 7 to 30 carbon atoms.

When the group represented by R³¹, R³², or R³³ has an alkyl moiety, the alkyl moiety may be branched or cyclic, and R³¹, R³², and R³³ may each independently, together with either adjacent benzene ring, form a ring.

R⁴ represents a hydroxy group, a carboxy group, or a group represented by the following formula (2-1):

[Formula 7]

(R^{4a})_{y}-L²-L¹- (2-1)
wherein L¹ represents —O—, —S—, —NR²², —NR²²CO—, —SO₂—, —CS—, —OCO—, or —COO—,
R²² has the same meaning as above described,
L² represents a group formed by removing a number v of hydrogen atoms from an alkyl group having 1 to 20 carbon atoms, a group formed by removing a number v of hydrogen atoms from an aryl group having 6 to 30 carbon atoms, a group formed by removing a number v of hydrogen atoms from an aralkyl group having 7 to 30 carbon atoms, or a group formed by removing a number v of hydrogen atoms from a heterocyclic group having 2 to 20 carbon atoms,
when the group represented by L² has an alkylene moiety, the alkylene moiety may be interrupted 1 to 5 times by —O—, —S—, —COO—, —OCO—, —NR²²—, —NR²²COO—, —OCONR²²—, —SCO—, —COS—, —OCS—, or —CSO—, and the alkylene moiety may be branched or cyclic,
R^{4a} represents OR⁴¹, SR⁴¹, CONR⁴²R⁴³, NR⁴²COR⁴³, OCOR⁴¹, COOR⁴¹, SCOR⁴¹, OCSR⁴¹, COSR⁴³, CSOR⁴¹, CN, or a halogen atom,
when a plurality of R^{4a} are present, they may be the same or different,
R⁴¹, R⁴², and R⁴³ each independently represent a hydrogen atom, an alkyl group having 1 to 20 carbon atoms, an aryl group having 6 to 30 carbon atoms, or an aralkyl group having 7 to 30 carbon atoms; when the group represented by R⁴¹, R², or R¹³ has an alkyl moiety, the alkyl moiety may be branched or cyclic, and R⁴ and R⁴³ may together form a ring, and
v represents an integer of 1 to 3.
* represents a bond to the first molecular structure of the oxime compound (1).

For the alkyl group having 1 to 20 carbon atoms, the aryl group having 6 to 30 carbon atoms, or the aralkyl group having 7 to 30 carbon atoms represented by R¹¹, R¹², R¹³, R²¹, R²², R²³, R²⁴, R³¹, R and R³³ in the formula (2), and R²², R⁴¹, R⁴², and R⁴³ in the formula (2-1), examples thereof include those listed for R¹¹, R¹², R¹³, R²¹, R²², R²³, and R²⁴ in the formula (1).

For the heterocyclic group having 2 to 20 carbon atoms represented by R¹¹, R¹², R¹³, R²¹, R²², R²³, and R²⁴ in the formula (2), and R²² in the formula (2-1), examples thereof include those listed for R¹¹, R¹², R¹³, R²¹, R²², R²³, and R²⁴ in the formula (1).

For the formula (2), the phrase “R³¹, R³², and R³³ may each independently, together with either adjacent benzene ring, form a ring” means R³¹, R³², and R³³ each independently, together with either adjacent benzene ring and also with the nitrogen atom or carbon atom bonded thereto, may form a ring.

Examples of the ring that may be formed by R³¹, R³², or R³³ together with either adjacent benzene ring in the formula (2) include those listed for the ring that may be formed by Ra¹² and Ra¹³, or Ra²² and Ra²³, together in the formula (1).

L² in the formula (2-1) represents a group formed by removing a number v of hydrogen atoms from an alkyl group having 1 to 20 carbon atoms, an aryl group having 6 to 30 carbon atoms, an aralkyl group having 7 to 30 carbon atoms, or a heterocyclic group having 2 to 20 carbon atoms.

Examples of the group formed by removing a number v of hydrogen atoms from an alkyl group having 1 to 20 carbon atoms when v is 1 include alkylene groups such as a methylene group, an ethylene group, a propylene group, a methylethylene group, a butylene group, a 1-methylpropylene group, a 2-methylpropylene group, a 1,2-dimethylpropylene group, a 1,3-dimethylpropylene group, a 1-methylbutylene group, a 2-methylbutylene group, a 3-methylbutylene group, a 4-methylbutylene group, a 2,4-dimethylbutylene group, a 1,3-dimethylbutylene group, a pentylene group, a hexylene group, a heptylene group, an octylene group, a nonylene group, a decylene group, a dodecylene group, a tridecylene group, a tetradecylene group, a pentadecylene group, an ethane-1,1-diyl group, and a propane-2,2-diyl group.

Examples of the group formed by removing a number v of hydrogen atoms from an aryl group having 6 to 30 carbon atoms when v is 1 include arylene groups such as a 1,2-phenylene group, a 1,3-phenylene group, a 1,4-phenylene group, a 2,6-naphthylene group, a 1,4-naphthylene group, a 2,5-dimethyl-1,4-phenylene group, an diphenylmethane-4,4′-diyl group, a 2,2-diphenylpropane-4,4′-diyl group, a diphenylsulfide-4,4′-diyl group, and diphenylsulfone-4,4′-diyl group.

Examples of the group formed by removing a number v of hydrogen atoms from an aralkyl group having 7 to 30 carbon atoms when v is 1 include a group represented by the following formula (a) and a group represented by the following formula (b).

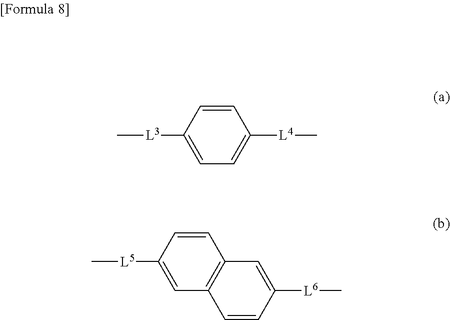

wherein L³ and L⁵ represent an alkylene group having 1 to 10 carbons, and L⁴ and L⁶ represent a single bond or an alkylene group with 1 to 10 carbons.

Examples of the alkylene group having 1 to 10 carbons include a methylene group, an ethylene group, a propylene group, a methyl ethylene group, a butylene group, a 1-methyl propylene group, a 2-methyl propylene group, a 1,2-dimethyl propylene group, a 1,3-dimethylpropylene group, a 1-methylbutylene group, a 2-methylbutylene group, a 3-methylbutylene group, a 4-methylbutylene group, a 2,4-dimethylbutylene group, a 1,3-dimethylbutylene group, a pentylene group, a hexylene group, a heptylene group, an octylene group, a nonylene group, and a decylene group.

Examples of the group formed by removing a number v of hydrogen atoms from a heterocyclic group having 2 to 20 carbon atoms when v is 1 include divalent heterocyclic groups such as a 2,5-pyridinediyl group, a 2,6-pyridinediyl group, a 2,5-pyrimidinediyl group, a 2,5-thiophenediyl group, a 3,4-tetrahydrofurandiyl group, a 2,5-tetrahydrofurandiyl group, a 2,5-furandiyl group, a 3,4-thiazolidiyl group, a 2,5-benzofuranediyl group, a 2,5-benzothiophenediyl group, an N-methylindole-2,5-diyl group, a 2,5-benzothiazoldiyl group, and a 2,5-benzoxazoldiyl group.

Examples of the halogen atom represented by R² or R³ in the formula (2) and R^{4a} in the formula (2-1) include a fluorine atom, a chlorine atom, a bromine atom, and an iodine atom.

A preferable example of the structure represented by the formula (2) is a structure represented by the formula (2a) below, in view of solubility in a solvent (F) and/or developability of the curable composition.

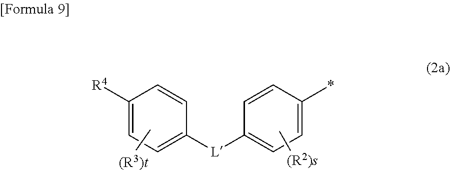

wherein L′ represents a sulfur atom or NR⁵⁰, and R⁵⁰ represents a linear, branched, or cyclic alkyl group having 1 to 20 carbon atoms, and R², R³, R⁴, s, and t have the same meaning as described above.

From the same viewpoint, another preferable example of the structure represented by the formula (2) is a structure represented by the following formula (2b):

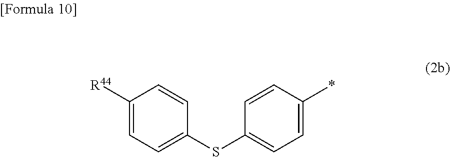

wherein R⁴⁴ represents a hydroxy group, a carboxy group, or a group represented by the following formula (2-2):

[Formula 11]

R^{44a}-L¹²-L¹¹- (2-2)
wherein L¹¹ represents —O— or *—OCO—, * represents the bond to L¹², L¹² represents an alkylene group having 1 to 20 carbons, the alkylene group may be interrupted 1 to 3 times by —O—, R^{44a} represents OR⁵⁵ or COOR⁵⁵, and R⁵⁵ represents a hydrogen atom or an alkyl group having 1 to 6 carbons.

R⁴ is preferably a group represented by the formula (2-2). This is advantageous in terms of solubility of the oxime compound (1) in a solvent (F) and developability of the curable composition.

The alkylene group represented by L¹² preferably has 1 to 10 carbon atoms, more preferably 1 to 4 carbon atoms.

R^{44a} is preferably a hydroxy group or a carboxy group, more preferably a hydroxy group.

The method for producing the oxime compound (1) having the second molecular structure represented by the formula (2) is not particularly limited, and such an oxime compound can be produced by a method described in JP 2011-132215A, for example.

Another example of the second molecular structure bonded to the first molecular structure represented by the formula (1) is a structure represented by the formula (3) below.

The bond represented by “*” in the formula (3) is directly bonded to the bond represented by “*” in the formula (1). In other words, when the second molecular structure is the structure represented by the formula (3), the benzene ring having “-*” in the formula (3) is directly bonded to the carbonyl group having “-*” in the formula (1).

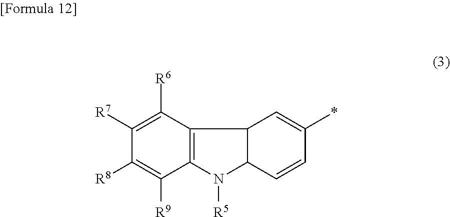

In the formula (3), R⁵ represents a hydrogen atom, an alkyl group having 1 to 20 carbon atoms, an aryl group having 6 to 30 carbon atoms, an arylalkyl group having 7 to 30 carbon atoms, or a heterocyclic group having 2 to 20 carbon atoms.

When the group represented by R⁵ has an alkyl moiety, the alkyl moiety may be branched or cyclic.

A hydrogen atom of the group represented by R⁵ is optionally replaced by R²¹, OR²¹, COR²¹, SR²¹, NR²²R²³, CONR²²R²³, —NR²²—OR²³, —N(COR²²)—OCOR²³, NR²²COR²¹, OCOR²¹, COOR²¹, —C(═N—OR²¹)—R²², —C(═N—OCOR²¹)—R²², SCOR²¹, OCSR²¹, COSR²¹, CSOR²¹, a hydroxy group, a nitro group, CN, a halogen atom, or COOR²¹.

R²¹, R²², and R²³ has the same meaning as described above.

A hydrogen atom of the group represented by R²¹, R²², or R²³ is optionally replaced by CN, a halogen atom, a hydroxy group, or a carboxy group.

When the group represented by R²¹, R²², or R²³ has an alkylene moiety, the alkylene moiety may be interrupted 1 to 5 times by —O—, —S—, —COO—, —OCO—, —NR²⁴—, —NR²⁴CO—, —NR²⁴COO—, —OCONR²⁴—, —SCO—, —COS—, —OCS—, or —CSO—.

R²⁴ has the same meaning as described above.

When the group represented by R²¹, R²², or R²³ has an alkyl moiety, the alkyl moiety may be branched or cyclic, and R²² and R²³ may together form a ring.

R⁶, R⁷, R⁸, and R⁹ each independently represent R⁶¹, OR⁶¹, SR⁶¹, COR⁶², CONR⁶³R⁶⁴, NR⁶⁵COR⁶¹, OCOR⁶¹, COOR⁶², SCOR⁶¹, OCSR⁶¹, COSR⁶², CSOR⁶¹, a hydroxy group, a nitro group, CN, or a halogen atom.

R⁶¹, R⁶², R⁶³, R⁶⁴, and R⁶⁵ each independently represent a hydrogen atom, an alkyl group having 1 to 20 carbon atoms, an aryl group having 6 to 30 carbon atoms, an arylalkyl group having 7 to 30 carbon atoms, or a heterocyclic group having 2 to 20 carbon atoms.

A hydrogen atom of the group represented by R⁶¹, R⁶², R⁶³, R⁶⁴, or R⁶⁵ is optionally replaced by OR²¹, COR²¹, SR²¹, NR²²Ra²³, CONR²²R²³, —NR²²—OR²³, —N(COR²²)—OCOR²³, —C(═N—OR²¹)—R²², —C(═N—OCOR²¹)—R²², CN, a halogen atom, or COOR²¹.

R⁶ and R⁷; R⁷ and R⁸; and R⁸ and R⁹ each may together form a ring.
* represents a bond to the first molecular structure of the oxime compound (1).

For the alkyl group having 1 to 20 carbon atoms, the aryl group having 6 to 30 carbon atoms, the aralkyl group having 7 to 30 carbon atoms, and the heterocyclic group having 2 to 20 carbon atoms represented by R⁵, R²¹, R²², R₂₃, R²⁴, R⁶¹, R⁶², R⁶³, R⁶⁴ or R⁶⁵ in the formula (3), examples thereof include those listed for R¹¹, R¹², R¹³, R¹¹, R²², R²³, and R²⁴ in the formula (1).

For the formula (3), the phrase “R²² and R²³ may together form a ring” means that R²² and R²³, together with the nitrogen atom, the carbon atom, or the oxygen atom bonded thereto, may form a ring.

Examples of the ring that may be formed by R²² and R²³ together include those listed for the ring that may be formed by Ra¹² and Ra¹³, or Ra²² and Ra²³ together in the formula (1).

Examples of the halogen atom represented by R⁶, R⁷, R⁸, or R⁹ and the halogen atom that may replace a hydrogen atom of R⁵, R²¹, R²², R²³, R⁶¹, R⁶², R⁶³, R⁶⁴, or R⁶⁵ in the formula (3) include a fluorine atom, a chlorine atom, a bromine atom, and an iodine atom.

In a preferable embodiment, R⁵ is a group represented by the formula (3-1) in view of solubility in a solvent (F) and/or developability of the curable composition.

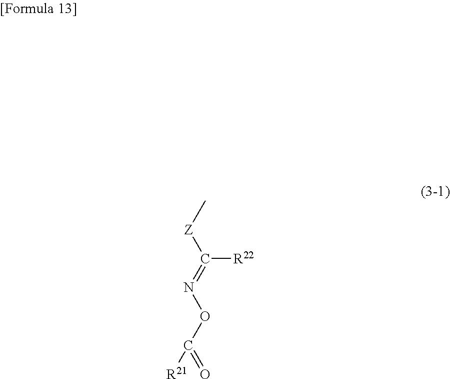

wherein Z represents a group formed by removing one hydrogen atom from an alkyl group having 1 to 20 carbon atoms, a group formed by removing one hydrogen atom from an aryl group having 6 to 30 carbon atoms, a group formed by removing one hydrogen atom from an aralkyl group having 7 to 30 carbon atoms, or a group formed by removing one hydrogen atom from a heterocyclic group having 2 to 20 carbon atoms,
when the group represented by Z has an alkylene moiety, the alkylene moiety may be interrupted 1 to 5 times by —O—, —S—, —COO—, —OCO—, —NR²⁴—, —NR²⁴COO—, —OCONR²⁴—, —SCO—, —COS—, —OCS—, or —CSO—, and the alkylene moiety may be branched or cyclic, and
R²¹, R²², and R²⁴ have the same meaning as described above.

From the same viewpoint, Z in the formula (3-1) is preferably a methylene group, an ethylene group, or a phenylene group.

From the same viewpoint, R²¹ and R²² in the formula (3-1) is preferably an alkyl group having 1 to 20 carbons or an aryl group having 6 to 30 carbons, and more preferably a methyl group, an ethyl group, or a phenyl group.

In another preferable embodiment, R⁷ is preferably a nitro group from the same viewpoint.

The method for producing the oxime compound (1) having the second molecular structure represented by the formula (3) is not particularly limited, and such an oxime compound can be produced by a method described in JP 2000-80068A or JP 2011-178776A, for example.

Still another example of the second molecular structure bonded to the first molecular structure represented by the formula (1) is a structure represented by the formula (4) below.

The bond represented by “*” in the formula (4) is directly bonded to the bond represented by “*” in the formula (1). In other words, when the second molecular structure is the structure represented by the formula (4), the benzene ring having “-*” in the formula (4) is directly bonded to the carbonyl group having “-*” in the formula (1).

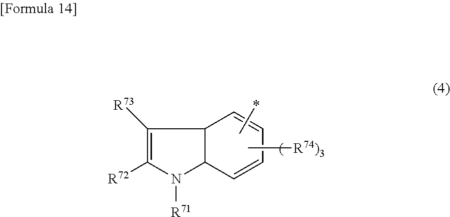

In the formula (4), R⁷¹ represents a hydrogen atom, an alkyl group having 1 to 20 carbon atoms, an aryl group having 6 to 30 carbon atoms, an aralkyl group having 7 to 30 carbon atoms, or a heterocyclic group having 2 to 20 carbon atoms.

When the group represented by R⁷¹ has an alkyl moiety, the alkyl moiety may be branched or may be cyclic.

A hydrogen atom of the group represented by R⁷¹ is optionally replaced by R²¹, OR²¹, COR²¹, SR²¹, NR²²R²³, CONR²²R²³, —NR²²—OR²³, —N(COR²²—OCOR²³, NR²²COR²¹, OCOR²¹, COOR²¹, —C(═N—OR²¹)—R²², —C(═N—OCOR²¹)—R²², SCOR²¹, OCSR²¹, COSR²¹, CSOR²¹, a hydroxy group, a nitro group, CN, a halogen atom, or COOR²¹.

R²¹, R²², and R²³ has the same meaning as described above.

A hydrogen atom of the group represented by R²¹, R²², or R²³ is optionally replaced by CN, a halogen atom, a hydroxy group, or a carboxy group.

When the group represented by R²¹, R²², or R²³ has an alkylene moiety, the alkylene moiety may be interrupted 1 to 5 times by —O—, —S—, —COO—, —OCO—, —NR²⁴—, —NR²⁴CO—, —NR²⁴COO—, —OCONR²⁴—, —SCO—, —COS—, —OCS—, or —CSO—.

R²⁴ has the same meaning as described above.

When the group represented by R²¹, R²², or R³ has an alkyl moiety, the alkyl moiety may be branched or cyclic, and R²² and R²³ may together form a ring.

R⁷², R⁷³, and three R⁷⁴ each independently represent R⁶¹, OR⁶¹, SR⁶¹, COR⁶², CONR⁶³R⁶⁴, NR⁶⁵COR⁶¹, OCOR⁶¹, COOR⁶², SCOR⁶¹, OCSR⁶¹, COSR⁶², CSOR⁶¹, a hydroxy group, a nitro group, CN, or a halogen atom.

R⁶¹, R⁶², R⁶³, R⁶⁴, and R⁶⁵ each independently represent a hydrogen atom, an alkyl group having 1 to 20 carbon atoms, an aryl group having 6 to 30 carbon atoms, an arylalkyl group having 7 to 30 carbon atoms, or a heterocyclic group having 2 to 20 carbon atoms.

A hydrogen atom of the group represented by R⁶¹, R⁶², R⁶³, R⁶⁴, or R⁶⁵ is optionally replaced by OR²¹, COR²¹, SR²¹, NR²²Ra²³, CONR²²R²³, —NR²²—OR²³, —N(COR²²)—OCOR²³, —C(═N—OR²¹)—R²², —C(═N—OCOR²¹)—R²², CN, a halogen atom, or COOR²¹.

R⁷² and R⁷³; and two R⁷⁴ each may together form a ring.
* represents a bond to the first molecular structure of the oxime compound (1).

For the alkyl group having 1 to 20 carbon atoms, the aryl group having 6 to 30 carbon atoms, the aralkyl group having 7 to 30 carbon atoms, and the heterocyclic group having 2 to 20 carbon atoms represented by R⁷¹, R²¹, R²², R²³, R²⁴, R₆₁, R⁶², R⁶³, R⁶⁴ or R⁶⁵ in the formula (4), examples thereof include those listed for R¹¹, R¹², R¹³, R²¹, R²², R²³, and R²⁴ in the formula (1).

For the formula (4), the phrase “R²¹ and R²³ may together form a ring” means that R²² and R²³, together with the nitrogen atom, the carbon atom, or the oxygen atom bonded thereto, may form a ring.

Examples of the ring that may be formed by R²² and R²³ together include those listed for the ring that may be formed by Ra¹² and Ra¹³, or Ra²² and Ra²³ together in the formula (1).

Examples of the halogen atom represented by R⁷², R⁷³ or R⁷⁴ in the formula (4) and the halogen atom that may replace a hydrogen atom of R⁷¹, R²¹, R²², R²³, R⁶¹, R⁶², R⁶³, R⁶⁴, or R⁶⁵ include a fluorine atom, a chlorine atom, a bromine atom, and an iodine atom.

The method for producing the oxime compound (1) having the second molecular structure represented by the formula (4) is not particularly limited, and such an oxime compound can be produced by a method described in WO 2017/051680A or WO 2020/004601A, for example.

Still another example of the second molecular structure bonded to the first molecular structure represented by the formula (1) is a structure represented by the formula (5) below.

The bond represented by “*” in the formula (5) is directly bonded to the bond represented by “*” in the formula (1). In other words, when the second molecular structure is the structure represented by the formula (5), the pyrrole ring having “-+” in the formula (5) is directly bonded to the carbonyl group having “-*” in the formula (1).

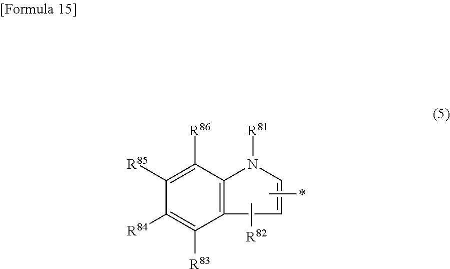

In the formula (5), R⁸¹ represents a hydrogen atom, an alkyl group having 1 to 20 carbon atoms, an aryl group having 6 to 30 carbon atoms, an aralkyl group having 7 to 30 carbon atoms, or a heterocyclic group having 2 to 20 carbon atoms.

When the group represented by R⁸¹ has an alkyl moiety, the alkyl moiety may be branched or may be cyclic.

A hydrogen atom of the group represented by R⁸¹ is optionally replaced by R²¹, OR²¹, COR²¹, SR²¹, NR²²R²³, CONR²²R²³, —NR²²—OR²³, —N(COR²²)—OCOR²³, NR²²COR²¹, OCOR²¹, COOR²¹, —C(═N—OR²¹)—R²², —C(═N—OCOR²¹)—R²², SCOR²¹, OCSR²¹, COSR²¹, CSOR²¹, a hydroxy group, a nitro group, CN, a halogen atom, or COOR²¹.

R²¹, R²², and R²³ each have the same meaning as described above.

A hydrogen atom of the group represented by R²¹, R²², or R²³ is optionally replaced by CN, a halogen atom, a hydroxy group, or a carboxy group.

When the group represented by R²¹, R²², or R²³ has an alkylene moiety, the alkylene moiety may be interrupted by 1 to 5 times by —O—, —S—, —COO—, —OCO—, —NR²⁴—, —NR²⁴CO—, —NR²⁴COO—, —OCONR²⁴—, —SCO—, —COS—, —OCS—, or —CSO—.

R²⁴ has the same meaning as described above.

When the group represented by R²¹, R²², or R²³ has an alkyl moiety, the alkyl moiety may be branched or cyclic, and R²² and R²³ may together form a ring.

R⁸², R⁸³, R⁸⁴, R⁸⁵, and R⁸⁶ each independently represent R⁶¹, OR⁶¹, SR⁶¹, COR⁶², CONR⁶³R⁶⁴, NR⁶⁵COR⁶¹, OCOR⁶¹, COOR⁶², SCOR⁶¹, OCSR⁶¹, COSR⁶², CSOR⁶¹, a hydroxy group, a nitro group, CN, or a halogen atom.

R⁶¹, R⁶², R⁶³, R⁶⁴, and R⁶⁵ each independently represent a hydrogen atom, an alkyl group having 1 to 20 carbon atoms, an aryl group having 6 to 30 carbon atoms, an arylalkyl group having 7 to 30 carbon atoms, or a heterocyclic group having 2 to 20 carbon atoms.

A hydrogen atom of the group represented by R⁶¹, R₆₂, R⁶³, R⁶⁴, or R⁶⁵ is optionally replaced by OR²¹, COR²¹, SR²¹, NR²²Ra²³, CONR²²R²³, —NR²²—OR²³, —N(COR²²)—OCOR²³, —C(═N—OR²¹)—R²², —C(═N—OCOR²¹)═—R²², CN, a halogen atom, or COOR²¹.

R⁸³ and R⁸⁴; R⁸⁴ and R⁸⁵; and R⁸⁵ and R⁸⁶ each may together form a ring.
* represents a bond to the first molecular structure of the oxime compound (1).

For the alkyl group having 1 to 20 carbon atoms, the aryl group having 6 to 30 carbon atoms, the aralkyl group having 7 to 30 carbon atoms, and the heterocyclic group having 2 to 20 carbon atoms represented by R⁸¹, R²¹, R²², R²³, R²⁴, R⁶¹, R⁶², R⁶³, R⁶⁴ or R⁶⁵ in the formula (5), examples thereof include those listed for R¹¹, R¹², R¹³, R²¹, R²², R²³, and R²⁴ in the formula (1).

For the formula (5), the phrase “R²² and R²³ may together form a ring” means that R²² and R²³, together with the nitrogen atom, the carbon atom, or the oxygen atom bonded thereto, may form a ring.

Examples of the ring that may be formed by R²² and R²³ together include those listed for the ring that may be formed by Ra¹² and Ra¹³, or Ra²² and Ra²³ together in the formula (1).

Examples of the halogen atom represented by R⁸², R⁸³, R⁸⁴, R⁸⁵, or R⁸⁶ in the formula (5) and the halogen atom that may replace a hydrogen atom of R⁸¹, R²¹, R²², R²³, R⁶¹, R⁶², R⁶³, R⁶⁴, or R⁶⁵ include a fluorine atom, a chlorine atom, a bromine atom, and an iodine atom.

The method for producing the oxime compound (1) having the second molecular structure represented by the formula (5) is not particularly limited, and such an oxime compound can be produced by a method described in WO 2017/051680A or WO 2020/004601A, for example.

Still another example of the second molecular structure bonded to the first molecular structure represented by the formula (1) is a structure represented by the formula (6) below.

The bond represented by “*” in the formula (6) is directly bonded to the bond represented by “*” in the formula (1). In other words, when the second molecular structure is the structure represented by the formula (6), the benzene ring having “-*” in the formula (6) is directly bonded to the carbonyl group having “-*” in the formula (1).

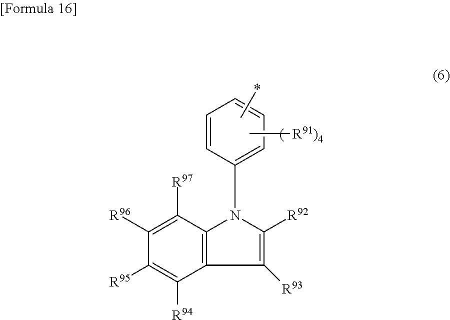

In the formula (6), a number 4 of R⁹¹, and R⁹², R⁹³, R⁹⁴, R⁹⁵, R⁹⁶, and R⁹⁷ each independently represent R⁶¹, OR⁶¹, SR⁶¹, COR⁶³, CONR⁶³R⁶⁴, NR⁶⁵COR⁶¹, OCOR⁶¹, COOR⁶², SCOR⁶¹, OCSR⁶¹, COSR⁶², CSOR⁶¹, a hydroxy group, a nitro group, CN, or a halogen atom.

R⁶¹, R⁶², R⁶³, R⁶⁴, and R⁶⁵ each independently represent a hydrogen atom, an alkyl group having 1 to 20 carbon atoms, an aryl group having 6 to 30 carbon atoms, an aralkyl group having 7 to 30 carbon atoms, or a heterocyclic group having 2 to 20 carbon atoms.

A hydrogen atom of the group represented by R⁶¹, R₆₂, R⁶³, R⁶⁴, or R⁶⁵ is optionally replaced by OR²¹, COR²¹, SR²¹, NR²²Ra²³, CONR²²R²³, —NR²²—OR²³, —N(COR²²)—OCOR²³, —C(═N—OR²¹)—R²², —C(═N—OCOR²¹)—R²², CN, a halogen atom, or COOR²¹.

R²¹, R²², and R²³ each have the same meaning as described above.

R⁹² and R⁹³; R⁹⁴ and R⁹⁵; R⁹⁵ and R⁹⁶; and R³⁶ and R⁹⁷ each may together form a ring.

* represents a bond to the first molecular structure of the oxime compound (1).

For the alkyl group having 1 to 20 carbon atoms, the aryl group having 6 to 30 carbon atoms, the aralkyl group having 7 to 30 carbon atoms, and the heterocyclic group having 2 to 20 carbon atoms represented by R²¹, R²², R²³, R⁶¹, R⁶², R⁶³, R⁶⁴, or R⁶⁵ in the formula (6), examples thereof include those listed for R¹¹, R¹², R¹³, R²¹, R²², and R²³ in the formula (1).

For the formula (6), the phrase “R²² and R²³ may together form a ring” means that R²² and R²³, together with the nitrogen atom, the carbon atom, or the oxygen atom bonded thereto, may form a ring.

Examples of the ring that may be formed by R²² and R²³ together include those listed for the ring that may be formed by Ra¹² and Ra¹³, or Ra²² and Ra²³ together in the formula (1).

Examples of the halogen atom represented by R⁹¹, R⁹², R⁹³, R⁹⁴, R⁹⁵, R⁹⁶, or R⁹⁷ in the formula (6) and the halogen atom that may replace a hydrogen atom of R²¹, R²², R²³, R⁶¹, R⁶², R⁶³, R⁶⁴, or R⁶⁵ include a fluorine atom, a chlorine atom, a bromine atom, and an iodine atom.

The method for producing the oxime compound (1) having the second molecular structure represented by the formula (6) is not particularly limited, and such an oxime compound can be produced by a method described in WO 2017/051680A or WO 2020/004601A, for example.

Other examples of the photopolymerization initiator include other photopolymerization initiators than the oxime compound (1). Examples of the other photopolymerization initiators include an oxime compound other than the oxime compound (1), an alkylphenone compound, a bimidazole compound, a triazine compound, and an acylphosphine compound.

Examples of an oxime compound other than the oxime compound (1) include an oxime compound having a partial structure represented by the following formula (d1). * represents a bond.

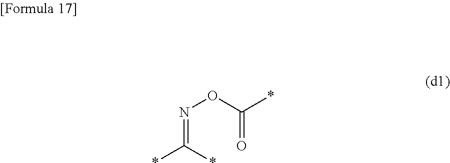 [SMILES: *C(=O)ON=C(*)*]

Examples of the oxime compound having a partial structure represented by the formula (d1) include N-benzoyloxy-1-(4-phenylsulfanylphenyl)butan-1-one-2-imine, N-benzoyloxy-1-(4-phenylsulfanylphenyl)octan-1-one-2-imine, N-benzoyloxy-1-(4-phenylsulfanylphenyl)-3-cyclopentylpropan-1-one-2-imine, N-acetoxy-1-[9-ethyl-6-(2-methylbenzoyl)-9H-carbazole-3-yl]ethane-1-imine, N-acetoxy-1-[9-ethyl-6-{2-methyl-4-(3,3-dimethyl-2,4-dioxacyclopentanylmethyloxy)benzoyl}-9H-carbazole-3-yl]ethane-1-imine, N-acetoxy-1-[9-ethyl-6-(2-methylbenzoyl)-9H-carbazole-3-yl]-3-cyclopentylpropane-1-imine, and N-benzoyloxy-1-[9-ethyl-6-(2-methylbenzoyl)-9H-carbazole-3-yl]-3-cyclopentylpropan-1-one-2-imine, and compounds disclosed in Japanese Patent Laid-Open No. 2011-132215, International Publication No. 2008/78678, International Publication No. 2008/78686, and International Publication No. 2012/132558. Commercially available products may be used, including Irgacure (registered trademark) OXE01, OXE02, and OXE03 (all manufactured by BASF SE), and N-1919, NCI-930, and NCI-831 (all manufactured by ADEKA CORPORATION).

Among others, the oxime compound having a partial structure represented by the formula (d1) is preferably at least one selected from the group consisting of N-benzoyloxy-1-(4-phenylsulfanylphenyl)butan-1-one-2-imine, N-benzoyloxy-1-(4-phenylsulfanylphenyl)octan-1-one-2-imine, and N-benzoyloxy-1-(4-phenylsulfanylphenyl)-3-cyclopentylpropan-1-one-2-imine, and is more preferably N-benzoyloxy-1-(4-phenylsulfanylphenyl)octan-1-one-2-imine.

The alkylphenone compound is a compound having a partial structure represented by the following formula (d2) or a partial structure represented by the following formula (d3). In these partial structures, the benzene ring may have a substituent.

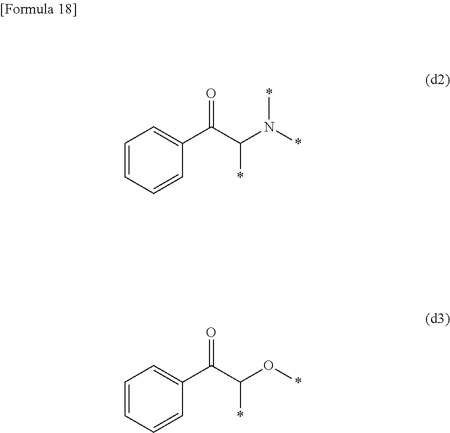 [SMILES: *C(C(=O)c1ccccc1)N(*)* ; *OC(*)C(=O)c1ccccc1]

Examples of the compound having a structure represented by the formula (d2) include 2-methyl-2-morpholino-1-(4-methylsulfanylphenyl)propan-1-one, 2-dimethylamino-1-(4-morpholinophenyl)-2-benzylbutan-1-one, and 2-(dimethylamino)-2-[(4-methylphenyl)methyl]-1-[4-(4-morpholinyl)phenyl]butan-1-one. Commercially available products may be used, including OMNIRAD (registered trademark) 369, 907, and 379 (all manufactured by IGM Resins B.V.).

Examples of the compound having a structure represented by the formula (d3) include 2-hydroxy-2-methyl-1-phenylpropan-1-one, 2-hydroxy-2-methyl-1-[4-(2-hydroxyethoxy)phenyl]propan-1-one, 1-hydroxycyclohexylphenyl ketone, an oligomer of 2-hydroxy-2-methyl-1-(4-isopropenylphenyl)propan-1-one, α,α-diethoxyacetophenone, and benzyl dimethyl ketal.

In view of sensitivity, the compound having a structure represented by the formula (d2) is preferable as the alkylphenone compound.

Examples of the biimidazole compound include a compound represented by the formula (d5):

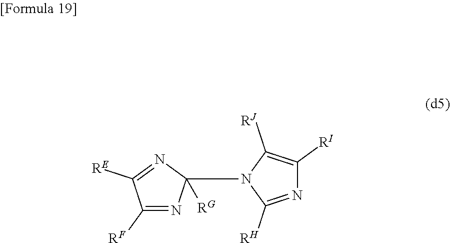

[In the formula (d5), R^{E} to R^{J} represent an aryl group having 6 to 10 carbon atoms which may have a substituent.]

Examples of the aryl group having 6 to 10 carbon atoms include a phenyl group, a toluyl group, a xylyl group, an ethylphenyl group, and a naphthyl group, and a phenyl group is preferable.

Examples of the substituent include a halogen atom and an alkoxy group having 1 to 4 carbon atoms. Examples of the halogen atom include a fluorine atom, a chlorine atom, a bromine atom, and an iodine atom, and a chlorine atom is preferable. Examples of the alkoxy group having 1 to 4 carbon atoms include a methoxy group, an ethoxy group, a propoxy group, and a butoxy group, and a methoxy group is preferable.

Examples of the biimidazole compound include 2,2′-bis(2-chlorophenyl)-4,4′,5,5′-tetraphenylbiimidazole, 2,2′-bis(2,3-dichlorophenyl)-4,4′,5,5′-tetraphenylbiimidazole (for example, see Japanese Patent Laid-Open No. 06-75372 and Japanese Patent Laid-Open No. 06-75373), 2,2′-bis(2-chlorophenyl)-4,4′,5,5′-tetraphenyl biimidazole, 2,2′-bis(2-chlorophenyl)-4,4′,5,5′-tetra(alkoxyphenyl)biimidazole, 2,2′-bis(2-chlorophenyl)-4,4′,5,5′-tetra(dialkoxyphenyl)biimidazole, 2,2′-bis(2-chlorophenyl)-4,4′,5,5′-tetra(trialkoxyphenyl)biimidazole (for example, see Japanese Patent No. 48-38403 and Japanese Patent Laid-Open No. 62-174204), and an imidazole compound in which phenyl groups at the 4,4′,5,5′ positions are each substituted with a carboalkoxy group (for example, see Japanese Patent Laid-Open No. 7-10913). Among others, the compounds represented by the following formulas and a mixture thereof are preferable.

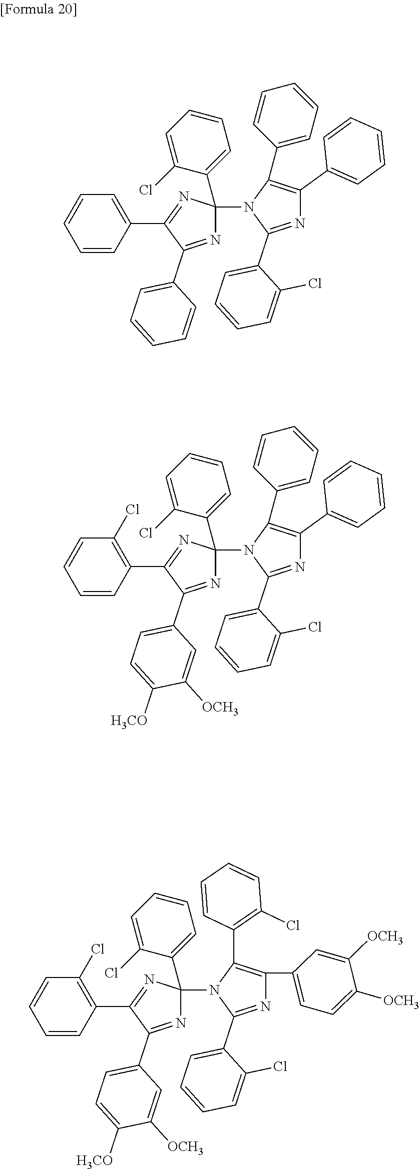 [SMILES: Clc1ccccc1-c1nc(-c2ccccc2)c(-c2ccccc2)n1C1(c2ccccc2Cl)N=C(c2ccccc2)C(c2ccccc2)=N1 ; COc1ccc(C2=NC(c3ccccc3Cl)(n3c(-c4ccccc4Cl)nc(-c4ccccc4)c3-c3ccccc3)N=C2c2ccccc2Cl)cc1OC ; COc1ccc(C2=NC(c3ccccc3Cl)(n3c(-c4ccccc4Cl)nc(-c4ccc(OC)c(OC)c4)c3-c3ccccc3Cl)N=C2c2ccccc2Cl)cc1OC]

Examples of the triazine compound include 2,4-bis(trichloromethyl)-6-(4-methoxyphenyl)-1,3,5-triazine, 2,4-bis(trichloromethyl)-6-(4-methoxynaphthyl)-1,3,5-triazine, 2,4-bis(trichloromethyl)-6-piperonyl-1,3,5-triazine, 2,4-bis(trichloromethyl)-6-(4-methoxystyryl)-1,3,5-triazine, 2,4-bis(trichloromethyl)-6-[2-(5-methylfuran-2-yl)ethenyl]-1,3,5-triazine, 2,4-bis(trichloromethyl)-6-[2-(furan-2-yl)ethenyl]-1,3,5-triazine, 2,4-bis(trichloromethyl)-6-[2-(4-diethylamino-2-methylphenyl)ethenyl]-1,3,5-triazine, and 2,4-bis(trichloromethyl)-6-[2-(3,4-dimethoxyphenyl)ethenyl]-1,3,5-triazine. Among these, 2,4-bis(trichloromethyl)-6-piperonyl-1,3,5-triazine is preferable.

Examples of the acylphosphine compound include bis(2,4,6-trimethylbenzoyl)phenylphosphine oxide, and (2,4,6-trimethylbenzoyl)diphenylphosphine oxide. Commercially available products may be used, including OMNIRAD (registered trademark) 819 (manufactured by IGM Resins B.V.).

Other examples of the other photopolymerization initiators than the oxime compound (1) include a benzoin compound, such as benzoin, benzoin methyl ether, benzoin ethyl ether, benzoin isopropyl ether, and benzoin isobutyl ether; a benzophenone compound, such as benzophenone, methyl o-benzoyl benzoate, 4-phenylbenzophenone, 4-benzoyl-4′-methyldiphenyl sulfide, 3,3′,4,4′-tetra(tert-butylperoxycarbonyl)benzophenone, 2,4,6-trimethylbenzophenone, and 4,4′-bis(diethylamino)benzophenone; a quinone compound, such as 9,10-phenanthrenequinone, 2-ethylanthraquinone, and camphorquinone; 10-butyl-2-chloroacridone, benzyl, methyl phenylglyoxylate, and a titanocene compound.

In view of enhancing the emission intensity of the curable composition and the cured film, the photopolymerization initiator is preferably at least one selected from the group consisting of an oxime compound, an alkylphenone compound, a biimidazole compound, a triazine compound, and an acylphosphine compound. In one preferable embodiment, the photopolymerization initiator includes an acylphosphine oxide compound.

The content ratio of the polymerization initiator (C), M_{c}, is, for example, 0.1% by mass or more and 20% by mass or less based on the total amount of the curable composition. In view of enhancing the sensitivity of the curable composition and enhancing the emission intensity and heat resistance (tendency for the emission characteristics not to be impaired by heat) of the curable composition and the cured film, the M_{c} is preferably 0.2% by mass or more and 15% by mass or less, more preferably 0.5% by mass or more and 10% by mass or less, even more preferably 1% by mass or more and 8V by mass or less, and may be 6% by mass or less, or 5% by mass or less.

The content ratio of the polymerization initiator (C) is, for example, 0.1% by mass or more and 20% by mass or less based on the total amount of the solids content of the curable composition. In view of enhancing the sensitivity of the curable composition and enhancing the emission intensity and heat resistance of the curable composition and the cured film, the content is preferably 0.2% by mass or more and 15% by mass or less, more preferably 0.5% by mass or more and 10% by mass or less, even more preferably 1% by mass or more and 8% by mass or less, and may be 6% by mass or less, or 5% by mass or less.

### [4] Polymerization Initiation Aid (C1)

The curable composition can further contain a polymerization initiation aid (C1) together with the polymerization initiator (C). The polymerization initiation aid (C1) is a compound that is used to accelerate the polymerization of the polymerizable compound (B) initiated by the polymerization initiator (C), or a sensitizer. Examples of the polymerization initiation aid (C1) include a photopolymerization initiation aid, such as an amine compound, an alkoxyanthracene compound, a thioxanthone compound, and a carboxylic acid compounds, and a thermal polymerization initiation aid. The curable composition may include two or more types of the polymerization initiation aids (C1).

Examples of the amine compound include triethanolamine, methyldiethanolamine, triisopropanolamine, methyl 4-dimethylaminobenzoate, ethyl 4-dimethylaminobenzoate, isoamyl 4-dimethylaminobenzoate, 2-dimethylaminoethyl benzoate, 2-ethylhexyl 4-dimethylaminobenzoate, N,N-dimethylparatoluidine, 4,4′-bis(dimethylamino)benzophenone (common name: Michler's ketone), 4,4′-bis(diethylamino)benzophenone, and 4,4′-bis(ethylmethylamino)benzophenone.

Examples of the alkoxy anthracene compound include 9,10-dimethoxyanthracene, 2-ethyl-9,10-dimethoxyanthracene, 9,10-diethoxyanthracene, 2-ethyl-9,10-diethoxyanthracene, 9,10-dibutoxyanthracene, and 2-ethyl-9,10-dibutoxyanthracene.

Examples of the thioxanthone compound include 2-isopropylthioxanthone, 4-isopropylthioxanthone, 2,4-diethylthioxanthone, 2,4-dichlorothioxanthone, and 1-chloro-4-propoxythioxanthone.

Examples of the carboxylic acid compound include phenylsulfanylacetic acid, methylphenylsulfanylacetic acid, ethylphenylsulfanylacetic acid, methylethylphenylsulfanylacetic acid, dimethylphenylsulfanylacetic acid, methoxyphenysulfanylacetic acid, dimethoxyphenylsulfanylacetic acid, chlorophenylsulfanylacetic acid, dichlorophenylsulfanylacetic acid, N-phenylglycine, phenoxyacetic acid, naphthylthioacetic acid, N-naphthylglycine, and naphthoxyacetic acid.

In a case where the curable composition contains the polymerization initiation aid (C1), the content of the polymerization initiation aid (C1) in the curable composition is preferably 0.1 parts by mass or more and 300 parts by mass or less, more preferably 0.1 parts by mass or more and 200 parts by mass or less, based on 100 parts by mass of the polymerizable compound (B). When the content of the polymerization initiation aid (C1) is within the above-described range, the curable composition can have higher sensitivity.

### [5] Antioxidant (D)

The curable composition contains an antioxidant (D). The antioxidant (D) is not particularly limited as long as it is an antioxidant for general industrial use, and a phenolic antioxidant, a phosphorus antioxidant, or a sulfur antioxidant can be used, for example. The curable composition may include two or more types of the antioxidants (D).

Examples of the phenol-based antioxidant include Irganox (R) 1010 (Irganox 1010: pentaerythritol tetrakis[3-(3,5-di-tert-butyl-4-hydroxyphenyl)propionate], manufactured by BASF Japan Ltd.), Irganox 1076 (Irganox 1076: Octadecyl-3-(3,5-di-tert-butyl-4-hydroxyphenyl)propionate, manufactured by BASF Japan Ltd.), Irganox 1330 (Irganox 1330: 3,3′,3′,5,5′,5″-hexa-tert-butyl-a, a′, a″-(mesitylene-2,4,6-triyl)tri-p-cresol, BASF Japan Ltd.), Irganox 3114 (Irganox 3114: 1,3,5-tris(3,5-di-tert-butyl-4-hydroxybenzyl)-1,3,5-triazine-2,4,6(1H,3H,5H)-trione, BASF Japan Ltd.), Irganox 3790 (Irganox 3790: 1,3,5-tris((4-tert-butyl-3-hydroxy-2,6-xylyl)methyl)-1,3,5-triazine-2,4,6(1H,3H,5H)-trione, BASF Japan Ltd.), Irganox 1035 (Irganox 1035: thiodiethylenebis[3-(3,5-di-tert-butyl-4 hydroxyphenyl)propionate], manufactured by BASF Japan Ltd.), Irganox 1135 (Irganox 1135: 3,5-bis(1,1-dimethylethyl)-4-hydroxy-C7-C9 side-chain alkyl ester of benzene propanoic acid, manufactured by BASF Japan Ltd.), Irganox 1520 L (Irganox 1520 L: 4,6-bis(octylthiomethyl)-o-cresol, manufactured by BASF Japan Ltd.), Irganox 3125 (Irganox 3125, BASF Japan Ltd.), Irganox 565 (Irganox 565: 2,4-bis(n-octylthio)-6-(4-hydroxy-3′,5′-di-tert-butylanilino)-1,3,5-triazine, manufactured by BASF Japan Ltd.), ADK STAB (R) AO-80 (ADK STAB AO-80: 3,9-bis(2-(3-(3-tert-butyl-4-hydroxy-5-methylphenyl)propionyloxy)-1,1-dimethylethyl)-2,4,8,10-tetraoxaspiro(5,5)undecane, manufactured by ADEKA Corporation), SUMILIZER (R) BHT, SUMILIZER GA-80, SUMILIZER GS (manufactured by Sumitomo Chemical Co., Ltd.), Cyanox (R) 1790 (Cyanox 1790, manufactured by Cytec Industries Inc.), and vitamin E (manufactured by Eisai Co., Ltd.).

The phenolic antioxidant is preferably an antioxidant having a hindered phenol structure in which a bulky organic group is bonded on at least one ortho position with respect to the phenolic hydroxy group. The bulky organic group is preferably a secondary or tertiary alkyl group, and specific examples include an isopropyl group, a s-butyl group, a t-butyl group, a s-amyl group, and a t-amyl group. Among these, a tertiary alkyl group is preferable, and a t-butyl group or a t-amyl group are particularly preferable.

Examples of the phosphorus antioxidant include Irgafos (registered trademark) 168 (tris(2,4-di-tert-butylphenyl) phosphite, manufactured by BASF SE), Irgafos (registered trademark) 12 (tris[2-[[2,4,8,10-tetra-tert-butyl dibenzo[d,f][1,3,2]dioxaphosphin-6-yl]oxy]ethyl]amine, manufactured by BASF SE), Irgafos (registered trademark) 38 (bis(2,4-bis(1,1-dimethylethyl)-6-methylphenyl) ethyl phosphite, manufactured by BASF SE), ADEKASTAB (registered trademark) 329K, PEP36, and PEP-8 (all manufactured by ADEKA CORPORATION), Sandstab P-EPQ (manufactured by CLARIANT), Weston (registered trademark) 618 and 619G (manufactured by GE), Ultranox 626 (manufactured by GE), and SUMILIZER (registered trademark) GP (6-[3-(3-tert-butyl-4-hydroxy-5-methylphenyl)propoxy]-2,4,8,10-tetra-t-butyl dibenz[d,f][1.3.2]dioxaphosphepine) (manufactured by Sumitomo Chemical Co., Ltd.).

The phosphorus antioxidant is preferably an antioxidant having a group represented by the following formula (e1):

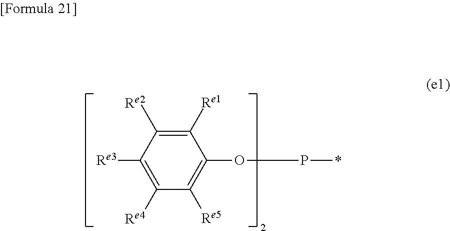

wherein R^{e1} to R^{e5} each independently represent a hydrogen atom or an alkyl group, and * represents a bond.

R^{e1} is preferably a hydrogen atom or an alkyl group having 1 to 4 carbon atoms, and more preferably a hydrogen atom, a methyl group, an ethyl group, or a t-butyl group.

R^{e2} and R^{e4} are preferably a methyl group or a hydrogen atom, and more preferably a hydrogen atom.

R^{e5} and R^{e3} are each independently preferably an alkyl group, more preferably a secondary or tertiary alkyl group, even more preferably a t-butyl or t-amyl group.

The R^{e1} of the two units, which are put in parentheses, may be bonded to each other to form a ring. The R^{e1} bonded to each other means the state in which the groups each formed by removing a hydrogen atom from R^{e1} are bonded to each other. For example, in a case where the two R^{e1} are both hydrogen atoms, it means a state in which the carbon atom to which R^{e1} is bonded in one benzene ring is directly bonded to the carbon atom to which R^{e1} is bonded in the other benzene ring.

Examples of the sulfur-based antioxidant include dialkyl thiodipropionate compounds such as dilauryl thiodipropionate, dimyristyl thiodipropionate, and distearate thiodipropionate; and β-alkylmercaptopropionic acid ester compounds of polyols such as tetrakis[methylene(3-dodecylthio)propionate]methane.

The antioxidant (D) is more preferably the phenolic antioxidant or the phosphorus antioxidant, more preferably an antioxidant having at least one of a hindered phenol structure and a group represented by the formula (e1) described above, even more preferably an antioxidant having both of the hindered phenol structure and the group represented by the formula (e1) described above, and particularly preferably SUMILIZER (registered trademark) GP.

The content ratio of the antioxidant (D), M_{D}, is, for example, 0.1% by mass or more and 60% by mass or less based on the total amount of the curable composition. In view of enhancing the emission intensity and heat resistance (tendency for the emission characteristics not to be impaired by heat) of the curable composition and the cured film, the M_{D} is preferably 0.1% by mass or more and 50% by mass or less, more preferably 0.2% by mass or more and 40% by mass or less, even more preferably 0.5% by mass or more and 30% by mass or less, and may be 20% by mass or less, 10% by mass or less, or 5% by mass or less.

The content ratio of the antioxidant (D) is, for example, 0.1% by mass or more and 60% by mass or less based on the total amount of the solids content of the curable composition. In view of enhancing the emission intensity and heat resistance of the curable composition and the cured film, the M_{D} is preferably 0.1% by mass or more and 50% by mass or less, more preferably 0.2% by mass or more and 40% by mass or less, even more preferably 0.5% by mass or more and 30% by mass or less, and may be 20% by mass or less, 10% by mass or less, 5% by mass or less, or 2% by mass or less.

### [6] Ratio Between Contents of Components (A) to (D)

The curable composition according to the first embodiment satisfies the following formula (i):

$$11.5 \leq {M}_{B} / {M}_{C} \leq 150 \qquad ( i )$$

wherein M_{B} represents the content (parts by mass) of the polymerizable compound (B) in the curable composition, and M_{c} represents the content (parts by mass) of the polymerization initiator (C) in the curable composition.

The curable composition, which satisfies the formula (i), is unlikely to generate the outgas described above. In view of suppressing generation of the outgas, M_{B}/M_{C} is preferably 15 or more, more preferably 20 or more, even more preferably 25 or more, still more preferably 30 or more, particularly preferably 35 or more, most preferably 40 or more. From the same viewpoint, M_{B}/M_{C} is preferably 140 or less, more preferably 130 or less.

The curable composition according to the second embodiment further satisfies the following formula (ii), in addition to the above-described formula (i):

$$0.01 \leq {M}_{D} / {M}_{A} \leq 0.6 \qquad ( ii )$$

wherein M_{A} represents the content (parts by mass) of the semiconductor particle (A) in the curable composition, and M_{D} represents the content (parts by mass) of the antioxidant (D) in the curable composition.

Further satisfying the formula (ii) is advantageous in terms of obtaining a curable composition and a cured film having favorable emission intensity, and also advantageous in terms of suppressing generation of outgas. In view of enhancing the emission intensity, M_{D}/M_{A} is preferably 0.02 or more, more preferably 0.03 or more, and may be 0.05 or more. In view of suppressing generation of outgas, M_{D}/M_{A} is preferably 0.55 or less, more preferably 0.5 or less, even more preferably 0.4 or less, still more preferably 0.3 or less, particularly preferably 0.2 or less, most preferably 0.1 or less.

The curable composition according to the third embodiment further satisfies the following formula (iii), in addition to the above-described formulas (i) and (ii):

$$0.5 \leq ( {M}_{B} \times {M}_{D} ) / ( {M}_{C} \times {M}_{A} ) \leq 7.5 . \qquad ( iii )$$

Further satisfying the formula (iii) is advantageous in terms of obtaining a curable composition and a cured film having favorable emission intensity, and also advantageous in terms of suppressing the generation of the outgas describe above. In view of enhancing the emission intensity and suppressing the generation of the outgas, (M_{B}×M_{D})/(M_{C}×M_{A}) is preferably 0.6 or more and 7.0 or less, more preferably 0.7 or more and 6.5 or less, even more preferably 0.8 or more and 6.0 or less, still more preferably 0.9 or more and 5.5 or less, particularly preferably 1.0 or more and 5.0 or less.

The curable composition according to the fourth embodiment satisfies the above formula (iii). When the curable composition satisfies the formula (iii), generation of the outgas described above can be suppressed, and the curable composition and the cured film also have favorable emission intensity. In view of enhancing the emission intensity and suppressing the generation of outgas, (M_{B}×M_{D})/(M_{C}×M_{A}) is preferably 0.6 or more and 7.0 or less, more preferably 0.7 or more and 6.5 or less, even more preferably 0.8 or more and 6.0 or less, still more preferably 0.9 or more and 5.5 or less, particularly preferably 1.0 or more and 5.0 or less.

In the first to fourth embodiments, the content ratio of the semiconductor particle (A), M_{A}, is preferably 10% by mass or more, more preferably 16% by mass or more, even more preferably 17% by mass or more, still more preferably 18% by mass or more, particularly preferably 20% by mass or more, most preferably 25% by mass or more, and preferably 45, by mass or less, more preferably 40% by mass or less, even more preferably 35% by mass or less, based on the total amount of the curable composition. The content ratio of the semiconductor particle (A), M_{A}, within the above-described range may be advantageous in terms of view of enhancing the emission intensity of the curable composition and the cured film.

In the first to fourth embodiments, the content ratio of the polymerizable compound (B), M_{B}, is preferably 10% by mass or more and 90% by mass or less, more preferably 20% by mass or more and 80% by mass or less, even more preferably 30% by mass or more and 75% by mass or less, still more preferably 40% by mass or more and 70% by mass or less, particularly preferably 50% by mass or more and 70% by mass or less, based on the total amount of the curable composition.

In the first to fourth embodiments, the content ratio of the polymerization initiator (C), Me, is, for example, 0.1% by mass or more and 20% by mass or less based on the total amount of the curable composition. In view of enhancing the sensitivity of the curable composition and enhancing the emission intensity and heat resistance of the curable composition and the cured film, the content is preferably 0.2% by mass or more and 15% by mass or less, more preferably 0.5% by mass or more and 10% by mass or less, even more preferably 1% by mass or more and 8% by mass or less, and may be 6% by mass or less, or 5% by mass or less.

In the first to fourth embodiments, the content ratio of the antioxidant (D), M_{D}, is, for example, 0.1% by mass or more and 60% by mass or less based on the total amount of the curable composition. In view of enhancing the emission intensity and heat resistance of the curable composition and the cured film, the M_{D} is preferably 0.1% by mass or more and 50% by mass or less, more preferably 0.2% by mass or more and 40% by mass or less, even more preferably 0.5% by mass or more and 30% by mass or less, and may be 20% by mass or less, 10% by mass or less, or 5% by mass or less.

### [7] Dipole Moment of Polymerizable Compound (B)

The curable composition according to the present invention may be the curable composition according to the fifth embodiment. The curable composition according to the fifth embodiment is any of the curable composition according to the first to fourth embodiment that further satisfies at least one of (iv) and (v) below:
(iv) the polymerizable compound (B) includes a polymerizable compound that has a dipole moment of 3D (Debye) or more (hereinafter also referred to as “polymerizable compound (Bx)”), in an amount of 40% by mass or more based on the total amount of the polymerizable compound (B); and
(v) the polymerizable compound (B) includes the polymerizable compound (Bx) in an amount of 20% by mass or more based on the total amount of the curable composition.

When at least one of (iv) and (v) is satisfied, weight loss during storage of the curable composition (hereinafter also referred simply to as “weight loss”) can be suppressed. When at least one of (iv) and (v) is satisfied, film-formability is favorable in addition to the suppression of the weight loss during storage, which results in formation of a cured film that is unlikely to generate wrinkles, and furthermore, it is possible to give a curable composition that can form a cured film having favorable emission intensity. When at least one of (iv) and (v) is satisfied, the viscosity is low in addition to the suppression of the weight loss during storage, which results in formation of a cured film that is unlikely to generate wrinkles, and furthermore, it is possible to give the curable composition that can form a cured film having favorable emission intensity. Furthermore, satisfying at least one of (iv) and (v) may be advantageous in terms of suppression of generation of outgas. The curable composition preferably satisfies both (iv) and (v) in view of suppressing weight loss and generation of outgas and also enhancing film-formability and emission intensity, and also in view of obtaining a low viscosity of the curable composition.

The polymerizable compound (B) may include two or more types of the polymerizable compounds (Bx). In this case, the content ratio of the polymerizable compound (Bx) in (iv) and that in (v) above are the total content ratio of the two or more types of the polymerizable compounds (Bx) based on the total amount of the polymerizable compound (B) and that based on the total amount of the curable composition, respectively.

In view of suppressing weight loss, the dipole moment of the polymerizable compound (Bx) is preferably 3.2D or more, more preferably 3.4D or more, even more preferably 3.6D or more. The dipole moment of the polymerizable compound (Bx) is generally 10D or less, and may be 8.0D or less, 7.0D or less, 6.0D or less, or 5.5D or less.

The weight loss of the curable composition is preferably 4.0% by mass or less, more preferably 3.0% by mass or less, even more preferably 2.0% by mass or less, still more preferably 1.0% by mass or less, particularly preferably 0.5% by mass or less, most preferably 0.1% by mass or less (for example, 0.0% by mass), as determined by the method described in the section of Examples later.

The dipole moment of the polymerizable compound can be determined, on the basis of the molecular structure thereof, by DFT (Density Functional Theory; B3LYP/6-31G+g(d)) calculation using a common calculation software. Examples of the calculation software include a quantum chemical calculation program “Gaussian series” manufactured by HULINKS Inc. The dipole moment of a polymerizable compound depends on, for example, the electronegativity of atoms constituting the polymerizable compound, and the steric structure.

In view of suppressing weight loss and generation of outgas, and furthermore, in view of enhancing film-formability and emission intensity and also obtaining a low viscosity of the curable composition, the content ratio of the polymerizable compound (Bx) is preferably 50% by mass or more, more preferably 60% by mass or more, even more preferably 70% by mass or more, still more preferably 80, by mass or more, particularly preferably 90% by mass or more, especially preferably 95% by mass or more (for example, 100% by mass), based on the total amount of the polymerizable compound (B). The content ratio may be 100% by mass or less, 90% by mass or less, or 80% by mass or less.

In view of suppressing weight loss and generation of outgas, and furthermore, in view of enhancing film-formability and emission intensity and also obtaining a low viscosity of the curable composition, the content ratio of the polymerizable compound (Bx) is preferably 30% by mass or more, more preferably 40% by mass or more, even more preferably 50% by mass or more, still more preferably 60% by mass or more, particularly preferably 65% by mass or more, based on the total amount of the curable composition. The content ratio may be 90% by mass or less, or 85% by mass or less.

In view of suppressing weight loss and generation of outgas, and furthermore, in view of enhancing film-formability and emission intensity and also obtaining a low viscosity of the curable composition, the polymerizable compound (B) preferably includes a bifunctional polymerizable compound that has a dipole moment of 3D or more (hereinafter also referred to as “polymerizable compound (Bx-2)”). The bifunctional polymerizable compound is a compound that has two polymerizable groups per molecule. Examples of the bifunctional polymerizable compound include the bifunctional (meth)acrylate compounds described hereinabove. The polymerizable compound (Bx-2) is preferably a bifunctional (meth)acrylate compound having a dipole moment of 3D or more.

In view of suppressing weight loss, the dipole moment of the polymerizable compound (Bx-2) is preferably 3.2D or more, more preferably 3.4D or more, even more preferably 3.6D or more, still more preferably 3.8D or more, particularly preferably 4.0D or more, most preferably 4.2D or more. The dipole moment of the polymerizable compound (Bx-2) is generally 8.0D or less, and may be 7.0D or less, 6.0D or less, or 5.0D or less.

In view of suppressing weight loss and generation of outgas, and furthermore, in view of enhancing film-formability and emission intensity and also obtaining a low viscosity of the curable composition, the content ratio of the polymerizable compound (Bx-2) is preferably 40% by mass or more, more preferably 50% by mass or more, even more preferably 60% by mass or more, still more preferably 70% by mass or more, further more preferably 80% by mass or more, particularly preferably 90% by mass or more, especially preferably 95, by mass or more (for example, 100% by mass), based on the total amount of the polymerizable compound (B). The content ratio may be 100% by mass or less, 95% by mass or less, 90% by mass or less, 80% by mass or less, or 70% by mass or less.

In view of suppressing weight loss and generation of outgas, and furthermore, in view of enhancing film-formability and emission intensity and also obtaining a low viscosity of the curable composition, the content ratio of the polymerizable compound (Bx-2) is preferably 20% by mass or more, more preferably 30% by mass or more, even more preferably 40% by mass or more, still more preferably 50% by mass or more, particularly preferably 60% by mass or more, based on the total amount of the curable composition. The content ratio may be 90% by mass or less, 85% by mass or less, or 80% by mass or less.

The polymerizable compound (B) may include two or more types of the polymerizable compounds (Bx-2). In this case, the content ratios of the polymerizable compound (Bx-2) described above are the total content ratio of the two or more types of the polymerizable compounds (Bx-2) based on the total amount of the polymerizable compound (B) and that based on the total amount of the curable composition, respectively.

The polymerizable compound (B) may include a polyfunctional polymerizable compound, in addition to the polymerizable compound (Bx-2). The polyfunctional polymerizable compound as used here is a compound having three or more polymerizable groups per molecule. Examples of the polyfunctional polymerizable compound include the polyfunctional (meth)acrylate compound described hereinabove. The number of the (meth)acryloyloxy groups per molecule of the polyfunctional (meth)acrylate compound is, for example, 3 or more and 6 or less, preferably 3 or more and 5 or less, more preferably 3.

Combination use of the polymerizable compound (Bx-2) with the polyfunctional polymerizable compound may highly suppress weight loss. In view of suppressing weight loss, the polyfunctional polymerizable compound preferably includes a polyfunctional polymerizable compound having a dipole moment of 3D or more (hereinafter also referred to as “polymerizable compound (Bx-3)”). The polymerizable compound (Bx-3) is preferably a trifunctional polymerizable compound having a dipole moment of 3D or more, more preferably a trifunctional(meth)acrylate compound having a dipole moment of 3D or more.

In view of suppressing weight loss, the dipole moment of the polymerizable compound (Bx-3) is preferably 3.2D or more, more preferably 3.4D or more, even more preferably 3.6D or more. The dipole moment of the polymerizable compound (Bx-3) is generally 10D or less, and may be 8.0D or less, 7.0D or less, 6.0D or less, 5.5D or less, 5.0D or less, or 4.0D or less.

In one embodiment, the polymerizable compound (B) includes the polymerizable compound (Bx-3), wherein the polymerizable compound (Bx-3) is a trifunctional polymerizable compound having a dipole moment of 3D or more and 4D or less. When the polymerizable compound (B) includes a trifunctional polymerizable compound having a dipole moment of 3D or more and 4D or less, there is a tendency that weight loss is more effectively suppressed.

In a case where the polymerizable compound (B) further includes the polyfunctional polymerizable compound, the content ratio thereof is preferably 0.1% by mass or more, more preferably 0.5% by mass or more, even more preferably 1.0% by mass or more, still more preferably 2.0% by mass or more, further more preferably 3.0% by mass or more, particularly preferably 4.0% by mass or more, most preferably 5.0% by mass or more, based on the total amount of the polymerizable compound (B), in view of suppressing weight loss. The content ratio is preferably 20% by mass or less, more preferably 15% by mass or less, even more preferably 10% by mass or less, still more preferably 8.0% by mass or less, based on the total amount of the polymerizable compound (B), in view of a reduced viscosity of the curable composition.

In a case where the polymerizable compound (B) further includes the polyfunctional polymerizable compound, the content ratio thereof is preferably 0.1% by mass or more, more preferably 0.2% by mass or more, even more preferably 0.5% by mass or more, still more preferably 1.0% by mass or more, further more preferably 2.0% by mass or more, particularly preferably 3.0% by mass or more, most preferably 4.0% by mass or more, based on the total amount of the curable composition, in view of suppressing weight loss. The content ratio is preferably 15% by mass or less, more preferably 10% by mass or less, even more preferably 8.0% by mass or less, still more preferably 6.0% by mass or less, based on the total amount of the curable composition, in view of a reduced viscosity of the curable composition.

The polymerizable compound (B) may include two or more types of polyfunctional polymerizable compounds (preferably the polymerizable compounds (Bx-3)). In this case, the above-described content ratios of the polyfunctional polymerizable compounds are the total content ratio of the two or more types of the polyfunctional polymerizable compounds based on the total amount of the polymerizable compound (B) and that based on the total amount of the curable composition, respectively.

In a case where the polymerizable compound (B) further includes the polyfunctional polymerizable compound, the polyfunctional polymerizable compound is preferably the polymerizable compound (Bx-3) in view of suppressing weight loss. In this case, the absolute value of the difference between the dipole moment of the polymerizable compound (Bx-2) and the dipole moment of the polymerizable compound (Bx-3) is preferably 2.0D or less, more preferably 1.5D or less, even more preferably 1.0D or less. The absolute value of the difference may be 0D.

The polymerizable compound (B) may include a polymerizable compound that has a dipole moment less than 3D (hereinafter also referred to as “polymerizable compound (By)”). The content ratio of the polymerizable compound (By) is preferably 30% by mass or less, more preferably 25% by mass or less, even more preferably 20% by mass or less, still more preferably 15% by mass or less, particularly preferably 10% by mass or less, most preferably 5% by mass or less, based on the total amount of the polymerizable compound (B). The content ratio may be 0% by mass, or may be 1% by mass or more, 2% by mass or more, or 3% by mass or more.

The polymerizable compound (B) may include a polymerizable compound that has a dipole moment less than 3D (hereinafter also referred to as “polymerizable compound (By)”). The content ratio of the polymerizable compound (By) is preferably 20% by mass or less, more preferably 15% by mass or less, even more preferably 10% by mass or less, still more preferably 5% by mass or less, based on the total amount of the curable composition. The content ratio may be 0% by mass, or may be 1% by mass or more, 2% by mass or more, or 3% by mass or more.

The polymerizable compound (B) may include two or more types of the polymerizable compounds (By). In this case, the content ratios of the polymerizable compound (By) described above are the total content ratio of the two or more types of the polymerizable compounds (By) based on the total amount of the polymerizable compound (B) and that based on the total amount of the curable composition, respectively.

The dipole moment of the polymerizable compound (By) may be, for example, 2.8D or less, 2.5D or less, or 2.0D or less, and may be more than 0, or 0.0001D or more.

### [8] Light Scattering Agent (E)

The curable composition may further contain a light scattering agent (E). When the curable composition contains the light scattering agent (E), a cured film to be formed from the curable composition has improved light-scattering properties against light irradiated from a light source. The curable composition may include two or more types of the light scattering agents (E).

Examples of the light scattering agent (E) include inorganic particles such as particles of metal or metal oxide, and glass particles. Examples of the metal oxide include TiO₂, SiO₂, BaTiO₃, and ZnO, and particles of TiO₂, which efficiently scatter light, are preferable.

The light scattering agent (E) has a volume-weighted median diameter of, for example, 0.03 μm or more, preferably 0.10 μm or more, more preferably 0.15 μm or more, even more preferably 0.20 μm or more, and may be, for example, 20 μm or less, preferably 5 μm or less, more preferably 1 μm or less.

The content ratio of the light scattering agent (E) in the curable composition is, for example, 0.001% by mass or more and 50% by mass or less based on the total amount of the curable composition or the total amount of the solids content of the curable composition, and it is preferably 0.01% by mass or more, more preferably 0.1% by mass or more, even more preferably 1% by mass or more, and preferably 30% by mass or less, more preferably 15% by mass or less, even more preferably 10% by mass or less, in view of enhancing the light scattering properties and the emission intensity of the curable composition and the cured film.

### [9] Solvent (F)

The curable composition may contain a solvent (F). If the curable composition contains the solvent (F), the content ratio thereof is preferably small. In a case where the curable composition contains the solvent (F), the content ratio thereof is preferably 10% by mass or less, more preferably 5% by mass or less, even more preferably 3% by mass or less, still more preferably 2% by mass or less, particularly preferably 1% by mass or less, and may be 0% by mass and be 0.5% by mass or more, based on the total amount of the curable composition. A small content of the solvent (F) facilitates the control of the film thickness when a cured film is formed, and can also reduce the production cost and the burden of the solvent on the global environment and working environment. The curable composition may contain two or more types of the solvents (F).

Examples of the solvent (F) include an ester solvent (a solvent having —C(═O)—O—), an ether solvent other than an ester solvent (a solvent having —O—), an ether ester solvent (a solvent having —C(═O)—O— and —O—), a ketone solvent other than an ester solvent (a solvent having —C(═O)—), an alcohol solvent, an aromatic hydrocarbon solvent, an amide solvent, and dimethyl sulfoxide.

Examples of the ester solvent include methyl lactate, ethyl lactate, butyl lactate, methyl 2-hydroxyisobutanoate, ethyl acetate, n-butyl acetate, isobutyl acetate, pentyl formate, isopentyl acetate, butyl propionate, isopropyl butyrate, ethyl butyrate, butyl butyrate, methyl pyruvate, ethyl pyruvate, propyl pyruvate, methyl acetoacetate, ethyl acetoacetate, and γ-butyrolactone.

Examples of the ether solvent include ethylene glycol monomethyl ether, ethylene glycol monoethyl ether, ethylene glycol monopropyl ether, ethylene glycol monobutyl ether, diethylene glycol monomethyl ether, diethylene glycol monoethyl ether, diethylene glycol monobutyl ether, propylene glycol monomethyl ether, propylene glycol monoethyl ether, propylene glycol monopropyl ether, propylene glycol monobutyl ether, 3-methoxy-1-butanol, 3-methoxy-3-methylbutanol, tetrahydrofuran, tetrahydropyran, 1,4-dioxane, diethylene glycol dimethyl ether, diethylene glycol diethyl ether, diethylene glycol methyl ethyl ether, diethylene glycol dipropyl ether, diethylene glycol dibutyl ether, anisole, phenetol, and methyl anisole.

Examples of the ether ester solvent include methyl methoxyacetate, ethyl methoxyacetate, butyl methoxyacetate, methyl ethoxyacetate, ethyl ethoxyacetate, methyl 3-methoxypropionate, ethyl 3-methoxypropionate, methyl 3-ethoxypropionate, ethyl 3-ethoxypropionate, methyl 2-methoxypropionate, ethyl 2-methoxypropionate, propyl 2-methoxypropionate, methyl 2-ethoxypropionate, ethyl 2-ethoxypropionate, methyl 2-methoxy-2-methylpropionate, ethyl 2-ethoxy-2-methylpropionate, 3-methoxybutylacetate, 3-methyl-3-methoxybutyl acetate, propylene glycol monomethyl ether acetate, propylene glycol monoethyl ether acetate, propylene glycol monopropyl ether acetate, ethylene glycol monomethyl ether acetate, ethylene glycol monoethyl ether acetate, diethylene glycol monoethyl ether acetate, diethylene glycol monobutyl ether acetate, and dipropylene glycol methyl ether acetate.

Examples of the ketone solvent include 4-hydroxy-4-methyl-2-pentanone, acetone, 2-butanone, 2-heptanone, 3-heptanone, 4-heptanone, 4-methyl-2-pentanone, cyclopentanone, cyclohexanone, and isophorone.

Examples of the alcohol solvent include methanol, ethanol, propanol, butanol, hexanol, cyclohexanol, ethylene glycol, propylene glycol, and glycerin.

Examples of the aromatic hydrocarbon solvent include benzene, toluene, xylene, and mesitylene.

Examples of the amide solvent include N,N-dimethylformamide, N,N-dimethylacetamide, and N-methylpyrrolidone.

The solvent (F) is preferably the ester solvent, the ether ester solvent, the alcohol solvent, or the amide solvent, and more preferably the ether ester solvent.

### [10] Leveling Agent (H)

The curable composition may further contain a leveling agent (H). Examples of the leveling agent (H) include a silicone surfactant, a fluorosurfactant, and a silicone surfactant having a fluorine atom. These may have a polymerizable group in a side chain thereof. The curable composition may contain two or more types of the leveling agents (H).

Examples of the silicone surfactant include a surfactant having a siloxane bond in its molecule. Specific examples include TORAY silicone DC3PA, SH7PA, DC11PA, SH21PA, SH28PA, SH29PA, SH30PA, and SH8400 (product names: manufactured by Dow TORAY), KP321, KP322, KP323, KP324, KP326, KP340, and KP341 (manufactured by Shin-Etsu Chemical Co., Ltd.), TSF400, TSF401, TSF410, TSF4300, TSF4440, TSF4445, TSF4446, TSF4452, and TSF4460 (manufactured by Momentive Performance Materials Japan).

Examples of the fluorosurfactant include a surfactant having a fluorocarbon chain in its molecule. Specific examples include Fluorad (registered trademark) FC 430 and FC 431 (manufactured by Sumitomo 3M Limited), MEGAFACE (registered trademark) F142D, F171, F172, F173, F177, F183, F554, F575, R30, and RS-718-K (manufactured by DIC Corporation), F-top (registered trademark) EF301, EF303, EF351, and EF352 (manufactured by Mitsubishi Materials Electronic Chemicals Co., Ltd.), Surflon (registered trademark) S381, S382, SC101, and SC105 (manufactured by AGC Inc.), and E5844 (manufactured by Daikin Finechemicals Co., Ltd.)

Examples of the silicone surfactant having a fluorine atom include a surfactant having a siloxane bond and a fluorocarbon chain in its molecule. Specific examples include MEGAFACE (registered trademark) R08, BL20, F475, F477, and F443 (manufactured by DIC Corporation).

In a case where the curable composition contains the leveling agent (H), the content ratio of the leveling agent (H) in the curable composition is, for example, 0.001% by mass or more and 1.0% by mass or less, and preferably 0.005% by mass or more and 0.75% by mass or less, more preferably 0.01% by mass or more and 0.5% by mass or less, even more preferably 0.05% by mass or more and 0.5% by mass or less, based on the total amount of the curable composition. A content ratio of the leveling agent (H) within the above-described range can bring about favorable flatness of the cured film.

### [11] Resin (I)

The curable composition may contain a resin (I). However, if the curable composition contains the resin (I), the content ratio thereof is preferably small. In a case where the curable composition contains the resin (I), the content ratio thereof is preferably 10% by mass or less, more preferably 5% by mass or less, even more preferably 3% by mass or less, still more preferably 2% by mass or less, particularly preferably 1% by mass or less, and may be 0% by mass and be 0.5% by mass or more, based on the total amount of the curable composition. When the content of the resin (I) is small, the curable composition can have a low viscosity, and accordingly, have the improved discharge characteristics, especially, improved discharge characteristics when it is ejected from an ejecting head of an inkjet printer. The curable composition may two or more types of the resins (I).

Examples of the resin (I) include the following resins [K1] to [K4]:
resin [K1]: copolymer of at least one (a) (hereinafter also referred to as “(a)”) selected from the group consisting of an unsaturated carboxylic acid and an unsaturated carboxylic acid anhydride and a monomer (c) (hereinafter also referred to as “(c)”) copolymerizable with (a) (but different from (a));
resin [K2]: resin obtained by reacting a copolymer of (a) and (c) with a monomer (b) (hereinafter also referred to as “(b)”) having a cyclic ether structure having 2 to 4 carbon atoms and an ethylenically unsaturated bond;
resin [K3]: resin obtained by reacting a copolymer of (b) and (c) with (a); and
resin [K4]: resin obtained by reacting a copolymer of (b) and (c) with (a) and further reacting with a carboxylic acid anhydride.

Examples of (a) include unsaturated monocarboxylic acids such as (meth)acrylic acid, crotonic acid, and o-, m-, and p-vinylbenzoic acid;
unsaturated dicarboxylic acids such as maleic acid, fumaric acid, citraconic acid, mesaconic acid, itaconic acid, 3-vinylphthalic acid, 4-vinylphthalic acid, 3,4,5,6-tetrahydrophthalic acid, 1,2,3,6-tetrahydrophthalic acid, dimethyltetrahydrophthalic acid, and 1,4-cyclohexenedicarboxylic acid;
bicyclo unsaturated compounds containing a carboxy group, such as methyl-5-norbornene-2,3-dicarboxylic acid, 5-carboxybicyclo[2.2.1]hept-2-ene, 5,6-dicarboxybicyclo[2.2.1]hept-2-ene, 5-carboxy-5-methylbicyclo[2.2.1]hept-2-ene, 5-carboxy-5-ethylbicyclo[2.2.1]hept-2-ene, 5-carboxy-6-methylbicyclo[2.2.1]hept-2-ene, and 5-carboxy-6-ethylbicyclo[2.2.1]hept-2-ene;
unsaturated dicarboxylic acid anhydrides such as maleic anhydride, citraconic anhydride, itaconic anhydride, 3-vinylphthalic anhydride, 4-vinylphthalic anhydride, 3,4,5,6-tetrahydrophthalic anhydride, 1,2,3,6-tetrahydrophthalic anhydride, dimethyltetrahydrophthalic anhydride, 5,6-dicarboxybicyclo[2.2.1]hept-2-ene anhydride;
unsaturated mono[(meth)acryloyloxyalkyl]esters of di- or higher polycarboxylic acids such as mono[2-(meth)acryloyloxyethyl]succinate and mono[2-(meth)acryloyoxyethyl]phthalate; and
unsaturated (meth)acrylates containing a hydroxy group and a carboxy group in the same molecule, such as α-(hydroxymethyl) (meth)acrylic acid.

Of these, (meth)acrylic acid, maleic anhydride and the like are preferable from the viewpoint of copolymerization reactivity, for example.

(b) is, for example, a monomer having a cyclic ether structure having 2 to 4 carbon atoms (for example, at least one selected from the group consisting of an oxirane ring, an oxetane ring, and a tetrahydrofuran ring) and an ethylenically unsaturated bond. (b) is preferably a monomer having a cyclic ether structure having 2 to 4 carbon atoms and a (meth)acryloyloxy group.

Examples of (b) include monomers having an oxirane ring and an ethylenically unsaturated bond, such as glycidyl (meth)acrylate, β-methylglycidyl (meth)acrylate, β-ethylglycidyl (meth)acrylate, glycidyl vinyl ether, o-vinylbenzyl glycidyl ether, m-vinylbenzyl glycidyl ether, p-vinylbenzyl glycidyl ether, α-methyl-o-vinylbenzyl glycidyl ether, α-methyl-m-vinylbenzyl glycidyl ether, α-methyl-p-vinylbenzyl glycidyl ether, 2,3-bis(glycidyloxymethyl)styrene, 2,4-bis(glycidyloxymethyl)styrene, 2,5-bis(glycidyloxymethyl) styrene, 2,6-bis(glycidyloxymethyl)styrene, 2,3,4-tris(glycidyloxymethyl) styrene, 2,3,5-tris(glycidyloxymethyl)styrene, 2,3,6-tris(glycidyloxymethyl) styrene, 3,4,5-tris(glycidyloxymethyl)styrene, and 2,4,6-tris(glycidyloxymethyl) styrene;
monomers having an oxetane ring and an ethylenically unsaturated bond, such as 3-methyl-3-methacryloyloxymethyloxetane, 3-methyl-3-acryloyloxymethyloxetane, 3-ethyl-3-methacryloyloxymethyloxetane, 3-ethyl-3-acryloyloxymethyloxetane, 3-methyl-3-methacryloyloxyethyloxetane, 3-methyl-3-acryloyloxyethyloxetane, 3-ethyl-3-methacryloyloxyethyloxetane, and 3-ethyl-3-acryloyloxyethyloxetane; and
monomers having a tetrahydrofuran ring and an ethylenically unsaturated bond, such as tetrahydrofurfuryl acrylate (for example, Viscoat V #150, manufactured by OSAKA ORGANIC CHEMICAL INDUSTRY LTD.) and tetrahydrofurfuryl methacrylate.
(b) is preferably a monomer having an oxirane ring and an ethylenically unsaturated bond, because the reactivity during the production of the resins [K2] to [K4] is high and unreacted (b) hardly remains.

Examples of (c) include (meth)acrylic esters such as methyl (meth)acrylate, ethyl (meth)acrylate, n-butyl (meth)acrylate, sec-butyl (meth)acrylate, tert-butyl (meth)acrylate, 2-ethylhexyl (meth)acrylate, dodecyl (meth)acrylate, lauryl (meth)acrylate, stearyl (meth)acrylate, cyclopentyl (meth)acrylate, cyclohexyl (meth)acrylate, 2-methylcyclohexyl (meth)acrylate, tricyclo[5.2.1.0^{2,6}]decan-8-yl (meth)acrylate (referred to as “dicyclopentanyl (meth)acrylate” (common name) in the art or sometimes referred to as “tricyclodecyl (meth)acrylate”), tricyclo[5.2.1.0^{2,6}]decen-8-yl (meth)acrylate (which is referred to as “dicyclopentenyl (meth)acrylate” (common name) in the art), dicyclopentanyloxyethyl (meth)acrylate, isobornyl (meth)acrylate, adamantyl (meth)acrylate, allyl (meth)acrylate, propargyl (meth)acrylate, phenyl (meth)acrylate, naphthyl (meth)acrylate, and benzyl (meth)acrylate;
hydroxy group-containing (meth)acrylic esters such as 2-hydroxyethyl (meth)acrylate and 2-hydroxypropyl (meth)acrylate;
dicarboxylic diesters such as diethyl maleate, diethyl fumarate, and diethyl itaconate;
bicyclo unsaturated compounds such as bicyclo[2.2.1]hept-2-ene, 5-methylbicyclo[2.2.1]hept-2-ene, 5-ethylbicyclo[2.2.1]hept-2-ene, 5-hydroxybicyclo[2.2.1]hept-2-ene, 5-hydroxymethylbicyclo[2.2.1]hept-2-ene, 5-(2′-hydroxyethyl)bicyclo[2.2.1]hept-2-ene, 5-methoxybicyclo[2.2.1]hept-2-ene, 5-ethoxybicyclo[2.2.1]hept-2-ene, 5,6-dihydroxybicyclo[2.2.1]hept-2-ene, 5,6-di(hydroxymethyl)bicyclo[2.2.1]hept-2-ene, 5,6-di(2′-hydroxyethyl)bicyclo[2.2.1]hept-2-ene, 5,6-dimethoxybicyclo[2.2.1]hept-2-ene, 5,6-diethoxybicyclo[2.2.1]hept-2-ene, 5-hydroxy-5-methylbicyclo[2.2.1]hept-2-ene, 5-hydroxy-5-ethylbicyclo[2.2.1]hept-2-ene, 5-hydroxymethyl-5-methylbicyclo[2.2.1]hept-2-ene, 5-tert-butoxycarbonylbicyclo[2.2.1]hept-2-ene, 5-cyclohexyloxycarbonylbicyclo[2.2.1]hept-2-ene, 5-phenoxycarbonylbicyclo[2.2.1]hept-2-ene, 5,6-bis(tert-butoxycarbonyl)bicyclo[2.2.1]hept-2-ene, and 5,6-bis(cyclohexyloxycarbonyl)bicyclo[2.2.1]hept-2-ene;
dicarbonylimide derivatives such as N-phenylmaleimide, N-cyclohexylmaleimide, N-benzylmaleimide, N-succinimidyl-3-maleimidobenzoate, N-succinimidyl-4-maleimidobutyrate, N-succinimidyl-6-maleimide caproate, N-succinimidyl-3-maleimide propionate, and N-(9-acridinyl)maleimide; and
styrene, α-methylstyrene, m-methylstyrene, p-methylstyrene, vinyltoluene, p-methoxystyrene, acrylonitrile, methacrylonitrile, vinyl chloride, vinylidene chloride, acrylamide, methacrylamide, vinyl acetate, 1,3-butadiene, isoprene, and 2,3-dimethyl-1,3-butadiene.

Among these, from the viewpoint of copolymerization reactivity and heat resistance of the resin (C), styrene, vinyltoluene, N-phenylmaleimide, N-cyclohexylmaleimide, N-benzylmaleimide, bicyclo[2.2.1]hept-2-ene and the like are preferable.

In the resin [K1], the ratio of the structural unit derived from each of (a) and (c) in the total structural units constituting the resin [K1] is preferably the following:
the structural unit derived from (a): 2 mol % or more and 60 mol % or less; and
the structural unit derived from (c): 40 mol % or more and 98 mole or less,
   and more preferably the following:
the structural unit derived from (a): 10 mol % or more and 50 mol, or less; and
the structural unit derived from (c): 50 mole or more and 90 mol % or less.

In the case where the resin (I) contains the structural unit derived from (a), the resin (I) can contain two or more structural units derived from (a), and in that case, the ratio (the content ratio in terms of mole) of the structural unit derived from (a) is the total sum of the ratios of the structural units. The same also applies to a structural unit derived from another monomer such as (b) and (c).

The resin [K1] can be produced with reference to the method disclosed in for example, a document “Experimental Method for Polymer Synthesis” (edited by Takayuki Otsu, published by Kagaku-Dojin Publishing Company, INC, First Edition, First Printed on Mar. 1, 1972) and cited documents described in the above-mentioned document.

Specific examples thereof include the following method: predetermined amounts of (a) and (c), a polymerization initiator, a solvent and the like are placed in a reaction vessel; for example, a deoxidization atmosphere is formed by replacing oxygen with nitrogen; and these are heated or kept warm during stirring.

The polymerization initiator, the solvent and the like which are used are not particularly limited, and those commonly used in the art can be used. Examples of the polymerization initiator include an azo compounds (2,2′-azobisisobutyronitrile, 2,2′-azobis(2,4-dimethylvaleronitrile), etc.) and an organic peroxides (benzoyl peroxide, etc.). The solvent may be any solvent that dissolves the monomers, and examples thereof include those listed above as the solvent (F), which may be contained in the curable composition.

A solution after a reaction, of the resultant copolymer may be used as it is; a concentrated or diluted solution of the copolymer may be used; or a solid (powder) taken out from the copolymer by a method such as reprecipitation may be used.

The resin [K2] can be produced by adding a cyclic ether having 2 to 4 carbon atoms of (b) to the copolymer of (a) and (c), that is, to a carboxylic acid and/or a carboxylic acid anhydride of (a).

The copolymer of (a) and (c) is first produced in the same manner as in the method described as the method for producing the resin [K1]. In this case, the ratio of the structural unit derived from each of (a) and (c) is preferably the same ratio as that described in the resin [K1].

Next, a cyclic ether having 2 to 4 carbon atoms of (b) is reacted with a part of the carboxylic acid and/or the carboxylic acid anhydride derived from (a) in the copolymer.

Subsequent to the production of the copolymer of (a) and (c), the resin [K2] can be produced by replacing a nitrogen atmosphere in a flask with air, and reacting (b) in the presence of a reaction catalyst for a carboxylic acid or a carboxylic acid anhydride and a cyclic ether (for example, an organic phosphorus compound, a metallic complex, or an amine compound), and a polymerization inhibitor (for example, hydroquinone and the like), for example, at 60° C. or more and 130° C. or less for 1 to 10 hours.

The amount of (b) used is preferably 5 mol or more and 80 mol or less, and more preferably 10 mol or more and 75 mol or less, based on 100 mol of (a).

Examples of the organic phosphorus compound as a reaction catalyst include triphenylphosphine. As the amine compound as the reaction catalyst, for example, an aliphatic tertiary amine compound or an aliphatic quaternary ammonium salt compound can be used, and specific examples thereof include tris(dimethylaminomethyl)phenol, triethylamine, tetrabutylammonium bromide, and tetrabutylammonium chloride.

The amount of the reaction catalyst used is preferably 0.001 part by mass or more and 5 parts by mass or less based on 100 parts by mass of the total amount of (a), (b), and (c).

The amount of the polymerization inhibitor used is preferably 0.001 part by mass or more and 5 parts by mass or less based on 100 parts by mass of the total amount of (a), (b), and (c).

The reaction conditions such as the charging method, the reaction temperature and the time can be appropriately adjusted in consideration of the production equipment, the amount of heat generated by the polymerization, and the like. In the same manner as the polymerization conditions, the charging method and the reaction temperature can be appropriately adjusted in consideration of the production equipment, the amount of heat generated by the polymerization, and the like.

The resin [K3] is produced by producing a copolymer of (b) and (c) in the same manner as in the above-mentioned method for producing the resin [K1] as a first step. In the same manner as in the above, a solution after a reaction, of the resultant copolymer may be used as it is; a concentrated or diluted solution of the copolymer may be used; or a solid (powder) taken out from the copolymer by a method such as reprecipitation may be used.

The ratio of the structural unit derived from each of (b) and (c) based on the total number of moles of the total structural units constituting the copolymer is preferably the following:
the structural unit derived from (b): 5 mol % or more and 95 mol or less; and
the structural unit derived from (c): 5 mol, or more and 95 mol % or less,
   and more preferably the following:
the structural unit derived from (b): 10 mol % or more and 90 mol % or less; and
the structural unit derived from (c): 10 mol, or more and 90 mol % or less.

The resin [K3] can be produced by reacting a carboxylic acid or a carboxylic acid anhydride of (a) with the cyclic ether derived from (b) contained in the copolymer of (b) and (c) under the same conditions as those of the method for producing the resin [K2].

The amount of (a) used which is reacted with the copolymer is preferably 5 mol or more and 80 mol or less based on 100 mol of (b).

The resin [K4] is a resin obtained by further reacting the resin [K3] with a carboxylic acid anhydride. A carboxylic acid anhydride is reacted with a hydroxy group generated by a reaction between a cyclic ether and a carboxylic acid or a carboxylic anhydride.

Examples of the carboxylic acid anhydride include maleic anhydride, citraconic anhydride, itaconic anhydride, 3-vinylphthalic anhydride, 4-vinylphthalic anhydride, 3,4,5,6-tetrahydrophthalic anhydride, 1,2,3,6-tetrahydrophthalic anhydride, dimethyltetrahydrophthalic anhydride, 5,6-dicarboxybicyclo[2.2.1]hept-2-ene anhydride.

The amount of the carboxylic acid anhydride used is preferably 0.5 to 1 mol based on 1 mol of the amount used in (a).

Specific examples of the resin (K1), the resin (K2), the resin (K3), and the resin (K4) include a resin [K1] such as a benzyl (meth)acrylate/(meth)acrylic acid copolymer and a styrene/(meth)acrylic acid copolymer;
a resin [K2] such as a resin produced by adding glycidyl (meth)acrylate to a benzyl (meth)acrylate/(meth)acrylic acid copolymer, a resin produced by adding glycidyl (meth)acrylate to a tricyclodecyl (meth)acrylate/styrene/(meth)acrylic acid copolymer, or a resin produced by adding glycidyl (meth)acrylate to a tricyclodecyl (meth)acrylate/benzyl (meth)acrylate/(meth)acrylic acid copolymer; a resin [K3] such as a resin produced by reacting a tricyclodecyl (meth)acrylate/glycidyl (meth)acrylate copolymer with (meth)acrylic acid or a resin produced by reacting a tricyclodecyl (meth)acrylate/styrene/glycidyl (meth)acrylate copolymer with (meth)acrylic acid; and a resin [K4] such as a resin produced by reacting a tricyclodecyl (meth)acrylate/glycidyl (meth)acrylate copolymer with (meth)acrylic acid to produce a resin and then reacting this resin with tetrahydrophthalic anhydride.

As a further example of the resin (I), the resin disclosed in Japanese Patent Laid-Open No. 2018-123274 can be mentioned. Examples of the resin include a polymer (hereinafter, also referred to as “resin (Ba)”) which has a double bond in a side chain, includes a structural unit (α) represented by the following formula (I) and a structural unit (β) represented by the following formula (II) in a main chain, and further includes an acid group.

The acid group may be introduced into the resin when, for example, the resin (Ba) contains a structural unit (y) derived from an acid group-containing monomer (for example, (meth)acrylic acid). The resin (Ba) preferably contains the structural units (α), (β), and (γ) in the main chain skeleton.

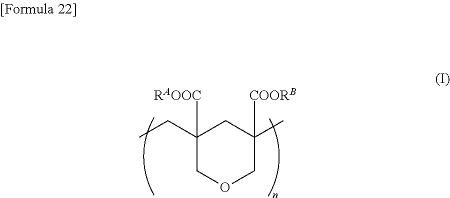

[In the formula, R^{A} and R^{B} are the same or different and each represent a hydrogen atom or a hydrocarbon group having 1 to 25 carbon atoms. n represents the average number of repeating units of the structural units represented by the formula (I), and is a number of 1 or more.]

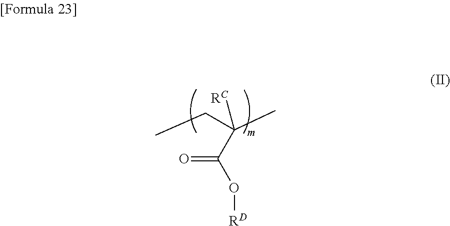

[In the formula, each R^{C} is the same or different and represents a hydrogen atom or a methyl group. Each RD is the same or different and represents a linear or branched chain hydrocarbon group having 4 to 20 carbon atoms. m represents the average number of repeating units of the structural units represented by the formula (II), and is a number of 1 or more.]

The content proportion of the structural unit (a) in the resin (Ba) is, for example, from the viewpoint of heat resistance and storage stability of the resin (Ba), 0.5% by mass or more and 50% by mass or less, preferably 1% by mass or more and 40% by mass or less, and more preferably 5% by mass or more and 30% by mass or less based on 100% by mass of the total amount of all monomer units that give the main chain skeleton of the resin (Ba). In the formula (I), n represents the average number of repeating units of the structural units (a) in the resin (Ba), and n can be set so that the content proportion of the structural units (a) falls within the above range.

The content proportion of the structural unit (P) is, for example, from the viewpoint of the solvent resistance of the cured film, 10% by mass or more and 90% by mass or less, preferably 20% by mass or more and 80% by mass or less, and more preferably 30% by mass or more and 75% by mass or less based on 100% by mass of the total amount of all monomer units that give the main chain skeleton of the resin (Ba). In the formula (II), m represents the average number of repeating units of the structural units (β) in the resin (Ba), and m can be set so that the content proportion of the structural units (β) falls within the above range.

The content proportion of the structural unit (γ) is, for example, from the viewpoint of the solubility of the resin (Ba), 0.5% by mass or more and 50% by mass or less, preferably 2% by mass or more and 50% by mass or less, and more preferably 5% by mass or more and 45% by mass or less based on 100% by mass of the total amount of all monomer units that give the main chain skeleton of the resin (Ba).

The resin (I) may be one or more selected from the group consisting of the resin [K1], the resin [K2], the resin [K3], the resin [K4], and the resin (Ba) described above.

### [12] Other Components

The curable composition may contain additives as other components, such as a dispersant, a plasticizer, and a filler, if necessary.

Examples of the dispersant include, but not limited to, cationic, anionic, nonionic, amphoteric, polyester, polyamine, and acrylic surfactants. In a case where the curable composition contains the light scattering agent (E), the dispersant is preferably used in combination therewith. When the curable composition contains the dispersant, the dispersibility of the light scattering agent (E) is improved in the curable composition.

In a case where the curable composition contains the dispersant, the content ratio thereof is preferably 10% by mass or less, more preferably 5% by mass or less, even more preferably 3% by mass or less, particularly preferably 1% by mass or less, and may be 0% by mass, or 0.1% by mass or more, or 0.3% by mass or more, based on the total amount of the curable composition. The content ratio is preferably 3% by mass or less, more preferably 2% by mass or less, particularly preferably 1% by mass or less, in view of reduction of the viscosity.

The content ratio of the additive is preferably 10% by mass or less, more preferably 5% by mass or less, even more preferably 3% by mass or less, particularly preferably 1% by mass or less, and may be 0% by mass, based on the total amount of the curable composition.

### <Method for Producing Curable Composition and Viscosity Thereof>

The curable composition can be produced according to a method including the step of mixing the specific components and other components used as necessary.

The mixing sequence of the components is not particularly limited. For example, the semiconductor particle (A) and the polymerizable compound (B) can be mixed to obtain a dispersion, and then, the dispersion can be mixed with the polymerization initiator (C), the antioxidant (D) and other components to prepare the curable composition.

The ligand-containing semiconductor particle as the semiconductor particle (A) may be one obtained by providing or preparing a semiconductor particle having an organic ligand coordinating thereto and then decreasing the amount of the organic ligand coordinating to the semiconductor particle, or in other words, performing ligand-decreasing treatment. The ligand-decreasing treatment may be treatment in which the organic ligand coordinating to the semiconductor particle is extracted with an appropriate solvent, for example.

The viscosity of the curable composition at 40° C. is preferably 20 cP or less, more preferably 15 cP or less, even more preferably 12 cP or less, still more preferably 10 cP or less. The lower limit is not particularly limited, and the viscosity may be 2 cP or more, 3 cP or more, or 5 cP or more. When the curable composition has a viscosity within the above-described range, the curable composition has the improved discharge characteristics. Particularly, when the curable composition has a viscosity within the above-described range, the curable composition can be smoothly ejected from an ejecting head of an inkjet printer, and can thus be suitably used as an ink for inkjet printers.

In a case where the curable composition is used as an ink for inkjet printers, the curable composition can be ejected from an ejecting head of an inkjet printer at a temperature of 40° C. or more. Since the curable composition may have favorable resistance to heat, the physical properties (particularly, photoconversion efficiency) of the cured film obtained may be favorable even if the curable composition is ejected at a temperature condition of 40° C. or more. When ejected from an ejecting head of an inkjet printer, the temperature of the curable composition may be 50° C. or more, or 60° C. or more, and may be 80° C. or less.

### <Cured Film, Patterned Cured Film, Wavelength Conversion Film, and Display Device>

A film (layer) formed from the curable composition can be cured to thereby obtain a cured film. Specifically, the curable composition can be applied to a substrate to form a coating film, and the resulting coating film can be exposed to light to obtain a cured film.

Examples of the substrate used include a plate of glass such as silica glass, borosilicate glass, alumina silicate glass, and soda-lime glass having a silica-coated surface; a plate of resin such as polycarbonate, polymethyl methacrylate, and polyethylene terephthalate; silicon; and those obtained by forming a thin film of aluminum, silver, or silver/copper/palladium alloy on any of these substrates.

Examples of the method for applying the curable composition include various printing methods, such as gravure printing method, offset printing method, letterpress printing method, screen printing method, transfer printing method, electrostatic printing method, and plate-less printing method; applicating methods, such as gravure coating method, roll coating method, knife coating method, air knife coating method, bar coating method, dip coating method, kiss coating method, spray coating method, die coating method, comma coating method, inkjet method, spin coating method, and slit coating method; and combined method thereof, and these can be used appropriately.

A light source used for exposure is preferably a light source generating light having a wavelength of 250 nm or more and 450 nm or less. For example, light having a wavelength less than 350 nm may be cut off with a filter for cutting off light having this wavelength range, and light having a wavelength of about 436 nm, about 408 nm, or about 365 nm may be selectively extracted with a band pass filter for extracting light having any of these wavelength ranges. Examples of the light source include a mercury lamps, a light emitting diode, a metal halide lamp, and a halogen lamp. The exposure may be carried out in air atmosphere or inert gas (nitrogen, argon, etc.) atmosphere, and preferably in inert gas atmosphere.

A patterned cured film can also be formed from the curable composition by patterning by a method such as photolithography method or inkjet method or printing method. Photolithography method causes loss of the composition, which is an expensive material, and therefore, inkjet method is preferably employed in view of reduction of material loss.

The method for producing a patterned cured film by inkjet method may include, for example, forming a bank on a substrate, applying the curable composition by inkjet method selectively to the area defined by the bank on the substrate, and expose the curable composition to light to cure the curable composition. As the substrate, those listed above in the description of the method for producing a cured film can be used.

The method for forming a bank may be photolithography method or inkjet method, for example, and it is preferable to form the bank by inkjet method. Examples of the inkjet method include bubble jet (registered trademark) method, which involves use of an electrothermal converter as an energy generating element, and piezojet method, which involves use of a piezo element.

As the light source used for exposure, those listed above in the description of the method for producing a cured film can be used.

A non-patterned cured film or a patterned cured film can be used suitably as a wavelength conversion film (wavelength conversion filter), which emits light having a wavelength different from that of incident light from a light-emitting member such as an LED. Particularly, the patterned cured film is preferably positioned above light-emitting elements corresponding to the pattern, such as an LED. The wavelength of light from each light-emitting element can be converted separately so as to appropriately control the shape of the light emission spectrum for red, green, blue, etc., which results in high color reproducibility. A display member having the wavelength conversion film can be suitably used for a display device such as a liquid crystal display device and an organic EL device.

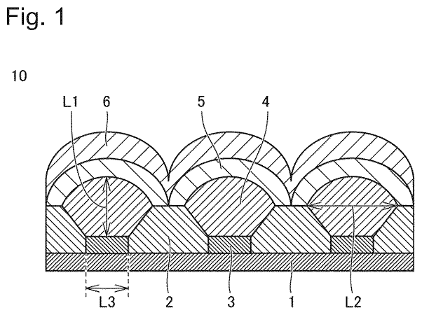

FIG. 1 is a schematic cross section of one embodiment of the display member produced by inkjet method. The display member 10 in FIG. 1 has banks 2 formed on a substrate 1 and light-emitting elements 3, such as LEDs, each disposed between the banks 2, and further has cured films 4 (wavelength conversion films) obtained by applying the curable composition according to the present invention to the light-emitting elements 3 between the banks 2 by inkjet method and then curing the composition (hereinafter, each cured film patterned in a size between the banks 2 is referred to as “cured film pixel”). On each cured film pixel 4, a color filter 5 and a gas barrier layer 6 may be disposed, for example.

Forming the cured film pixels 4 by inkjet method enables patterning in a relatively large size, and the resultant can be suitably applied to, for example, a large-sized display such as digital signage.

In a case where the inkjet method is employed, the cured film pixel 4 formed from the curable composition according to the present invention preferably has a vertical dimension (L1) of 9 μm or more, more preferably 12 μm or more, even more preferably 15 μm or more, and may be 40 μm or less, or 30 μm or less. The vertical dimension (L1) may be the same length as the horizontal dimension (L3) of the light-emitting element.

In a case where the inkjet method is employed, the cured film pixel 4 formed from the curable composition according to the present invention preferably has a horizontal dimension (L2) of 10 μm or more, more preferably 30 μm or more, even more preferably 50 μm or more, still more preferably 80 μm or more, particularly preferably 100 μm or more, and may be 900 μm or less, 800 μm or less, 700 μm or less.

The vertical dimension (L1) of the cured film pixel 4 is the dimension in the substrate's thickness direction in a cross section when cut in the direction vertical to the substrate. The cross section is obtained by cutting at the position such that the vertical dimension of the cured film pixel 4 is maximum. FIG. 1 shows the cross section obtained when cut in the direction vertical to the substrate at the position such that the vertical dimension of the cured film pixel 4 is maximum.

The horizontal dimension (L2) of the cured film pixel 4 is the maximum dimension of the cured film pixel 4 in the direction horizontal to the substrate, and refers to a dimension when viewed the substrate in the vertical direction thereto (dimension in the planer view).

The horizontal dimension (L3) of the light-emission element is the maximum dimension of the light-emission element in the direction horizontal to the substrate, and refers to a dimension when viewed the substrate in the vertical direction thereto (dimension in the planer view).

### EXAMPLES

The present invention will now be described more specifically by way of Examples, but the present invention is not limited by Examples below at all. It is, as a matter of course, also possible to carry out the present invention with suitable modification made appropriately within the scope of the gist described hereinabove or hereinafter, and they are all encompassed by the technical scope of the present invention. Hereinafter, “parts” and “i” mean “parts by mass” and “A by mass”, respectively, unless otherwise noticed.

The following materials were used in Examples and Comparative Examples.
Semiconductor particle (A): a dried product of quantum dots obtained by removing toluene from a quantum dots dispersion in toluene (the wavelength of the maximum peak in the emission spectrum: 530 nm; the full width at half maximum: 42 nm) by distillation under reduced pressure, wherein the quantum dots were ligand-containing quantum dots containing oleic acid as the organic ligand (G) and having a structure: InP/ZnSeS.
Polymerizable compound (B1): calboxy group-containing polyfunctional (meth)acrylate (product name: “ARONIX M-510”, manufactured by TOAGOSEI CO., LTD.). This compound corresponds to the compound (B-3a) described hereinabove.
Polymerizable compound (B2): 2-(2-vinyloxyethoxy)ethyl acrylate (VEEA (registered trademark), manufactured by NIPPON SHOKUBAI CO., LTD.). This compound corresponds to the compound (B-4) described hereinabove.
Polymerizable compound (B3): dicyclopentenyl acrylate (manufactured by Showa Denko Materials Co., Ltd.; volatile content at 80° C. (1 h): 0.26% by mass; glass transition temperature of homopolymer: 120° C.). This compound corresponds to the compound (B-1) described hereinabove.
Polymerizable compound (B4): tetrahydrofurfuryl acrylate (manufactured by Tokyo Chemical Industry Co., Ltd.; volatile content at 80° C. (1 h): 1.44% by mass; glass transition temperature of homopolymer: −12° C.). This compound corresponds to the compound (B-1) described hereinabove.
Polymerizable compound (B5): lauryl acrylate (manufactured by Tokyo Chemical Industry Co., Ltd.; volatile content at 80° C. (1 h): 0.22% by mass; glass transition temperature of homopolymer: −12° C.). This compound corresponds to the compound (B-1) described hereinabove.
Polymerizable compound (B6): ethylcarbitol acrylate (manufactured by Tokyo Chemical Industry Co., Ltd.; volatile content at 80° C. (1 h): 0.57% by mass; glass transition temperature of homopolymer: −67° C.). This compound corresponds to the compound (B-1) described hereinabove.
Polymerizable compound (B7): 3,3,5-trimethylcyclohexyl acrylate (manufactured by Tokyo Chemical Industry Co., Ltd.; volatile content at 80° C. (1 h): 1.57% by mass; glass transition temperature of homopolymer: 52° C.). This compound corresponds to the compound (B-1) described hereinabove.
Polymerizable compound (B8): ethyl methacrylate (Light Ester E, manufactured by Kyoeisha Chemical Co., Ltd.; volatile content at 80° C. (1 h): 7.24% by mass; glass transition temperature of homopolymer: 65° C.). This compound corresponds to the compound (B-1) described hereinabove.
Polymerizable compound (B9): bifunctional acrylate compound corresponding to the compound (B-2) described hereinabove (dipole moment 4.5854).
Polymerizable compound (B10): polyfunctional acrylate compound corresponding to the compound (B-3b) described hereinabove (dipole moment 3.7115).
Polymerizable compound (B11): dipropylene glycol diacrylate (glass transition temperature of homopolymer: 110° C.; dipole moment 4.4234). This compound corresponds to the compound (B-2) described hereinabove.
Polymerizable compound (B12): tripropylene glycol diacrylate (glass transition temperature of homopolymer: 55° C.; dipole moment 6.1895). This compound corresponds to the compound (B-2) described hereinabove.
Polymerization initiator (C1): OMNIRAD (registered trademark) 819, manufactured by IGM Resins B.V.
Polymerization initiator (C2): OMNIRAD (registered trademark) 369, manufactured by IGM Resins B.V.
Antioxidant (D1): SUMILIZER (registered trademark) GP manufactured by Sumitomo Chemical Co., Ltd.
Light-scattering agent (E1): Titanium dioxide particles (volume-weighted median diameter 0.23 μm)
Solvent (F1): Propylene glycol monomethyl ether acetate (PGMEA)
Leveling agent (G1): MEGAFACE (registered trademark) F-554, manufactured by DIC Corporation

The emission spectrum of the semiconductor particle (A) was obtained on a measurement sample that was a dispersion of the semiconductor particle (A) diluted such that the absorbance at a wavelength of 450 nm was 0.4, using an absolute PL quantum yield spectrometer (“C9920-02”, manufactured by HAMAMATSU PHOTONICS K.K., excitation light 450 nm, room temperature, in air atmosphere).

The “glass transition temperature of a homopolymer” described above is the glass transition temperature of a homopolymer of that polymerizable compound, and the value described in “Chemical” in “Business & Products” on the web site of OSAKA ORGANIC CHEMICAL INDUSTRY LTD. (ooc.co.jp) were used.

The “volatile content at 80° C. (1 h)” described above is the volatile content when the polymerizable compound is heated at 80° C. for 1 hour, and specifically, it was determined in the following manner.

In an aluminum cup, 5 g of a polymerizable compound was weighed, and the cup was then placed on a hotplate at 80° C. for 1 hour. The volatile content (% by mass) was calculated using the following equation from the initial weight (W0) and the weight after 1 hour (W1):

Volatile content (% by mass)=100×(W0−W1)/W0

The dipole moment (D: Debye) of a polymerizable compound was determined on a basis of its molecular structure by DFT (Density Functional Theory; B3LYP/6-31G+g(d)) calculation using a quantum chemical calculation software “Gaussian 16” manufactured by HULINKS Inc.

### Comparative Example 1 and 2

The polymerizable compound (B) described in Table 1 was added to the semiconductor particle (A), and the resultant was stirred using an ultrasonic bath and a touch mixer until the solids disappeared, to thereby obtain a quantum dots/monomer dispersion. To the dispersion obtained, the polymerization initiator (C), the antioxidant (D), the solvent (F), and the leveling agent (H) were added according to the formulation described in Table 1 or 2, and the resultant was stirred using a touch mixer to thereby obtain a curable composition.

### Example 1 to 12

The polymerizable compound (B) described in Table 1 or 2 was added to the semiconductor particle (A), and the resultant was stirred using an ultrasonic bath and a touch mixer until the solids disappeared, to thereby obtain a quantum dots/monomer dispersion. To the dispersion obtained, the polymerization initiator (C), the antioxidant (D), and the leveling agent (H) were added according to the formulation described in Table 1 or 2, and the resultant was stirred using a touch mixer to thereby obtain a curable composition.

In Tables 1 and 2, the numerical values in parts by mass for the components other than the solvent (F) are values in terms of the solids content.

The values of M_{B}/M_{C}, M_{D}/M_{A}, and (M_{B}×M_{D})/(M_{C}×M_{A}) are also shown in Tables 1 and 2. The viscosity of the curable composition at 40° C. is also shown in Tables 1 and 2. The viscosity of the curable composition at 40° C. was measured using a Brookfield rotary viscometer in conditions of a constant temperature of 40° C. and a number of rotations of 3 rpm.

TABLE 1

| | | Comparative | | | | | | | |
|---|---|---|---|---|---|---|---|---|---|
| | | Example | | Example | | | | | |
| | | 1 | 2 | 1 | 2 | 3 | 4 | 5 | 6 |
| Semiconductor | (A) | 29.1 | 29.1 | 28.0 | 28.0 | 28.0 | 28.0 | 28.0 | 28.0 |
| particle (A) | | | | | | | | | |
| Polymerizable | (B1) | 13.5 | 13.5 | 12.6 | 12.6 | 12.6 | 12.6 | 12.6 | 12.6 |
| compound (B) | (B2) | 13.5 | 13.5 | 33.8 | 33.8 | 33.8 | 33.8 | 33.8 | 27.4 |
| | (B3) | | | 23.0 | | | | | 28.4 |
| | (B4) | | | | 23.0 | | | | |
| | (B5) | | | | | 23.0 | | | |
| | (B6) | | | | | | 23.0 | | |
| | (B7) | | | | | | | 23.0 | |
| | (B8) | 17.5 | 17.5 | | | | | | |
| | (B9) | | | | | | | | |
| | (B10) | | | | | | | | |
| | (B11) | | | | | | | | |
| | (B12) | | | | | | | | |
| Polymerization | (C1) | | 3.9 | 1.5 | 1.5 | 1.5 | 1.5 | 1.5 | 2.5 |
| initiator (C) | (C2) | 3.9 | | | | | | | |
| Antioxidant (D) | (D1) | 19.4 | 19.4 | 1.0 | 1.0 | 1.0 | 1.0 | 1.0 | 1.0 |
| Solvent (F) | (F1) | 3.0 | 3.0 | | | | | | |
| Leveling agent (H) | (G1) | 0.1 | 0.1 | 0.1 | 0.1 | 0.1 | 0.1 | 0.1 | 0.1 |
| Total | | 100 | 100 | 100 | 100 | 100 | 100 | 100 | 100 |
| M_{B}/M_{C} | | 11.4 | 11.4 | 46.3 | 46.3 | 46.3 | 46.3 | 46.3 | 27.4 |
| M_{D}/M_{A} | | 0.67 | 0.67 | 0.04 | 0.04 | 0.04 | 0.04 | 0.04 | 0.04 |
| (M_{B} × M_{D})/(M_{C} × M_{A}) | | 7.6 | 7.6 | 1.7 | 1.7 | 1.7 | 1.7 | 1.7 | 1.0 |
| Viscosity of curable | (cP) | 16 | 18 | 12 | 10 | 11 | 12 | 11 | 15 |
| composition (40° C.) | | | | | | | | | |
| Amount of outgas | Relative | 102 | 100 | 29.9 | 33.1 | 29.3 | 31.2 | 33.8 | 38.2 |
| generated | value | | | | | | | | |
| Emission intensity | (μW) | 1865 | 1828 | 1986 | 1884 | 1998 | 1628 | 1861 | 1906 |
| EI | | | | | | | | | |

TABLE 2

| | | Example | | | | | |
|---|---|---|---|---|---|---|---|
| | | 7 | 8 | 9 | 10 | 11 | 12 |
| Semiconductor | (A1) | 28.0 | 28.0 | 28.0 | 28.0 | 28.0 | 28.0 |
| particle (A) | | | | | | | |
| Polymerizable | (B1) | 12.6 | 18.0 | 5.0 | | 4.5 | 4.5 |
| compound (B) | (B2) | 34.8 | 35.8 | 17.0 | | | |
| | (B3) | 23.0 | 15.1 | | | | |
| | (B4) | | | | | | |
| | (B5) | | | | | | |
| | (B6) | | | | | | |
| | (B7) | | | | | | |
| | (B8) | | | | | | |
| | (B9) | | | 47.4 | 64.9 | | |
| | (B10) | | | | 4.5 | | |
| | (B11) | | | | | 64.9 | |
| | (B12) | | | | | | 64.9 |
| Polymerization | (C1) | 0.5 | 1.5 | 1.5 | 1.5 | 1.5 | 1.5 |
| initiator (C) | (C2) | | | | | | |
| Antioxidant (D) | (D1) | 1.0 | 1.5 | 1.0 | 1.0 | 1.0 | 1.0 |
| Solvent (F) | (F1) | | | | | | |
| Leveling agent (H) | (G1) | 0.1 | 0.1 | 0.1 | 0.1 | 0.1 | 0.1 |
| Total | | 100 | 100 | 100 | 100 | 100 | 100 |
| M_{B}/M_{C} | | 140.8 | 45.9 | 46.3 | 46.3 | 46.3 | 46.3 |
| M_{D}/M_{A} | | 0.04 | 0.05 | 0.04 | 0.04 | 0.04 | 0.04 |
| (M_{B} × M_{D})/(M_{C} × M_{A}) | | 5.0 | 2.5 | 1.7 | 1.7 | 1.7 | 1.7 |
| Viscosity of curable | (cP) | 13 | 18 | 10 | 10 | 12 | 14 |
| composition (40° C.) | | | | | | | |
| Amount of outgas | Relative | 51.0 | 40.0 | 76.4 | 53.3 | 64.5 | 62.7 |
| generated | value | | | | | | |
| Emission intensity | (μW) | 2068 | 2026 | 1978 | 1962 | 1988 | 1997 |
| EI | | | | | | | |

### <Evaluation Test>

### (1) Amount of Outgas Generated

The curable composition was applied to a 5 cm-square glass substrate (“EAGLE XG” manufactured by Corning Incorporated) by spin coating method such that the layer after post-baking had a thickness of 10 μm. The resulting coating was irradiated to light in nitrogen atmosphere in an amount of light exposed of 200 mJ/cm² (on a basis of 365 nm) using an exposure equipment (“SPOT CURE SP-7” manufactured by Ushio Inc.), and subjected to post-baking at 180° C. for 30 minutes, to thereby prepare a cured film. The thickness of the cured film was measured using a profilometer for measuring a film thickness (“DektakXT” manufactured by Bruker).

After the preparation of the cured film, a part thereof was peeled off, and used as a measurement sample. The sample was subjected to TG-DTA. The temperature was increased to 180° C., and that temperature was kept for 60 minutes. The weight change ratio (weight after kept for 60 minutes/weight before TG-DTA) was determined. The weight change ratio corresponds to the amount of outgas generated. In the column “Amount of outgas generated” in Tables 1 and 2, the weight change ratio in Comparative Example 2 was regarded as “100”, and the relative values of the respective weight change ratios to Comparative Example 2 were shown for Examples and other Comparative Example.

### (2) Emission Intensity of Cured Film

A cured film was prepared on a glass substrate in the same manner as in (1) above.

A light-scattering plate was placed on a backlight with a blue LED lamp having a wavelength of the emission peak of 450 nm as a point light source, and the resultant was used as a backlight member. The backlight member was placed with the light-scattering plate facing upward, and a spectral radiance meter (“SR-UL1R” manufactured by TOPCON TECHNOHOUSE CORPORATION) was arranged at a position 60 cm above the surface of the light-scattering plate. The cured film formed on the glass substrate as described above was used as a measurement sample, and the measurement sample was placed on the surface of the light-scattering plate with the cured film facing upward. In that state, the backlight was turned on, and the spectral radiance spectrum was obtained for the light emitted from the cured film using the above-described spectral radiance meter, and from the resulting spectrum, the emission intensity EI (μW) at the wavelength of the maximum peak in the emission peak was calculated. The results are shown in Tables 1 and 2.

### (3) Weight Loss Ratio of Curable Composition

The curable composition immediately after the preparation was placed in a sealed container, and left stand in an environment at 25° C. for 1 day. Then, 0.5 g of the curable composition was weighed in a 6 mL screw vial, and the vial was closed with a cap, placed on a hot plate set at 40° C., and stored for 4 days. The weight loss ratio (% by mass) of the curable composition was calculated from the weight of the curable composition before the storage at 40° C. for 4 day (W0) and that after the storage at 40° C. for 4 day (W1) using the following equation.

$$Weight loss ratio ( \% by mass ) = 100 \times ( W 0 - W 1 ) / W 0$$

The weight loss ratio was determined for the curable compositions of Example 9 and Example 10, and found to be 0.0% by mass for both.

### REFERENCE SIGNS LIST

1: Substrate, 2: bank, 3: light-emitting element, 4: cured film (wavelength conversion filter), 5: color filter, 6: gas barrier layer, 10: display member, L1: vertical dimension, L2: horizontal dimension, L3: horizontal dimension of light-emitting element

1. A curable composition comprising: a semiconductor particle (A); a polymerizable compound (B); a polymerization initiator (C); and an antioxidant (D);
wherein a formula (i) is satisfied:
$$11.5 \leq {M}_{B} / {M}_{C} \leq 150 \qquad ( i )$$
wherein M_{B} represents a content ratio (% by mass) of the polymerizable compound (B) and M_{c} represents a content ratio (% by mass) of the polymerization initiator (C), all based on a total amount of the curable composition.

2. The curable composition according to claim 1, wherein a formula (ii) is further satisfied:
$$0.01 \leq {M}_{D} / {M}_{A} \leq 0.6 \qquad ( ii )$$
wherein M_{A} represents a content ratio (% by mass) of the semiconductor particle (A) and M_{D} represents a content ratio (% by mass) of the antioxidant (D), all based on the total amount of the curable composition.

3. The curable composition according to claim 1, wherein a formula (iii) is further satisfied:
$$0.5 \leq ( {M}_{B} \times {M}_{D} ) / ( {M}_{C} \times {M}_{A} ) \leq 7.5 . \qquad ( iii )$$

4. A curable composition comprising: a semiconductor particle (A); a polymerizable compound (B); a polymerization initiator (C); and an antioxidant (D);
wherein a formula (iii) is satisfied:
$$0.5 \leq ( {M}_{B} \times {M}_{D} ) / ( {M}_{C} \times {M}_{A} ) \leq 7.5 . \qquad ( iii )$$
wherein M_{A} represents a content ratio (% by mass) of the semiconductor particle (A), M_{B} represents a content ratio (% by mass) of the polymerizable compound (B), M_{c} represents a content ratio (% by mass) of the polymerization initiator (C), and M_{D} represents a content ratio (% by mass) of the antioxidant (D), all based on a total amount of the curable composition.

5. The curable composition according to claim 1, further comprising a light scattering agent (E).

6. The curable composition according to claim 1, wherein the polymerizable compound (B) includes a polymerizable compound that has a volatile content of 7% by mass or less when heated at 80° C. for 1 hour.

7. The curable composition according to claim 1, wherein the polymerizable compound (B) includes a polymerizable compound of which homopolymer has a glass transition temperature of −50° C. or more.

8. The curable composition according to any claim 1, wherein the polymerizable compound (B) includes a polymerizable compound that has a dipole moment of 3D or more, in an amount of 40% by mass or more based on a total amount of the polymerizable compound (B).

9. The curable composition according to claim 8, wherein the polymerizable compound (B) includes a difunctional polymerizable compound that has a dipole moment of 3D or more, in an amount of 40% by mass or more based on the total amount of the polymerizable compound (B).

10. The curable composition according to claim 8, wherein the polymerizable compound (B) includes a trifunctional polymerizable compound that has a dipole moment of 3D or more and 4D or less.

11. The curable composition according to claim 1, wherein the polymerizable compound (B) includes a polymerizable compound that has a dipole moment of 3D or more, in an amount of 20% by mass or more based on the total amount of the curable composition.

12. The curable composition according to claim 11, wherein the polymerizable compound (B) includes a difunctional polymerizable compound that has a dipole moment of 3D or more, in an amount of 20% by mass or more based on the total amount of the curable composition.

13. The curable composition according to claim 11, wherein the polymerizable compound (B) includes a trifunctional polymerizable compound that has a dipole moment of 3D or more and 4D or less.

14. The curable composition according to claim 1, wherein a content ratio of a solvent (F) is 1% by mass or less based on the total amount of the curable composition.

15. The curable composition according to claim 1, wherein a content ratio of a resin (I) is 1% by mass or less based on the total amount of the curable composition.

16. The curable composition according to claim 1, wherein the curable composition has a viscosity of 20 cP or less at 40° C.

17. A cured film formed from the curable composition according to claim 1.

18. A display device comprising the cured film according to claim 17.
